(19) United States
(12) Patent Application Publication
(10) Pub. No.: US 2020/0142302 A1
(43) Pub. Date: May 7, 2020

(54) CURABLE COMPOSITION, CURED PRODUCT, COLOR FILTER, METHOD FOR PRODUCING COLOR FILTER, SOLID-STATE IMAGING ELEMENT, AND IMAGE DISPLAY DEVICE

(71) Applicant: FUJIFILM Corporation, Tokyo (JP)

(72) Inventors: Junichi ITO, Haibara-gun (JP); Yushi KANEKO, Haibara-gun (JP); Hiroaki IDEI, Haibara-gun (JP); Yutaro FUKAMI, Haibara-gun (JP); Kazuya OTA, Haibara-gun (JP)

(73) Assignee: FUJIFILM Corporation, Tokyo (JP)

(21) Appl. No.: 16/735,760

(22) Filed: Jan. 7, 2020

Related U.S. Application Data
(63) Continuation of application No. PCT/JP2018/029702, filed on Aug. 8, 2018.

(30) Foreign Application Priority Data
Aug. 31, 2017 (JP) 2017-167431

(51) Int. Cl. G03F 7/00; C08F 220/14; C08F 220/28; C08F 220/18; G03F 7/038; G03F 7/039

(52) U.S. Cl. CPC G03F 7/0007; C08F 220/14; C08F 220/281; G03F 7/162; C08F 220/1807; G03F 7/038; G03F 7/039; C08F 220/283

(57) ABSTRACT

A curable composition contains a particle and at least one polymer compound selected from the group consisting of a polymer compound having a specific structure and a specific absorbance E of less than 5 at a maximum absorption wavelength in the range of 400 to 800 nm and a polymer compound having a specific structure and a specific absorbance E of less than 5 at a maximum absorption wavelength in the range of 400 to 800 nm.

### CROSS-REFERENCE TO RELATED APPLICATIONS

This application is a Continuation of PCT International Application No. PCT/JP2018/029702 filed on Aug. 8, 2018, which claims priority under 35 U.S.C § 119(a) to Japanese Patent Application No. 2017-167431 filed on Aug. 31, 2017. Each of the above application(s) is hereby expressly incorporated by reference, in its entirety, into the present application.

### BACKGROUND OF THE INVENTION

### 1. Field of the Invention

The present disclosure relates to a curable composition, a cured product, a color filter, a method for producing a color filter, a solid-state imaging element, and an image display device.

### 2. Description of the Related Art

A member such as a color filter is produced by a photolithographic method or the like, using a coloring photosensitive composition which is formed by adding a polyfunctional monomer, a photopolymerization initiator, an alkali-soluble resin, and other components to a pigment dispersion composition in which an organic pigment or an inorganic pigment is dispersed.

Examples of a dispersant or composition used in the formation of a conventional color filter include those described in JP2007-277514A, JP2010-523810A, JP2016-102191A, and JP2017-057380A.

JP2007-277514A discloses a polymer compound represented by General Formula (1).

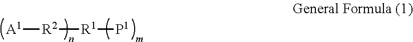

In the formula, R¹ represents an (m+n)-valent organic linking group, and R² represents a single bond or a divalent organic linking group. A¹ is a monovalent organic group containing at least one moiety selected from an organic coloring agent structure, a heterocyclic structure, an acid group, a group having a basic nitrogen atom, a urea group, a urethane group, a group having a coordinating oxygen atom, a hydrocarbon group having 4 or more carbon atoms, an alkoxysilyl group, an epoxy group, an isocyanate group, and a hydroxyl group. n number of A¹'s and R²'s may be each independently the same as or different from one another. m represents 1 to 8, n represents 2 to 9, and m+n satisfies 3 to 10. P¹ represents a polymer skeleton. m number of P¹'s may be the same as or different from one another.

JP2010-523810A discloses an alkali-soluble resin composition including a monomer containing an acid group, a monomer polymerizable with the monomer containing an acid group, and a polyfunctional thiol compound as a chain transfer agent.

JP2016-102191A discloses a coloring composition which contains a coloring agent represented by General Formula (1) and a curable compound, and has a specific absorbance represented by Expression (Aλ) of 5 or more at a maximum absorption wavelength within 400 nm to 800 nm.

(D-R²)ₙ—R¹-(L₁-P)ₘ (1)

In General Formula (1), R¹ represents an (m+n)-valent linking group,

P represents a monovalent substituent having a repeating unit derived from a vinyl compound;

D represents a coloring agent structure,

R² and L¹ each independently represent a single bond or a divalent linking group,

m represents an integer of 1 to 13,

in a case where m is 1, P represents a monovalent substituent having 2 to 20 repeating units derived from a vinyl compound,

in a case where m is 2 or more, a plurality of P's may be different from one another, and an average number of repeating units derived from a vinyl compound in the plurality of P's is 2 to 20,

n represents an integer of 2 to 14,

in a case where n is 2 or more, a plurality of D's may be different from one another, and

m+n represents an integer of 2 to 15;

E=A/(c×L) (Aλ)

in Expression (Aλ), E represents a specific absorbance at a maximum absorption wavelength within 400 nm to 800 nm,

A represents an absorbance at a maximum absorption wavelength within 400 nm to 800 nm,

L represents a cell length, which is expressed in cm, and

c represents a concentration of a coloring agent in a solution, which is expressed in mg/ml.

JP2017-057380A discloses a curable composition containing (A) at least one selected from a pigment or a metal oxide particle, (B) dispersant, and (C) at least one selected from a binder resin or a polymerizable compound, in which (B) dispersant contains a specific compound.

### SUMMARY OF THE INVENTION

For example, a cured product such as a color filter is obtained by pattern formation using the dispersant or composition described in JP2007-277514A, JP2010-523810A, JP2016-102191A, and JP2017-057380A, but further improvement in edge shape has been required in the pattern of the resulting cured product.

An object to be achieved by an embodiment of the present invention is to provide a curable composition that provides an excellent edge shape in a pattern of a cured product thereof.

Further, an object to be achieved by another embodiment of the present invention is to provide a cured product having an excellent edge shape, a color filter comprising the cured product, a method for producing the color filter, and a solid-state imaging element or an image display device, each of which comprising the color filter.

Means for achieving the foregoing objects include the following aspects.

<1> A curable composition comprising:

a particle; and

at least one polymer compound selected from the group consisting of a polymer compound represented by Formula I and having a specific absorbance E represented by Expression Aλ of less than 5 at a maximum absorption wavelength within a range of 400 nm to 800 nm, and a polymer compound represented by Formula II and having a specific absorbance E represented by Expression Aλ of less than 5 at a maximum absorption wavelength within a range of 400 nm to 800 nm,

Specific absorbance E=A/(c×L) Expression Aλ

in Expression Aλ, A represents an absorbance at the maximum absorption wavelength within the range of 400 nm to 800 nm, L represents an optical path length at a time of measuring the absorbance, which is expressed in cm, and c represents a concentration of the polymer compound in a solution, which is expressed in mg/mL.

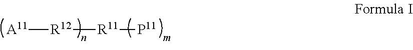

In Formula I, R¹¹ represents an (m+n)-valent organic linking group, A¹¹'s each independently represent a monovalent organic group containing at least one structure or group selected from the group consisting of an organic coloring agent structure, a heterocyclic structure, an acid group, a group having a basic nitrogen atom, a urea group, a urethane group, a group having a coordinating oxygen atom, a hydrocarbon group having 4 or more carbon atoms, an alkoxysilyl group, an epoxy group, an isocyanate group, and a hydroxy group, R¹²'s each independently represent a single bond or a divalent organic linking group, n represents 1.5 to 9, P¹¹ represents a polymer chain containing a constitutional unit having a polymerizable group, m represents 1 to 8.5, and m+n is 3 to 10.

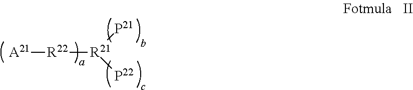

In Formula II, R²¹ represents an (a+b+c)-valent organic linking group, and A²¹ represents a monovalent organic group containing at least one moiety selected from an organic coloring agent structure, a heterocyclic structure, an acid group, a group having a basic nitrogen atom, a urea group, a urethane group, a group having a coordinating oxygen atom, a hydrocarbon group having 4 or more carbon atoms, an alkoxysilyl group, an epoxy group, an isocyanate group, or a hydroxyl group, R²² represents a single bond or a divalent organic linking group, a represents 0 to 8.5, b represents 1 to 10, c represents 1 to 8.5, a+b+c is 3 to 10, P²¹ represents a polymer chain having an acid value of 10 mgKOH/g or less and containing a constitutional unit having a polymerizable group, and P²² represents a polymer chain having an acid value of 20 mgKOH/g or more and containing a constitutional unit having an acid group.

<2> The curable composition according to <1>, in which the polymerizable group contained in P¹¹ and the polymerizable group contained in P²¹ include at least one selected from the group consisting of a (meth)acryloxy group, a (meth)acrylamide group, and a vinyl phenyl group.

<3> The curable composition according to <1> or <2>, in which P¹¹ further contains a constitutional unit having an acid group.

<4> The curable composition according to <3>, in which the constitutional unit having an acid group is represented by Formula A.

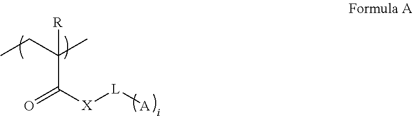

In Formula A, R represents a hydrogen atom or an alkyl group having 1 to 4 carbon atoms, X represents —O— or —NR^{N}— where R^{N} represents a hydrogen atom or an alkyl group having 1 to 4 carbon atoms, L represents an (i+1)-valent linking group, A represents an acid group, and i represents an integer of 1 to 3.

<5> The curable composition according to any one of <1> to <4>, in which a polymerizable group value in P²¹ is 0.01 mol/g to 6 mol/g.

<6> The curable composition according to any one of <1> to <5>, in which the particle includes at least one selected from the group consisting of a colorant and an infrared absorber.

<7> The curable composition according to any one of <1> to <6>, further comprising:
a photopolymerization initiator.

<8> The curable composition according to any one of <1> to <7>, further comprising: a polymerizable compound.

<9> A cured product obtained by curing the curable composition according to any one of <1> to <8>.

<10> A color filter comprising:

the cured product according to <9>.

<11> A method for producing a color filter, comprising:

applying the curable composition according to any one of <1> to <8> onto a support to form a composition film;

exposing the formed composition film in a pattern-wise manner; and

developing the composition film after exposure to form a pattern.

<12> A method for producing a color filter, comprising:

applying the curable composition according to any one of <1> to <8> onto a support and curing the applied curable composition to form a cured product;

forming a photoresist layer on the cured product;

exposing the photoresist layer in a pattern-wise manner and developing the exposed photoresist layer to form a resist pattern; and

etching the cured product through the resist pattern.

<13> A solid-state imaging element comprising:

the color filter according to <10>.

<14> An image display device comprising:

the color filter according to <10>.

According to an embodiment of the present invention, it is possible to provide a curable composition that provides an excellent edge shape in a pattern of a cured product thereof.

Further, according to another embodiment of the present invention, it is possible to provide a cured product having an excellent edge shape, a color filter comprising the cured product, a method for producing the color filter, and a solid-state imaging element or an image display device, each of which comprising the color filter.

### BRIEF DESCRIPTION OF THE DRAWINGS

FIG. 1 is a schematic diagram showing a measurement position of an undercut width in a cured product on a pattern in the Examples.

### DESCRIPTION OF THE PREFERRED EMBODIMENTS

Hereinafter, the contents of the present disclosure will be described in detail. The description of constituent elements described below may be based on representative embodiments of the present disclosure, but the present disclosure is not limited to such embodiments.

In the present disclosure, a term “to” indicating a numerical range is used as a meaning including numerical values described before and after the term as a lower limit value and an upper limit value, respectively.

Regarding a term, group (atomic group) in the present disclosure, a term with no description of “substituted” and “unsubstituted” includes both a group not having a substituent and a group having a substituent. For example, an “alkyl group” includes not only an alkyl group having no substituent (unsubstituted alkyl group), but also an alkyl group having a substituent (substituted alkyl group).

In the present disclosure, unless otherwise specified, “Me” represents a methyl group, “Et” represents an ethyl group, “Pr” represents a propyl group, “Bu” represents a butyl group, and “Ph” represents a phenyl group.

In the present specification, “(meth)acrylic” is a term used as a concept including both acrylic and methacrylic, and “(meth)acryloyl” is a term used as a concept including both acryloyl and methacryloyl.

In the present disclosure, a term “step” not only includes an independent step, but also includes a step, in a case where the step may not be clearly distinguished from the other step, as long as the expected object of the step is achieved.

In addition, in the present disclosure, “% by mass” is identical to “% by weight” and “parts by mass” is identical to “parts by weight”.

Further, in the present disclosure, a combination of two or more preferred aspects is a more preferred aspect.

In addition, unless otherwise noted, a weight-average molecular weight (Mw) and a number-average molecular weight (Mn) in the present disclosure are molecular weights obtained by conversion using polystyrene as a standard substance, following the detection by a gel permeation chromatography (GPC) analyzer using columns of TSKgel GMHxL, TSKgel G4000HxL, and TSKgel G2000HxL (all of which are trade names manufactured by Tosoh Corporation), using tetrahydrofuran (THF) as a solvent and a differential refractometer.

Hereinafter, the present disclosure will be described in detail.

(Curable Composition)

The curable composition according to the present disclosure (hereinafter, also referred to as “composition”) contains a particle; and at least one polymer compound selected from the group consisting of a polymer compound represented by Formula I and having a specific absorbance E represented by Expression Aλ of less than 5 at a maximum absorption wavelength within a range of 400 nm to 800 nm (hereinafter, also referred to as “first polymer compound”), and a polymer compound represented by Formula II and having a specific absorbance E represented by Expression Aλ of less than 5 at a maximum absorption wavelength within a range of 400 nm to 800 nm (hereinafter, also referred to as “second polymer compound”),

Specific absorbance E=A/(c×L) Expression Aλ

in Expression Aλ, A represents an absorbance at the maximum absorption wavelength within the range of 400 nm to 800 nm, L represents an optical path length at the time of measuring the absorbance, which is expressed in cm, and c represents a concentration of the polymer compound in a solution, which is expressed in mg/mL.

By using the curable composition according to the present disclosure, a cured product having an excellent edge shape in the pattern of the cured product to be obtained is obtained.

The reason why the above effect is obtained is unclear, but is estimated as follows.

In recent years, a pattern containing functional particles (organic pigments, inorganic pigments, or the like), such as a color filter, has been desired to increase the content of particles in the cured product in order to obtain a thinner cured product for the purpose of improving functionality. That is, in the curable composition for forming a color filter or the like, it is required to obtain a cured product with less curable compound.

In addition, in a case where a cured film is obtained by exposure from the side opposite to the substrate, generally the exposure side is strongly irradiated with light, and the light is attenuated toward the substrate side due to light absorption or light scattering by the compound. Since the deep portion is difficult to cure, curing on the substrate side is insufficient, a difference in the degree of curing between the substrate and the side opposite thereto may occur and therefore the pattern edge shape may be inclined with respect to the substrate. In a case where such a pattern having an inclined edge shape is used, it is known to adversely affect the second and third adjacent cured products and device performance, and therefore there is a need for improvement.

In the curable composition, for example, in order to improve the curing sensitivity by exposure or heat, it has been studied to increase the content of a polymerizable compound having a low molecular weight (for example, a molecular weight of less than 1,000) to improve the curability.

However, the present inventors have found that, according to the above method, although the curing sensitivity is improved, there is a problem that the edge shape in the pattern of the cured product to be obtained is deteriorated.

Therefore, as a result of extensive studies, the present inventors have found that the edge shape in the pattern of the cured product to be obtained is improved by using the curable composition according to the present disclosure.

Although the detailed mechanism by which the above effect is obtained is unknown, it is considered that the polymer compound according to the present disclosure is dispersed with the particles and is present in a state of being adsorbed and close to the particles. Therefore, it is speculated that the polymer compound according to the present disclosure is different from other curable compounds (a polyfunctional monomer and a polymer compound having a curable group) in the state of being. Therefore, in a case where the polymer compound according to the present disclosure is cured, it is considered that the particles can be more efficiently cured (fixed) because the polymer compound is adsorbed on the particles.

Similarly, in a case where the polymer compound according to the present disclosure is dissolved in a developer, it is considered that the uncured composition containing the particles is more efficiently removed because the polymer compound is adsorbed on the particles. For this reason, it is considered that the balance between the curing of the deep portion and the developability of the surface is maintained, and the pattern shape (in particular, the edge shape) is improved.

In addition, it is presumed that the acid group contained in A¹¹ in the first polymer compound and P²² in the second polymer compound is a binding site with the particles.

Here, it is considered that a curable composition having excellent long-term dispersion stability of the particles (for example, dispersion stability at 45° C. for 3 days) can be easily obtained since the binding site with the particles exists relatively biased at the position of A¹¹ or P²² in the molecule of the polymer compound, and therefore the phenomenon that the first polymer compound and the second polymer compound adsorb to different particles and cross-link between the particles is difficult to occur.

<Particle>

The particle used in the present disclosure is not particularly limited, and preferably includes a colorant, an infrared absorber, or a high refractive index material, more preferably at least one selected from the group consisting of a colorant and an infrared absorber, and still more preferably a colorant.

By using a colorant as the particle for use in the present disclosure, a curable composition for producing a cured product suitably used as, for example, a color filter or a black matrix provided between pixels of the color filter is obtained.

By using an infrared absorber as the particle for use in the present disclosure, a curable composition for producing a cured product suitably used as, for example, an infrared absorption filter is obtained.

By using a high refractive index material as the particle for use in the present disclosure, a curable composition for producing a cured product suitably used, for example, as a refractive index adjusting film is obtained.

[Colorant]

As the colorant, either a dye or a pigment may be used, or both thereof may be used in combination. Examples of the inorganic pigment include black pigments such as carbon black and titanium black; oxides of metals such as iron, cobalt, aluminum, cadmium, lead, copper, titanium, magnesium, chromium, zinc, and antimony, and metal complex salts. Examples of the organic pigment or inorganic pigment include the following.

Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, and 214 (all of which are yellow pigments);

C. I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, and 279 (all of which are red pigments);

C. I. Pigment Green 7, 10, 36, 37, 58, and 59 (all of which are green pigments); C. I. Pigment Violet 1, 19, 23, 27, 32, 37, 42, 58, and 59 (all of which are violet pigments); and

C. I. Pigment Blue 1, 2, 15, 15:1, 15:2, 15:3, 15:4, 15:6, 16, 22, 60, 64, 66, 79, and 80 (all of which are blue pigments).

In addition, a halogenated zinc phthalocyanine pigment having an average number of halogen atoms of 10 to 14, an average number of bromine atoms of 8 to 12, and an average number of chlorine atoms of 2 to 5 in the molecule can also be used as the green pigment. Specific examples of the green pigment include compounds described in WO2015/118720A.

In addition, an aluminum phthalocyanine compound having a phosphorus atom can also be used as the blue pigment. Specific examples of the blue pigment include compounds described in paragraphs [0022] to [0030] of JP2012-247591A and paragraph [0047] of JP2011-157478A.

The curable composition according to the present disclosure may contain a pigment derivative.

Examples of the pigment derivative include compounds having a structure in which a part of an organic pigment is substituted with an acidic group, a basic group, or a phthalimidomethyl group. Examples of the organic pigment for constituting the pigment derivative include a diketopyrrolopyrrole-based pigment, an azo-based pigment, a phthalocyanine-based pigment, an anthraquinone-based pigment, a quinacridone-based pigment, a dioxazine-based pigment, a perinone-based pigment, a perylene-based pigment, a thioindigo-based pigment, an isoindoline-based pigment, an isoindolinone-based pigment, a quinophthalone-based pigment, a threne-based pigment, and a metal complex-based pigment. In addition, the acidic group contained in the pigment derivative is preferably a sulfonic acid group, a carboxylic acid group, or a quaternary ammonium base thereof, more preferably a carboxylic acid group or a sulfonic acid group, and particularly preferably a sulfonic acid group. The basic group contained in the pigment derivative is preferably an amino group and particularly preferably a tertiary amino group. Specific examples of the pigment derivative include the following compounds. In addition, reference can be made to the description in paragraphs [0162] to [0183] of JP2011-252065A, the contents of which are incorporated herein by reference.

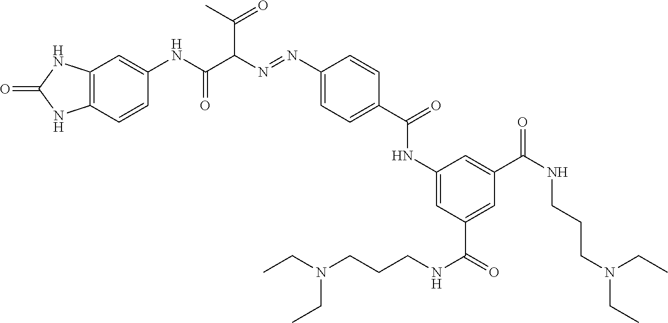 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

The colorants may be used alone or in combination of two or more thereof.

The content of the colorant is preferably 10% by mass to 80% by mass and more preferably 20% to 70% by mass with respect to the total solid content of the composition.

In the present disclosure, the total solid content refers to a total mass of components excluding the solvent in the curable composition.

[Infrared Absorber]

The infrared absorber is not particularly limited, and a known infrared absorber is used. For example, the infrared absorber is preferably a diiminium compound, a squarylium compound, a cyanine compound, a phthalocyanine compound, a naphthalocyanine compound, a quaterylene compound, an aminium compound, an iminium compound, an azo compound, an anthraquinone compound, a porphyrin compound, a pyrrolopyrrole compound, an oxonol compound, a croconium compound, a hexaphyrin compound, a metal dithiol compound, a copper compound, a tungsten compound, or a metal boride, more preferably a diiminium compound, a squarylium compound, a cyanine compound, a phthalocyanine compound, a naphthalocyanine compound, a quaterylene compound, a pyrrolopyrrole compound, a metal dithiol compound, a copper compound, or a tungsten compound, still more preferably a squarylium compound, a cyanine compound, a phthalocyanine compound, or a pyrrolopyrrole compound, and particularly preferably a squarylium compound or a pyrrolopyrrole compound.

Further examples of the infrared absorber include infrared absorbing pigments such as infrared absorbers described in JP2009-263614A, JP2011-068731A, WO2015/166873A, and the like. A specific example of the infrared absorber may be a compound having the following structure.

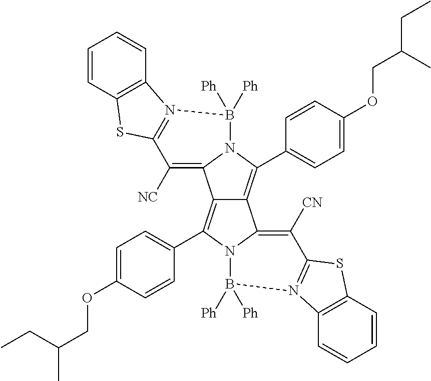

For example, the infrared absorber is preferably a compound having absorption in a wavelength range of 700 nm to 2000 nm and more preferably a compound having a maximum absorption wavelength in a wavelength range of 700 nm to 2000 nm.

The volume average particle diameter of the infrared absorber is preferably 0.01 μm to 0.1 μm and more preferably 0.01 μm to 0.05 μm.

The infrared absorbers may be used alone or in combination of two or more thereof.

In addition, the infrared absorber may be used in combination with the foregoing pigment.

The content of the infrared absorber is preferably 10% by mass to 80% by mass and more preferably 20% to 70% by mass with respect to the total solid content of the composition.

[High Refractive Index Material]

The high refractive index material is not particularly limited and may be a known high refractive index material. For example, metal oxide particles are preferable.

The metal oxide particles are preferably oxide particles containing atoms such as Be, Mg, Ca, Sr, Ba, Sc, Y, La, Ce, Gd, Tb, Dy, Yb, Lu, Ti, Zr, Hf, Nb, Mo, W, Zn, B, Al, Si, Ge, Sn, Pb, Sb, Bi, and Te; more preferably titanium oxide, titanium composite oxide, zinc oxide, zirconium oxide, indium tin oxide (ITO), or antimony tin oxide (ATO); still more preferably titanium oxide, titanium composite oxide, or zirconium oxide; particularly preferably titanium oxide or zirconium oxide; and most preferably titanium dioxide. The titanium dioxide is particularly preferably rutile titanium dioxide having a high refractive index. The surface of these metal oxide particles can be treated with an organic material in order to impart dispersion stability.

From the viewpoint of transparency of the curable composition, an average primary particle diameter of the high refractive index material is preferably 1 nm to 200 nm and particularly preferably 3 nm to 80 nm. Here, the average primary particle diameter of the particles refers to an arithmetic average of values obtained by measuring particle diameters of any 200 particles with an electron microscope. In a case where the particle shape is not spherical, the maximum diameter is defined as the particle diameter.

In addition, the high refractive index materials may be used alone or in combination of two or more thereof.

The content of the high refractive index material in the curable composition according to the present disclosure may be appropriately determined in consideration of the refractive index, light transmittance, and the like required for an optical member obtained from the curable composition. The content of the high refractive index material is preferably 5% by mass to 80% by mass and more preferably 10% by mass to 70% by mass with respect to the total solid content of the curable composition according to the present disclosure.

<First Polymer Compound>

The curable composition according to the present disclosure preferably contains a first polymer compound.

The first polymer compound is a polymer compound represented by Formula I and having a specific absorbance E represented by Expression Aλ of less than 5 at a maximum absorption wavelength within a range of 400 nm to 800 nm.

The polymer compound in the present disclosure refers to a compound having a weight-average molecular weight of 1000 or more, preferably 2000 or more, and more preferably 5000 or more.

In addition, the first polymer compound has a polymerizable group in the structure thereof. The polymerizable group is preferably an ethylenically unsaturated group. From the viewpoint of the pattern cross-sectional shape and the adhesiveness to the substrate, the ethylenically unsaturated group is preferably a vinyl phenyl group, a (meth)acrylamide group, or a (meth)acryloxy group, more preferably a (meth)acrylamide group or a (meth)acryloxy group, and most preferably a (meth)acryloxy group.

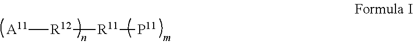

In Formula I, R¹¹ represents an (m+n)-valent organic linking group, A¹¹'s each independently represent a monovalent organic group containing at least one structure or group selected from the group consisting of an organic coloring agent structure, a heterocyclic structure, an acid group, a group having a basic nitrogen atom, a urea group, a urethane group, a group having a coordinating oxygen atom, a hydrocarbon group having 4 or more carbon atoms, an alkoxysilyl group, an epoxy group, an isocyanate group, and a hydroxy group, R¹²'s each independently represent a single bond or a divalent organic linking group, n represents 1.5 to 9, P^{H}'s each independently represent a polymer chain containing a constitutional unit having a polymerizable group, m represents 1 to 8.5, and m+n is 3 to 10.

[A¹¹]

In Formula I, n number of A¹¹'s may be the same as or different from one another.

Hereinafter, the at least one structure or group selected from the group consisting of an organic coloring agent structure, a heterocyclic structure, an acid group, a group having a basic nitrogen atom, a urea group, a urethane group, a group having a coordinating oxygen atom, a hydrocarbon group having 4 or more carbon atoms, an alkoxysilyl group, an epoxy group, an isocyanate group, and a hydroxy group in A¹¹ is referred to as an “adsorption site”, which will be described.

At least one adsorption site may be contained in one A¹¹, or two or more adsorption sites may be contained in one A¹¹.

In the present disclosure, the “monovalent organic group containing at least one adsorption site” is a monovalent organic group formed by bonding the above-mentioned adsorption site to an organic linking group consisting of 1 to 200 carbon atoms, 0 to 20 nitrogen atoms, 0 to 100 oxygen atoms, 1 to 400 hydrogen atoms, and 0 to 40 sulfur atoms. In a case where the adsorption site itself can constitute a monovalent organic group, the adsorption site itself may be a monovalent organic group represented by A¹¹.

First, the adsorption site constituting A¹¹ will be described hereinafter.

The “organic coloring agent structure” may be, for example, preferably a phthalocyanine-based coloring agent structure, an insoluble azo-based coloring agent structure, an azo lake-based coloring agent structure, an anthraquinone-based coloring agent structure, a quinacridone-based coloring agent structure, a dioxazine-based coloring agent structure, a diketopyrrolopyrrole-based coloring agent structure, an anthrapyridine-based coloring agent structure, an anthanthrone-based coloring agent structure, an indanthrone-based coloring agent structure, a flavanthrone-based coloring agent structure, a perinone-based coloring agent structure, a perylene-based coloring agent structure, or a thioindigo-based coloring agent structure; more preferably a phthalocyanine-based coloring agent structure, an azo lake-based coloring agent structure, an anthraquinone-based coloring agent structure, a dioxazine-based coloring agent structure, or a diketopyrrolopyrrole-based coloring agent structure; and particularly preferably a phthalocyanine-based coloring agent structure, an anthraquinone-based coloring agent structure, or a diketopyrrolopyrrole-based coloring agent structure.

The “heterocyclic structure” may be a group having at least one or more heterocyclic rings. The heteroatom in the “heterocyclic structure” preferably includes at least one 0 (oxygen atom), N (nitrogen atom), or S (sulfur atom), and more preferably at least one nitrogen atom.

For example, the heterocyclic ring in the “heterocyclic structure” is preferably a heterocyclic ring selected from the group consisting of thiophene, furan, xanthene, pyrrole, pyrroline, pyrrolidine, dioxolane, pyrazole, pyrazoline, pyrazolidine, imidazole, oxazole, thiazole, oxadiazole, triazole, thiadiazole, pyran, pyridine, piperidine, dioxane, morpholine, pyridazine, pyrimidine, piperazine, triazine, trithiane, isoindoline, isoindolinone, benzimidazolone, benzothiazole, succinimide, phthalimide, naphthalimide, hydantoin, indole, quinoline, carbazole, acridine, acridone, and anthraquinone; and more preferably a heterocyclic ring selected from the group consisting of pyrroline, pyrrolidine, pyrazole, pyrazoline, pyrazolidine, imidazole, triazole, pyridine, piperidine, morpholine, pyridazine, pyrimidine, piperazine, triazine, isoindoline, isoindolinone, benzimidazolone, benzothiazole, succinimide, phthalimide, naphthalimide, hydantoin, carbazole, acridine, acridone, and anthraquinone.

The “organic coloring agent structure” or “heterocyclic structure” may further have a substituent, and examples of the substituent include an alkyl group having 1 to 20 carbon atoms such as a methyl group or an ethyl group; an aryl group having 6 to 16 carbon atoms such as a phenyl group or a naphthyl group; a hydroxyl group; an amino group; a carboxyl group; a sulfonamide group; an N-sulfonylamide group; an acyloxy group having 1 to 6 carbon atoms such as an acetoxy group; an alkoxy group having 1 to 20 carbon atoms such as a methoxy group or an ethoxy group; a halogen atom such as a chlorine atom or a bromine atom; an alkoxycarbonyl group having 2 to 7 carbon atoms such as a methoxycarbonyl group, an ethoxycarbonyl group, or a cyclohexyloxycarbonyl group; a cyano group; and a carbonic acid ester group such as a t-butyl carbonate group. Here, these substituents may be bonded to the organic coloring agent structure or the heterocyclic ring through a linking group constituted by combining the following structural units or the foregoing structural units.

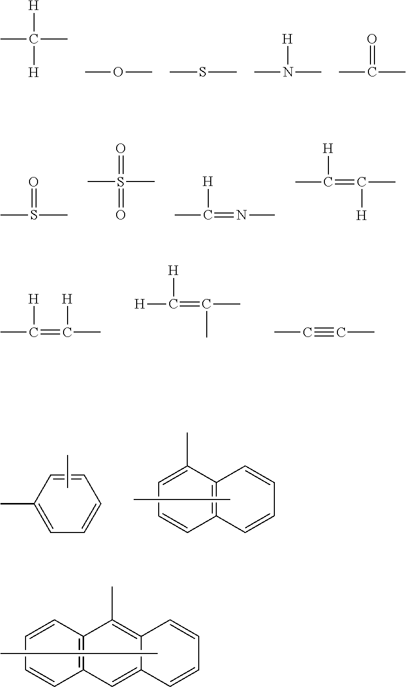

For example, the “acid group” is preferably a carboxylic acid group, a sulfonic acid group, a monosulfate group, a phosphoric acid group, a monophosphate group, or a boric acid group; more preferably a carboxylic acid group, a sulfonic acid group, a monosulfate group, a phosphoric acid group, or a monophosphate group; and particularly preferably a carboxylic acid group, a sulfonic acid group, or a phosphoric acid group.

For example, the “group having a basic nitrogen atom” is preferably an amino group (—NH₂) or a substituted imino group (—NHR⁸ or —NR⁹R¹⁰ in which R⁸, R⁹, and R¹⁰) each independently represent an alkyl group having 1 to 20 carbon atoms, an aryl group having 6 or more carbon atoms, or an aralkyl group having 7 or more carbon atoms, among which an alkyl group having 1 to 20 carbon atoms, an aryl group having 6 to 20 carbon atoms, or an aralkyl group having 7 to 20 carbon atoms is preferable).

Preferred examples of the group having a basic nitrogen atom include a guanidyl group represented by Formula (a1) and an amidinyl group represented by Formula (a2).

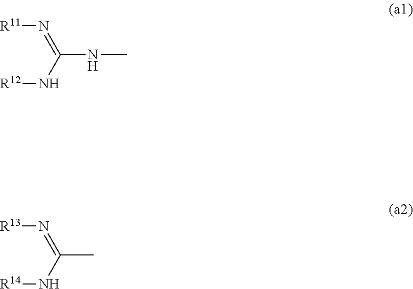

In Formula (a1), R¹¹ and R¹² each independently represent an alkyl group having 1 to 20 carbon atoms, an aryl group having 6 to 20 carbon atoms, or an aralkyl group having 7 or more carbon atoms.

In Formula (a2), R¹³ and R¹⁴ each independently represent an alkyl group having 1 to 20 carbon atoms, an aryl group having 6 to 20 carbon atoms, or an aralkyl group having 7 or more carbon atoms.

Among these, an amino group (—NH₂), a substituted imino group (—NHR⁸ or —NR⁹R¹⁰ in which R⁸, R⁹, and R¹⁰ each independently represent an alkyl group having 1 to 10 carbon atoms, a phenyl group, or a benzyl group), a guanidyl group represented by Formula (a1) [in Formula (a1), and R¹² each independently represent an alkyl group having 1 to 10 carbon atoms, a phenyl group, or a benzyl group], an amidinyl group represented by Formula (a2) [in Formula (a2), R¹³ and R¹⁴ each independently represent an alkyl group having 1 to 10 carbon atoms, a phenyl group, or a benzyl group], or the like is more preferable.

In particular, an amino group (—NH₂), a substituted imino group (—NHR⁸ or —NR⁹R¹⁰ in which R⁸, R⁹, and R¹⁰ each independently represent an alkyl group having 1 to 5 carbon atoms, a phenyl group, or a benzyl group), a guanidyl group represented by Formula (a1) [in Formula (a1), and R¹² each independently represent an alkyl group having 1 to 5 carbon atoms, a phenyl group, or a benzyl group], an amidinyl group represented by Formula (a2) [in Formula (a2), R¹³ and R¹⁴ each independently represent an alkyl group having 1 to 5 carbon atoms, a phenyl group, or a benzyl group], or the like is preferably used.

The “urea group” is, for example, preferably —NR¹⁵CONR¹⁶R¹⁷ (in which R¹⁵, R¹⁶, and R¹⁷ each independently represent a hydrogen atom, an alkyl group having 1 to 20 carbon atoms, an aryl group having 6 or more carbon atoms, or an aralkyl group having 7 or more carbon atoms); more preferably —NR¹⁵CONHR¹⁷ (in which R¹⁵ and R¹⁷ each independently represent a hydrogen atom, an alkyl group having 1 to 20 carbon atoms, an aryl group having 6 to 20 carbon atoms, or an aralkyl group having 7 to 20 carbon atoms, among which an alkyl group having 1 to 10 carbon atoms, an aryl group having 6 to 20 carbon atoms, or an aralkyl group having 7 to 20 carbon atoms is preferable); and particularly preferably —NHCONHR¹⁷ (in which R¹⁷ represents a hydrogen atom, an alkyl group having 1 to 10 carbon atoms, an aryl group having 6 or more carbon atoms, or an aralkyl group having 7 or more carbon atoms, among which an alkyl group having 1 to 10 carbon atoms, an aryl group having 6 to 20 carbon atoms, or an aralkyl group having 7 to 20 carbon atoms is preferable).

The “urethane group” is, for example, preferably —NHCOOR¹⁸, —NR¹⁹COOR²⁰, —OCONHR²¹, or —OCONR²²R²³ (in which R¹⁸, R¹⁹, R²⁰, R²¹, R²², and R²³ each independently represent an alkyl group having 1 to 20 carbon atoms, an aryl group having 6 or more carbon atoms, or an aralkyl group having 7 or more carbon atoms, among which an alkyl group having 1 to 20 carbon atoms, an aryl group having 6 to 20 carbon atoms, or an aralkyl group having 7 to 20 carbon atoms is preferable); more preferably —NHCOOR¹⁸ or —OCONHR²¹ (in which R¹⁸ and R²¹ each independently represent an alkyl group having 1 to 20 carbon atoms, an aryl group having 6 or more carbon atoms, or an aralkyl group having 7 or more carbon atoms, among which an alkyl group having 1 to 20 carbon atoms, an aryl group having 6 to 20 carbon atoms, or an aralkyl group having 7 to 20 carbon atoms is preferable); and particularly preferably —NHCOOR¹⁸ or —OCONHR²¹ (in which R¹⁸ and R²¹ each independently represent an alkyl group having 1 to 10 carbon atoms, an aryl group having 6 to 12 carbon atoms, or an aralkyl group having 7 to 10 carbon atoms).

Examples of the “group having a coordinating oxygen atom” include an acetylacetonato group and a group having a crown ether structure.

The “hydrocarbon group having 4 or more carbon atoms” is, for example, preferably an alkyl group having 4 or more carbon atoms, an aryl group having 6 or more carbon atoms, or an aralkyl group having 7 or more carbon atoms; more preferably an alkyl group having 4 to 20 carbon atoms, an aryl group having 6 to 20 carbon atoms, or an aralkyl group having 7 to 20 carbon atoms; and particularly preferably an alkyl group having 4 to 15 carbon atoms (for example, an octyl group or a dodecyl group), an aryl group having 6 to 15 carbon atoms (for example, a phenyl group or a naphthyl group), or an aralkyl group having 7 to 15 carbon atoms (for example, a benzyl group).

Examples of the “alkoxysilyl group” include a trimethoxysilyl group and a triethoxysilyl group.

The organic linking group bonded to the adsorption site is preferably a single bond or an organic linking group consisting of 1 to 100 carbon atoms, 0 to 10 nitrogen atoms, 0 to 50 oxygen atoms, 1 to 200 hydrogen atoms, and 0 to 20 sulfur atoms, and this organic linking group may be unsubstituted or may further have a substituent.

Specific examples of such an organic linking group include groups constituted by combining the following structural units or the foregoing structural units.

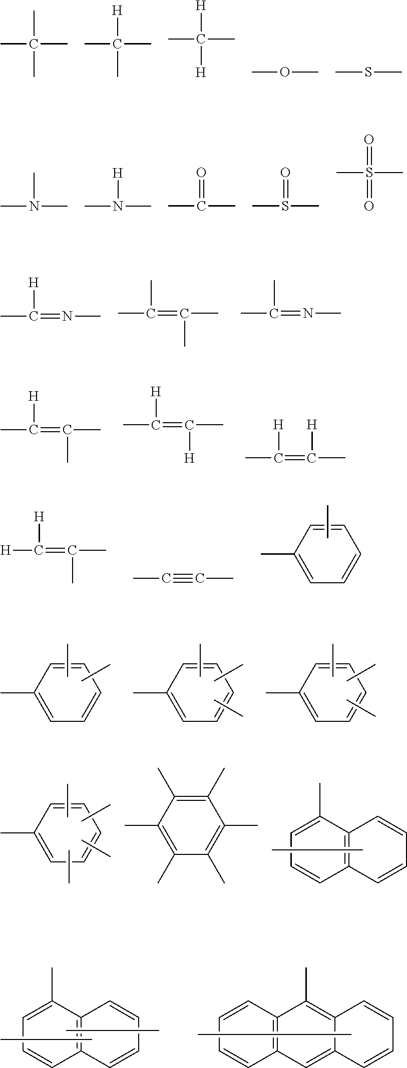

In a case where the organic linking group has a substituent, examples of the substituent include an alkyl group having 1 to 20 carbon atoms such as a methyl group or an ethyl group; an aryl group having 6 to 16 carbon atoms such as a phenyl group or a naphthyl group; a hydroxyl group; an amino group; a carboxyl group; a sulfonamide group; an N-sulfonylamide group; an acyloxy group having 1 to 6 carbon atoms such as an acetoxy group; an alkoxy group having 1 to 6 carbon atoms such as a methoxy group or an ethoxy group; a halogen atom such as a chlorine atom or a bromine atom; an alkoxycarbonyl group having 2 to 7 carbon atoms such as a methoxycarbonyl group, an ethoxycarbonyl group, or a cyclohexyloxycarbonyl group; a cyano group; and a carbonic acid ester group such as a t-butyl carbonate group.

Among the above, A¹¹ is preferably a monovalent organic group containing at least one moiety selected from an organic coloring agent structure, a heterocyclic structure, an acid group, a group having a basic nitrogen atom, a urea group, and a hydrocarbon group having 4 or more carbon atoms.

A¹¹ is more preferably a monovalent organic group represented by General Formula (4).

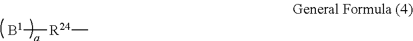

In General Formula (4), B¹ represents an adsorption site (that is, a partial structure selected from the group consisting of an organic coloring agent structure, a heterocyclic structure, an acid group, a group having a basic nitrogen atom, a urea group, a urethane group, a group having a coordinating oxygen atom, a hydrocarbon group having 4 or more carbon atoms, an alkoxysilyl group, an epoxy group, an isocyanate group, and a hydroxyl group), and R²⁴ represents a single bond or an (a+1)-valent organic linking group. a represents an integer of 1 to 10, and a number of B¹'s in Formula (4) may be the same as or different from one another.

Examples of the adsorption site represented by B¹ include the same as the adsorption site constituting A¹¹ of Formula I, and preferred examples thereof are also the same.

Above all, a moiety selected from the group consisting of an organic coloring agent structure, a heterocyclic structure, an acid group, a group having a basic nitrogen atom, a urea group, and a hydrocarbon group having 4 or more carbon atoms is preferable.

R²⁴ represents a single bond or an (a+1)-valent organic linking group, and a represents an integer of 1 to 10. a is preferably an integer of 1 to 7, more preferably an integer of 1 to 5, and particularly preferably an integer of 1 to 3.

The (a+1)-valent organic linking group includes a group consisting of 1 to 100 carbon atoms, 0 to 10 nitrogen atoms, 0 to 50 oxygen atoms, 1 to 200 hydrogen atoms, and 0 to 20 sulfur atoms, which may be unsubstituted or may further have a substituent.

Specific examples of the (a+1)-valent organic linking group include the structural units described as specific examples of the foregoing organic linking group, and groups (which may form a ring structure) constituted by combining or the foregoing structural units.

R²⁴ is preferably a single bond or an (a+1)-valent organic linking group consisting of 1 to 50 carbon atoms, 0 to 8 nitrogen atoms, 0 to 25 oxygen atoms, 1 to 100 hydrogen atoms, and 0 to 10 sulfur atoms; more preferably a single bond or an (a+1)-valent organic linking group consisting of 1 to 30 carbon atoms, 0 to 6 nitrogen atoms, 0 to 15 oxygen atoms, 1 to 50 hydrogen atoms, and 0 to 7 sulfur atoms; and particularly preferably a single bond or an (a+1)-valent organic linking group consisting of 1 to 10 carbon atoms, 0 to 5 nitrogen atoms, 0 to 10 oxygen atoms, 1 to 30 hydrogen atoms, and 0 to 5 sulfur atoms.

Among the above, in a case where the (a+1)-valent organic linking group has a substituent, examples of the substituent include an alkyl group having 1 to 20 carbon atoms such as a methyl group or an ethyl group; an aryl group having 6 to 16 carbon atoms such as a phenyl group or a naphthyl group; a hydroxyl group; an amino group; a carboxyl group; a sulfonamide group; an N-sulfonylamide group; an acyloxy group having 1 to 6 carbon atoms such as an acetoxy group; an alkoxy group having 1 to 6 carbon atoms such as a methoxy group or an ethoxy group; a halogen atom such as a chlorine atom or a bromine atom; an alkoxycarbonyl group having 2 to 7 carbon atoms such as a methoxycarbonyl group, an ethoxycarbonyl group, or a cyclohexyloxycarbonyl group; a cyano group; and a carbonic acid ester group such as a t-butyl carbonate group.

[R¹²]

In Formula I, R¹² represents a single bond or a divalent organic linking group. n number of R¹²'s may be the same as or different from one another.

The divalent organic linking group includes a group consisting of 1 to 100 carbon atoms, 0 to 10 nitrogen atoms, 0 to 50 oxygen atoms, 1 to 200 hydrogen atoms, and 0 to 20 sulfur atoms, which may be unsubstituted or may further have a substituent.

Specific examples of the divalent organic linking group include the following structural units and groups constituted by combining the following structural units.

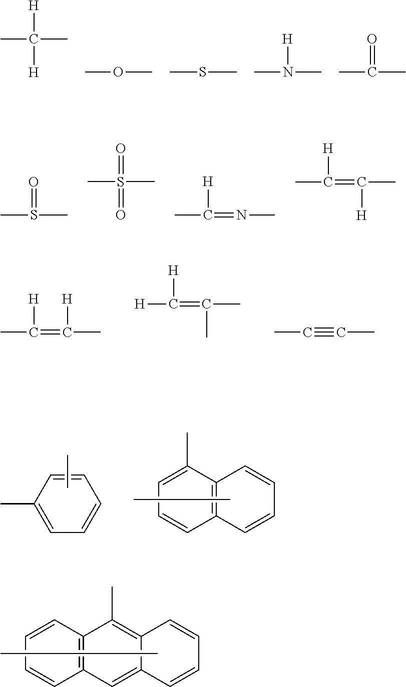

R¹² is preferably a single bond or a divalent organic linking group consisting of 1 to 50 carbon atoms, 0 to 8 nitrogen atoms, 0 to 25 oxygen atoms, 1 to 100 hydrogen atoms, and 0 to 10 sulfur atoms; more preferably a single bond or a divalent organic linking group consisting of 1 to 30 carbon atoms, 0 to 6 nitrogen atoms, 0 to 15 oxygen atoms, 1 to 50 hydrogen atoms, and 0 to 7 sulfur atoms; and particularly preferably a single bond or a divalent organic linking group consisting of 1 to 10 carbon atoms, 0 to 5 nitrogen atoms, 0 to 10 oxygen atoms, 1 to 30 hydrogen atoms, and 0 to 5 sulfur atoms.

Among the above, in a case where the divalent organic linking group has a substituent, examples of the substituent include an alkyl group having 1 to 20 carbon atoms such as a methyl group or an ethyl group; an aryl group having 6 to 16 carbon atoms such as a phenyl group or a naphthyl group; a hydroxyl group; an amino group; a carboxyl group; a sulfonamide group; an N-sulfonylamide group; an acyloxy group having 1 to 6 carbon atoms such as an acetoxy group; an alkoxy group having 1 to 6 carbon atoms such as a methoxy group or an ethoxy group; a halogen atom such as a chlorine atom or a bromine atom; an alkoxycarbonyl group having 2 to 7 carbon atoms such as a methoxycarbonyl group, an ethoxycarbonyl group, or a cyclohexyloxycarbonyl group; a cyano group; and a carbonic acid ester group such as a t-butyl carbonate group.

[R¹¹]

In Formula I, represents an (m+n)-valent organic linking group. m+n satisfies 3 to 10.

Examples of the (m+n)-valent organic linking group represented by R¹¹ include groups consisting of 1 to 100 carbon atoms, 0 to 10 nitrogen atoms, 0 to 50 oxygen atoms, 1 to 200 hydrogen atoms, and 0 to 20 sulfur atoms, which may be unsubstituted or may further have a substituent.

Specific examples of the (m+n)-valent organic linking group include groups (which may form a ring structure) constituted by combining the following structural units or the foregoing structural units.

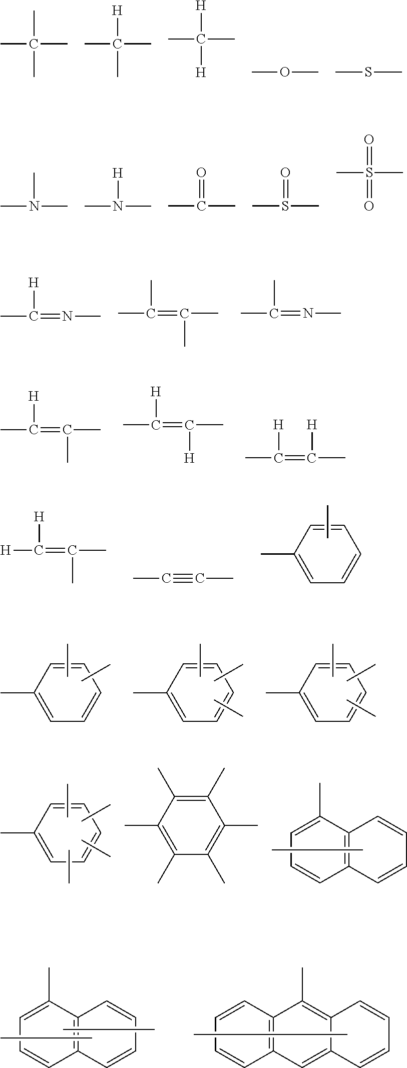

The (m+n)-valent organic linking group is preferably a group consisting of 1 to 60 carbon atoms, 0 to 10 nitrogen atoms, 0 to 40 oxygen atoms, 1 to 120 hydrogen atoms, and 0 to 10 sulfur atoms; more preferably a group consisting of 1 to 50 carbon atoms, 0 to 10 nitrogen atoms, 0 to 30 oxygen atoms, 1 to 100 hydrogen atoms, and 0 to 7 sulfur atoms; and particularly preferably a group consisting of 1 to 40 carbon atoms, 0 to 8 nitrogen atoms, 0 to 20 oxygen atoms, 1 to 80 hydrogen atoms, and 0 to 5 sulfur atoms.

Among the above, in a case where the (m+n)-valent organic linking group has a substituent, examples of the substituent include an alkyl group having 1 to 20 carbon atoms such as a methyl group or an ethyl group; an aryl group having 6 to 16 carbon atoms such as a phenyl group or a naphthyl group; a hydroxyl group; an amino group; a carboxyl group; a sulfonamide group; an N-sulfonylamide group; an acyloxy group having 1 to 6 carbon atoms such as an acetoxy group; an alkoxy group having 1 to 6 carbon atoms such as a methoxy group or an ethoxy group; a halogen atom such as a chlorine atom or a bromine atom; an alkoxycarbonyl group having 2 to 7 carbon atoms such as a methoxycarbonyl group, an ethoxycarbonyl group, or a cyclohexyloxycarbonyl group; a cyano group; and a carbonic acid ester group such as a t-butyl carbonate group.

Specific examples [specific examples (1) to (17)] of the (m+n)-valent organic linking group represented by R¹¹ are shown below. However, the present disclosure is not limited thereto.

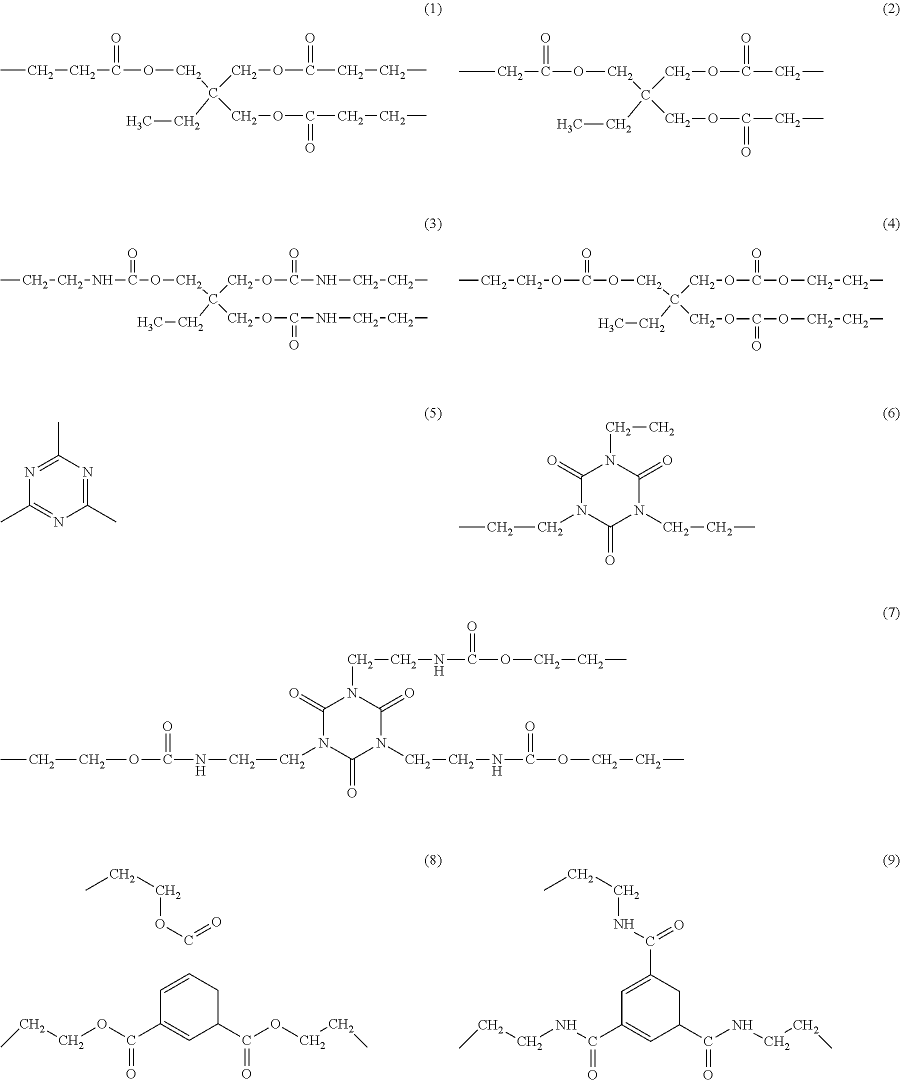

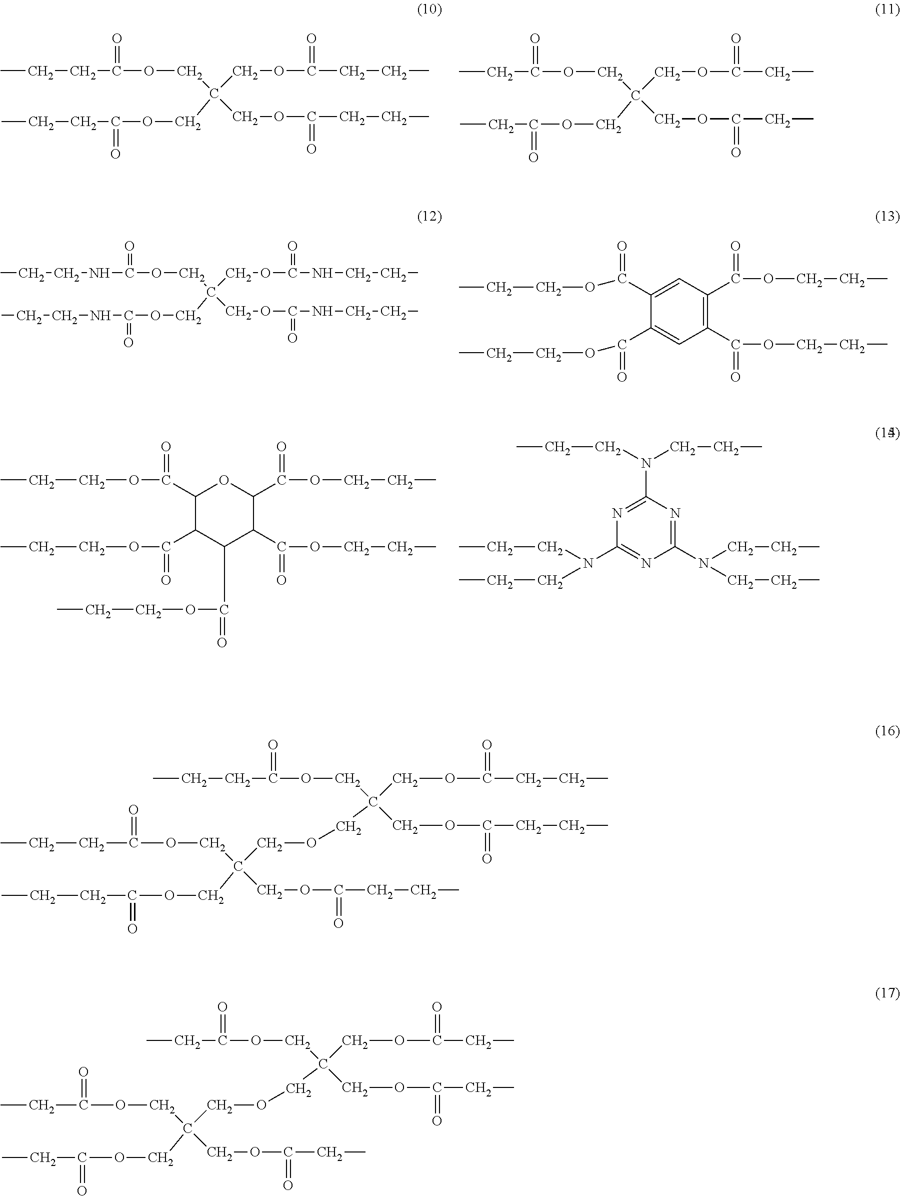

Among the above-mentioned specific examples, the most preferable (m+n)-valent organic linking group is the following groups from the viewpoint of availability of raw materials, ease of synthesis, and solubility in various solvents.

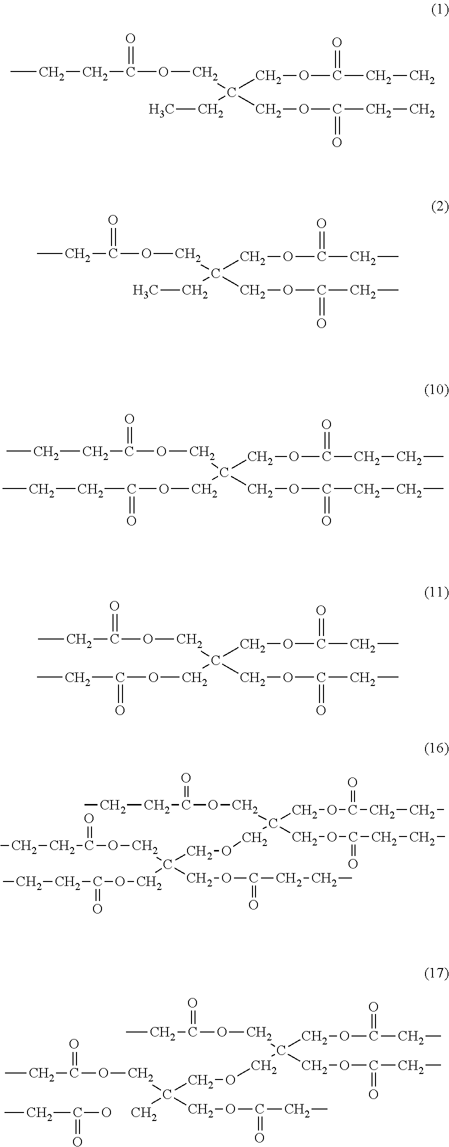

[P¹¹]

In Formula I, P¹¹ represents a polymer chain, which can be selected from known polymers according to the purpose and the like. m number of P¹¹'s may be the same as or different from one another.

In the present disclosure, the polymer chain refers to a molecular chain having a molecular weight of 1,000 or more, preferably a molecular chain having a molecular weight of 2,000 or more, and more preferably a molecular chain having a molecular weight of 5,000 or more.

Among the polymers, the polymer for constituting a polymer chain is preferably at least one selected from the group consisting of a homopolymer or copolymer of vinyl monomers, an ester-based polymer, an ether-based polymer, a urethane-based polymer, an amide-based polymer, an epoxy-based polymer, a silicone-based polymer, and a modification product or copolymer thereof [for example, a polyether/polyurethane copolymer, or a copolymer of a polymer of polyether/vinyl monomer (which may be any of a random copolymer, a block copolymer, and a graft copolymer, among which a random copolymer is more preferable)]; more preferably at least one selected from the group consisting of a homopolymer or copolymer of vinyl monomers, an ester-based polymer, an ether-based polymer, a urethane-based polymer, and a modification product or copolymer thereof; and particularly preferably a polymer or copolymer of vinyl monomers.

Further, the polymer is preferably soluble in an organic solvent. In a case where the polymer has a low affinity for the organic solvent, the affinity for a dispersion medium becomes low in a case where the polymer is used as a pigment dispersant, whereby a sufficient adsorption layer required for dispersion stabilization may not be secured.

The vinyl monomer is not particularly limited and examples thereof are preferably (meth)acrylic acid esters, crotonic acid esters, vinyl esters, maleic acid diesters, fumaric acid diesters, itaconic acid diesters, (meth)acrylamides, styrenes, vinyl ethers, vinyl ketones, olefins, maleimides, (meth)acrylonitriles, and vinyl monomers having an acid group.

Hereinafter, preferred examples of these vinyl monomers will be described.

Examples of (meth)acrylic acid esters include methyl (meth)acrylate, ethyl (meth)acrylate, n-propyl (meth)acrylate, isopropyl (meth)acrylate, n-butyl (meth)acrylate, isobutyl (meth)acrylate, t-butyl (meth)acrylate, amyl (meth)acrylate, n-hexyl (meth)acrylate, cyclohexyl (meth)acrylate, t-butyl cyclohexyl (meth)acrylate, 2-ethylhexyl (meth)acrylate, t-octyl (meth)acrylate, dodecy (meth)acrylate, octadecyl (meth)acrylate, acetoxyethyl (meth)acrylate, phenyl (meth)acrylate, 2-hydroxy ethyl (meth)acrylate, 2-hydroxypropyl (meth)acrylate, 3-hydroxypropyl (meth)acrylate, 4-hydroxybutyl (meth)acrylate, 2-methoxyethyl (meth)acrylate, 2-ethoxyethyl (meth)acrylate, 2-(2-methoxyethoxy)ethyl (meth)acrylate, 3-phenoxy-2-hydroxypropyl (meth)acrylate, 2-chloroethyl (meth)acrylate, glycidyl (meth)acrylate, 3,4-epoxycyclohexylmethyl (meth)acrylate, vinyl (meth)acrylate, 2-phenylvinyl (meth)acrylate, 1-propenyl (meth)acrylate, allyl (meth)acrylate, 2-aryloxyethyl (meth)acrylate, propargyl (meth)acrylate, benzyl (meth)acrylate, diethylene glycol monomethyl ether (meth)acrylate, diethylene glycol monoethyl ether (meth)acrylate, triethylene glycol monomethyl ether (meth)acrylate, triethylene glycol monoethyl ether (meth)acrylate, polyethylene glycol monomethyl ether (meth)acrylate, polyethylene glycol monoethyl ether (meth)acrylate, β-phenoxyethoxyethyl (meth)acrylate, nonylphenoxy polyethylene glycol (meth)acrylate, dicyclopentenyl (meth)acrylate, dicyclopentenyloxyethyl (meth)acrylate, trifluoroethyl (meth)acrylate, octafluoropentyl (meth)acrylate, perfluorooctylethyl (meth)acrylate, dicyclopentanyl (meth)acrylate, tribromophenyl (meth)acrylate, tribromophenyloxyethyl (meth)acrylate, and γ-butyrolactone (meth)acrylate.

Examples of crotonic acid esters include butyl crotonate and hexyl crotonate.

Examples of vinyl esters include vinyl acetate, vinylchloro acetate, vinyl propionate, vinyl butyrate, vinyl methoxyacetate, and vinyl benzoate.

Examples of maleic acid diesters include dimethyl maleate, diethyl maleate, and dibutyl maleate.

Examples of fumaric acid diesters include dimethyl fumarate, diethyl fumarate, and dibutyl fumarate.

Examples of itaconic acid diesters include dimethyl itaconate, diethyl itaconate, and dibutyl itaconate.

Examples of (meth)acrylamides include (meth)acrylamide, N-methyl (meth)acrylamide, N-ethyl (meth)acrylamide, N-propyl (meth)acrylamide, N-isopropyl (meth)acrylamide, N-n-butyl (meth)acrylamide, N-t-butyl (meth)acrylamide, N-cyclohexyl (meth)acrylamide, N-(2-methoxy ethyl) (meth)acrylamide, N,N-dimethyl (meth)acrylamide, N,N-diethyl (meth)acrylamide, N-phenyl (meth)acrylamide, N-nitrophenyl acrylamide, N-ethyl-N-phenyl acrylamide, N-benzyl (meth)acrylamide, (meth)acryloyl morpholine, diacetone acrylamide, N-methylol acrylamide, N-hydroxyethyl acrylamide, vinyl (meth)acrylamide, N,N-diallyl (meth)acrylamide, and N-allyl (meth)acrylamide.

Examples of styrenes include styrene, methyl styrene, dimethyl styrene, trimethyl styrene, ethyl styrene, isopropyl styrene, butyl styrene, hydroxy styrene, methoxy styrene, buthoxy styrene, acetoxy styrene, chlorostyrene, dichlorostyrene, bromostyrene, chloromethylstyrene, hydroxystyrene protected by a group deprotectable with an acidic substance (for example, t-Boc), vinyl methylbenzoate, and α-methylstyrene.

Examples of vinyl ethers include methyl vinyl ether, ethyl vinyl ether, 2-chloroethyl vinyl ether, hydroxyethyl vinyl ether, propyl vinyl ether, butyl vinyl ether, hexyl vinyl ether, octyl vinyl ether, methoxyethyl vinyl ether, and phenyl vinyl ether.

Examples of vinyl ketones include methyl vinyl ketone, ethyl vinyl ketone, propyl vinyl ketone, and phenyl vinyl ketone.

Examples of olefins include ethylene, propylene, isobutylene, butadiene, and isoprene.

Examples of maleimides include maleimide, butyl maleimide, cyclohexyl maleimide, and phenyl maleimide.

(Meth)acrylonitrile, a heterocyclic group substituted with a vinyl group (for example, vinyl pyridine, N-vinyl pyrrolidone, or vinyl carbazole), N-vinyl formamide, N-vinyl acetamide, N-vinyl imidazole, vinyl caprolactone, and the like may also be used.

In addition to the above compounds, for example, a vinyl monomer having a functional group such as a urethane group, a urea group, a sulfonamide group, a phenol group, or an imide group may also be used. Such a monomer having a urethane group or a urea group may be appropriately synthesized, for example, using an addition reaction of an isocyanate group with a hydroxyl group or an amino group. Specifically, the monomer may be appropriately synthesized using the addition reaction of a monomer containing an isocyanate group with a compound having one hydroxyl group or a compound containing one primary or secondary amino group, or the addition reaction of a monomer containing a hydroxyl group or a monomer containing a primary or secondary amino group with monoisocyanate.

—Polymerizable Group—

P¹¹ in the present disclosure includes a constitutional unit having a polymerizable group.

The polymerizable group is not particularly limited and is preferably an ethylenically unsaturated group.

The method for introducing a constitutional unit having a polymerizable group is not particularly limited, and examples thereof include polymer reactions such as a method of forming a polymer chain containing a constitutional unit having a carboxyl group and then reacting the carboxyl group with a compound having a polymerizable group such as an epoxy group or a (meth)acryloxy group; a method of forming a polymer chain having a constitutional unit having a hydroxy group and then reacting the hydroxy group with a compound having a polymerizable group such as an isocyanate group or a (meth)acryloxy group; a method of forming a polymer chain containing a halogen atom and then desorbing a hydrogen halide to form a double bond; and a method of forming a polymer chain containing a constitutional unit having a carboxyl group and then reacting the formed polymer chain with a compound containing a halogenated alkyl group and a polymerizable group.

The polymerizable group contained in is not particularly limited, and from the viewpoint of the pattern cross-sectional shape and the adhesiveness to the substrate, preferably includes at least one selected from the group consisting of a (meth)acryloxy group, a (meth)acrylamide group, and a vinyl phenyl group; more preferably at least one selected from the group consisting of a (meth)acrylamide group and a (meth)acryloxy group; and most preferably a (meth)acryloxy group.

The constitutional unit having a polymerizable group in P″ is preferably a constitutional unit represented by any one of Formula B-1, B-2, B-3, or B-4.

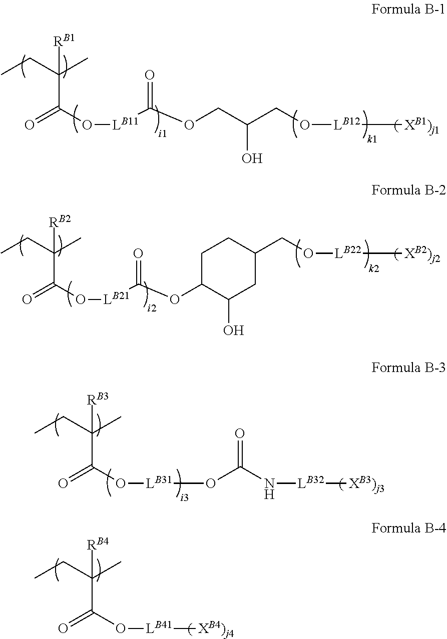

—Formula B-1—

In Formula B-1, R^{B1} represents a hydrogen atom or a methyl group, L^{B11}'s each independently represent a divalent hydrocarbon group, i1 represents an integer of 0 to 20, and L^{B12} represents a (j1+1)-valent hydrocarbon group. k1 represents 0 or 1, j1 represents an integer of 1 to 10, X^{B1}'s each independently represent a structure represented by Formula X-1 or X-2, and in a case where k1 is 0, j1 is 1.

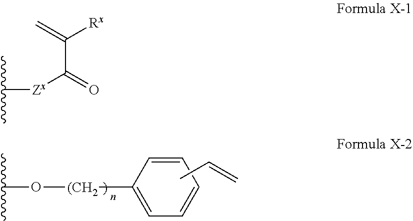

In Formula X-1, R^{x} represents a hydrogen atom or a methyl group, and Z′ represents —O— or —NR^{x}— in which R^{x} represents a hydrogen atom or an alkyl group.

Z′ is preferably —O—.

R^{x} is preferably a hydrogen atom.

In Formula X-2, n represents an integer of 0 to 4, and is preferably 0 or 1.

In Formula X-1 and Formula X-2, the wavy line represents a binding site with another structure.

In Formula B-1, L^{B11}'s are each independently preferably an alkylene group having 1 to 20 carbon atoms or an arylene group having 6 to 20 carbon atoms, more preferably an alkylene group having 1 to 20 carbon atoms, and still more preferably an alkylene group having 2 to 10 carbon atoms.

In Formula B-1, i1 is preferably an integer of 0 to 10.

In Formula B-1, L^{B12} is preferably a (j1+1)-valent aliphatic hydrocarbon group and more preferably a (j1+1)-valent saturated aliphatic hydrocarbon group. In addition, the aliphatic hydrocarbon group preferably has 1 to 20 carbon atoms and more preferably 2 to 10 carbon atoms.

In Formula B-1, j1 is preferably an integer of 1 to 5, more preferably 1 or 2, and still more preferably 1.

—Formula B-2—

In Formula B-2, R^{B2} represents a hydrogen atom or a methyl group, L^{B21}'s each independently represent a divalent hydrocarbon group, i2 represents an integer of 0 to 20, L^{B22} represents a (j2+1)-valent hydrocarbon group, k2 represents 0 or 1, j2 represents an integer of 1 to 10, X^{B2}'s each independently represent a structure represented by Formula X-1 or Formula X-2, and in a case where k2 is 0, j2 is 1.

In Formula B-2, L^{B21}'s are each independently preferably an alkylene group having 1 to 20 carbon atoms or an arylene group having 6 to 20 carbon atoms, more preferably an alkylene group having 1 to 20 carbon atoms, and still more preferably an alkylene group having 2 to 10 carbon atoms.

In Formula B-2, i2 is preferably an integer of 0 to 10.

In Formula B-2, L^{B22} is preferably a (j2+1)-valent aliphatic hydrocarbon group and more preferably a (j2+1)-valent saturated aliphatic hydrocarbon group. In addition, the aliphatic hydrocarbon group preferably has 1 to 20 carbon atoms and more preferably 2 to 10 carbon atoms.

In Formula B-2, j2 is preferably an integer of 1 to 5, more preferably 1 or 2, and still more preferably 1.

—Formula B-3—

In Formula B-3, R^{B3} represents a hydrogen atom or a methyl group, L^{B31}'s each independently represent a divalent hydrocarbon group, i3 represents an integer of 1 to 20, L^{B32} represents a (j3+1)-valent hydrocarbon group, j3 represents an integer of 1 to 10, and X^{B3}'s each independently represent a structure represented by Formula X-1 or Formula X-2.

In Formula B-3, L^{B31}'s each independently represent a divalent hydrocarbon group, preferably an alkylene group having 1 to 20 carbon atoms or an arylene group having 6 to 20 carbon atoms, more preferably an alkylene group having 1 to 20 carbon atoms, still more preferably an alkylene group having 2 to 10 carbon atoms, and particularly preferably an ethylene group, a 1-methylethylene group, or a 2-methylethylene group.

In Formula B-3, i3 is preferably an integer of 1 to 10.

In Formula B-3, L^{B32} is preferably a (j3+1)-valent aliphatic hydrocarbon group and more preferably a (j3+1)-valent saturated aliphatic hydrocarbon group. In addition, the aliphatic hydrocarbon group preferably has 1 to 20 carbon atoms and more preferably 2 to 10 carbon atoms.

In Formula B-3, j3 is preferably an integer of 1 to 5, more preferably 1 or 2, and still more preferably 1.

—Formula B-4—

In Formula B-4, L^{B41} represents a (j4+1)-valent hydrocarbon group, j4 represents an integer of 1 to 10, and X^{B4}'s each independently represent a structure represented by Formula X-1 or Formula X-2.

In Formula B-4, L^{B41} is preferably a (j4+1)-valent aliphatic hydrocarbon group and more preferably a (j4+1)-valent saturated aliphatic hydrocarbon group. In addition, the aliphatic hydrocarbon group preferably has 1 to 20 carbon atoms and more preferably 2 to 10 carbon atoms.

In Formula B-4, j4 is preferably an integer of 1 to 5, more preferably 1 or 2, and still more preferably 1.

The structure according to Formula B-1 or Formula B-2 is obtained, for example, by reacting a polymerizable group-containing epoxy compound with a polymer chain having a constitutional unit derived from an acid group-containing monomer.

Examples of the acid group-containing monomer include, but are not limited to, methacrylic acid, acrylic acid, ω-carboxy-polycaprolactone (n=2) monoacrylate (ARONIX M-5300), 2-methacryloyloxyethyl succinate (LIGHT ESTER HO-MS), 2-acryloyloxyethyl hexahydrophthalate (LIGHT ESTER HOA-HH), 2-acryloyloxyethyl phthalate (LIGHT ESTER HOA-MPL), 4-(4-(acryloyloxy)butoxy)benzoic acid, 12-methacrylamidododecanoic acid, β-carboxyethyl acrylate, and styrene carboxylate.

Examples of the polymerizable group-containing epoxy compound include, but are not limited to, glycidyl acrylate, glycidyl methacrylate, 4-hydroxybutyl acrylate glycidyl ether, (7-oxabicyclo[4.1.0]heptan-3-yl)methyl acrylate, (7-oxabicyclo[4.1.0]heptan-3-yl)methyl methacrylate, 9-(oxiran-2-yl)nonyl acrylate, 2-methyl-2-(((oxiran-2-ylmethoxy)carbonyl)amino)propane-1,3-diyl diacrylate, 6-acrylamide hexanoic acid glycidyl ester, and N-methyl-N-hydroxyethyl acrylamide glycidyl ether.

In addition, the structure according to Formula B-3 is be obtained, for example, by reacting an isocyanate group-containing compound with a polymer chain having a constitutional unit derived from a hydroxyl group-containing monomer.

Examples of the hydroxyl group-containing monomer include, but are not limited to, hydroxyethyl methacrylate, hydroxyethyl (meth)acrylamide, hydroxypropyl (meth)acrylate, hydroxybutyl (meth)acrylate, polypropylene glycol mono(meth)acrylate, poly(ethylene glycol-propylene glycol) mono(meth)acrylate, poly(ethylene glycol-tetramethylene glycol) mono(meth)acrylate, poly(propylene glycol-tetramethylene glycol) mono(meth)acrylate, propylene glycol polybutylene glycol) mono(meth)acrylate, vinyl benzyl alcohol, 2-hydroxy-3-phenoxypropyl acrylate, and 2-methacryloyloxyethyl 2-hydroxypropyl phthalate.

Examples of the isocyanate group-containing compound include, but are not limited to, acryloyloxyethoxyethyl isocyanate (KARENZ AOI), methacryloyloxyethyl isocyanate (KARENZ MOI), 1,1-bis(acryloyloxymethyl)ethyl isocyanate (KARENZ BEI), and methacryloyloxyethoxyethyl isocyanate (KARENZ MOI-EG).

In addition, the structure according to Formula B-4 is obtained by forming a polymer chain containing a constitutional unit derived from a monomer containing a halogen atom and then desorbing a hydrogen halide.

Further, the structure according to Formula B-4 is obtained by reacting a polymer chain containing a constitutional unit derived from an acid group-containing monomer with a compound containing a halogenated alkyl group and a polymerizable group.

Examples of the monomer containing a halogen atom include, but are not limited to, 2-((3-chloropropanoyl)oxy)ethyl methacrylate and 2-((2-bromo-2-methylpropanoyl)oxy)ethyl methacrylate.

Examples of the method for introducing a polymerizable group in addition to B-1 to B-4 include a method in which a halogenated alkyl group-containing monomer is reacted with a polymer chain having a constitutional unit derived from an acid group-containing monomer.

Examples of the acid group-containing monomer include, but are not limited to, the acid group-containing monomers described in the structure according to Formula B-1 or Formula B-2 described above.

Examples of the compound containing a halogenated alkyl group and a polymerizable group include, but are not limited to, 4-chloromethylstyrene.

Specific examples of the constitutional unit having a polymerizable group in P¹¹ include, but are not limited to, constitutional units having a polymerizable group in the following polymer compounds 1 to 10.

The polymerizable group value in P¹¹ is preferably 0.1 mol/g to 6.0 mol/g and more preferably 0.3 mol/g to 5.0 mol/g from the viewpoint of the pattern cross-sectional shape and the adhesiveness to the substrate.

In the present disclosure, the polymerizable group value of the polymer chain is calculated, for example, by adding an aqueous sodium hydroxide solution to a polymer solution, confirming from ¹H-NMR that the peak of the polymerizable group introduced into the polymer has disappeared, and then quantifying the amount of monomer generated by decomposition of the polymer by means of HPLC. —Acid group—

P¹¹ preferably further contains a constitutional unit having an acid group.

The acid group is, for example, preferably a carboxylic acid group, a sulfonic acid group, a monosulfate group, a phosphoric acid group, a monophosphate group, a boric acid group, or a phenolic hydroxyl group; more preferably a carboxylic acid group, a sulfonic acid group, a monosulfate group, a phosphoric acid group, or a monophosphate group; still more preferably a carboxylic acid group, a sulfonic acid group, or a phosphoric acid group; and particularly preferably a carboxylic acid group.

The constitutional unit having an acid group is preferably a constitutional unit represented by Formula A.

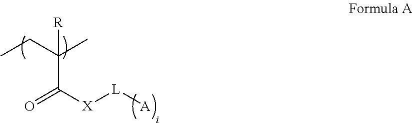

In Formula A, R represents a hydrogen atom or an alkyl group having 1 to 4 carbon atoms, X represents —O— or —NR^{N}— in which R^{N} represents a hydrogen atom or an alkyl group having 1 to 4 carbon atoms, L represents an (i+1)-valent linking group, A represents an acid group, and i represents an integer of 1 to 3.

In Formula A, R is preferably a hydrogen atom or a methyl group.

In Formula A, X is preferably —O— or —NH— and more preferably —O—.

In Formula A, L represents an (i+1)-valent linking group, and is preferably a group obtained by removing i+1 number of hydrogen atoms from a hydrocarbon, or a polyester structure having a carboxyl group at the terminal thereof.

The hydrocarbon is preferably an aliphatic hydrocarbon and more preferably a saturated aliphatic hydrocarbon.

The polyester structure is preferably a polylactone structure or a polyhydroxycarboxylic acid ester structure. In addition, the polyester structure is preferably a polyester structure formed by an alkylene group and an ester bond. The alkylene group is preferably an alkylene group having 1 to 10 carbon atoms.

In Formula A, A represents an acid group, preferably a carboxylic acid group, a sulfonic acid group, a monosulfate group, a phosphoric acid group, a monophosphate group, a boric acid group, or a hydroxyphenyl group; more preferably a carboxylic acid group, a sulfonic acid group, a monosulfate group, a phosphoric acid group, or a monophosphate group; still more preferably a carboxylic acid group, a sulfonic acid group, or a phosphoric acid group; and particularly preferably a carboxylic acid group.

In Formula A, i represents an integer of 1 to 3, and is preferably 1 or 2.

The acid group is introduced into the polymer chain by using a vinyl monomer having an acid group.

Examples of the vinyl monomer having an acid group include a vinyl monomer having a carboxyl group and a vinyl monomer having a sulfonic acid group.

Examples of the vinyl monomer having a carboxyl group include (meth)acrylic acid, vinyl benzoic acid, maleic acid, maleic acid monoalkyl ester, fumaric acid, itaconic acid, crotonic acid, cinnamic acid, and acrylic acid dimer. In addition, a product of an addition reaction of a monomer having a hydroxyl group such as 2-hydroxyethyl (meth)acrylate with a cyclic anhydride such as a maleic acid anhydride, a phthalic acid anhydride, or a cyclohexanedicarboxylic acid anhydride, ω-carboxypolycaprolactone mono(meth)acrylate, and the like can also be used. In addition, a monomer containing an anhydride such as a maleic acid anhydride, an itaconic acid anhydride, or a citraconic acid anhydride may also be used as a precursor of a carboxyl group. Of these, (meth)acrylic acid is particularly preferable from the viewpoint of copolymerizability, cost, solubility, and the like.

Examples of the vinyl monomer having an acid group include, but are not limited to, methacrylic acid, acrylic acid, ω-carboxy-polycaprolactone (n2) monoacrylate (ARONIX M-5300), 2-methacryloyloxyethyl succinate (LIGHT ESTER HO-MS), 2-acryloyloxyethyl hexahydrophthalate (LIGHT ESTER HOA-HH), 2-acryloyloxyethyl phthalate (LIGHT ESTER HOA-MPL), 4-(4-(acryloyloxy)butoxy)benzoic acid, 12-methacrylamidododecanoic acid, β-carboxyethyl acrylate, and styrene carboxylate.

Examples of the vinyl monomer having a sulfonic acid group include 2-acrylamido-2-methylpropanesulfonic acid. Examples of the vinyl monomer having a phosphoric acid group include mono(2-acryloyloxyethyl) phosphate and mono(1-methyl-2-acryloyloxyethyl) phosphate.

Further, a vinyl monomer containing a phenolic hydroxy group or a vinyl monomer containing a sulfonamide group can also be used as the vinyl monomer having an acid group.

In a case where P¹¹ includes a constitutional unit having an acid group, the content of the constitutional unit having an acid group in the polymer skeleton is preferably 3% by mass to 40% by mass and more preferably 5% by mass to 20% by mass in terms of mass with respect to the entire polymer chain.

[m and n]

In Formula I, m represents 1 to 8.5, preferably 2 to 6, more preferably 3 to 6, and still more preferably 4 to 6.

In Formula I, n represents 1.5 to 9, preferably 2 to 8, more preferably 2 to 7, and still more preferably 3 to 6.

In addition, m+n is preferably 3 to 10 and more preferably 4 to 10.

In a case where m is 3 or more, the generation of residues during development is likely to be suppressed.

This is presumed to be because, in a case where m is 3 or more, the entanglement of the polymer chains in the first polymer compound is suppressed and therefore the solubility in the developer is improved.

In addition, in a case where m is 3 or more, a curable composition having excellent curability is easily obtained.

This is presumed to be because, in a case where m is 3 or more, the occurrence of an intramolecular polymerization reaction (intramolecular crosslinking) in the first polymer compound is suppressed and therefore an intermolecular polymerization reaction is likely to proceed.

[Polymer Compound Represented by General Formula (2)]

Among the polymer compounds represented by Formula I, a polymer compound represented by General Formula (2) is preferable.

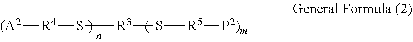

In General Formula (2), A² represents a monovalent organic group containing at least one moiety selected from an organic coloring agent structure, a heterocyclic structure, an acid group, a group having a basic nitrogen atom, a urea group, a urethane group, a group having a coordinating oxygen atom, a hydrocarbon group having 4 or more carbon atoms, an alkoxysilyl group, an epoxy group, an isocyanate group, and a hydroxyl group. n number of A²'s may be the same as or different from one another.

In addition, A² has the same definition as A¹¹ in General Formula I and a preferred aspect thereof is also the same.

In General Formula (2), R⁴ and R⁵ each independently represent a single bond or a divalent organic linking group. n number of R⁴'s may be the same as or different from one another. m number of R⁵'s may be the same as or different from one another.

As the divalent organic linking group represented by R⁴ or R⁵, the same divalent organic linking groups as those represented by R¹² in Formula I can be used, and a preferred aspect thereof is also the same.

In General Formula (2), R³ represents an (m+n)-valent organic linking group. m+n satisfies 3 to 10.

Examples of the (m+n)-valent organic linking group represented by R³ include groups consisting of 1 to 60 carbon atoms, 0 to 10 nitrogen atoms, 0 to 50 oxygen atoms, 1 to 100 hydrogen atoms, and 0 to 20 sulfur atoms, which may be unsubstituted or may further have a substituent.

Specifically, the (m+n)-valent organic linking group represented by R³ is the same as the (m+n)-valent organic linking group represented by in Formula I and a preferred aspect thereof is also the same.

In General Formula (2), m represents 1 to 8. m is preferably 1 to 5, more preferably 1 to 4, and particularly preferably 1 to 3.

In General Formula (2), n represents 2 to 9. n is preferably 2 to 8, more preferably 2 to 7, and particularly preferably 3 to 6.

P² in General Formula (2) represents a polymer skeleton, which can be selected from known polymers according to the purpose and the like. m number of P²'s may be the same as or different from one another. A preferred aspect of the polymer is the same as that of in Formula I.

Among the polymer compounds represented by General Formula (2), those satisfying all of R³, R⁴, R⁵, P², m, and n shown below are most preferable.

R³: specific example (1), (2), (10), (11), (16), or (17) above

R⁴: a single bond or a divalent organic linking group constituted by combining the following structural units or the foregoing structural units and consisting of “1 to 10 carbon atoms, 0 to 5 nitrogen atoms, 0 to 10 oxygen atoms, 1 to 30 hydrogen atoms, and 0 to 5 sulfur atoms” (which may have a substituent, examples of which include: an alkyl group having 1 to 20 carbon atoms such as a methyl group or an ethyl group; an aryl group having 6 to 16 carbon atoms such as a phenyl group or a naphthyl group; a hydroxyl group; an amino group; a carboxyl group; a sulfonamide group; an N-sulfonylamide group; an acyloxy group having 1 to 6 carbon atoms such as an acetoxy group; an alkoxy group having 1 to 6 carbon atoms such as a methoxy group or an ethoxy group; a halogen atom such as a chlorine atom or a bromine atom; an alkoxycarbonyl group having 2 to 7 carbon atoms such as a methoxycarbonyl group, an ethoxycarbonyl group, or a cyclohexyloxycarbonyl group; a cyano group; and a carbonic acid ester group such as a t-butyl carbonate group).

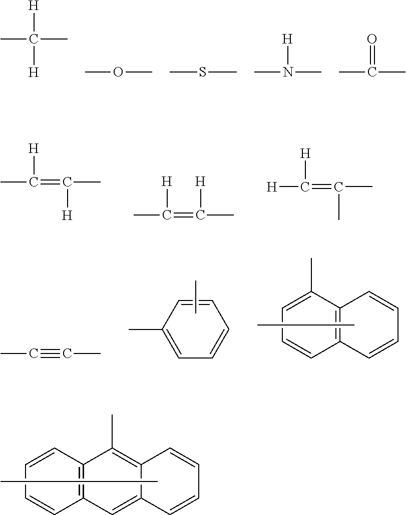

R⁵: a single bond, an ethylene group, a propylene group, a group (a) given below, or a group (b) given below

In the following groups, R¹² represents a hydrogen atom or a methyl group, and 1 represents 1 or 2.

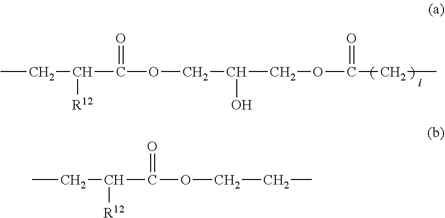

P²: a polymer or copolymer of vinyl monomers, an ester-based polymer, an ether-based polymer, a urethane-based polymer, or a modification product thereof

m: 1 to 3

n: 3 to 6

[Physical Properties of First Polymer Compound]

The acid value of the first polymer compound in the present disclosure is not particularly limited, and is preferably 10 to 200 (mgKOH/g), more preferably 15 to 150 (mgKOH/g), and particularly preferably 50 to 120 (mg KOH/g) from the viewpoint of developability.

In the present specification, the acid value of a compound is measured by the following titration method.

The acid value represents the mass of potassium hydroxide required to neutralize acidic components per gram of solid content. A measurement sample is dissolved in a tetrahydrofuran/water=9/1 (mass ratio) mixed solvent, and the resulting solution is neutralized and titrated with a 0.1 mol/L aqueous sodium hydroxide solution at 25° C. using a potentiometric titrator (trade name: AT-510, manufactured by Kyoto Electronics Manufacturing Co., Ltd.). The acid value is calculated in accordance with the following expression using an inflection point of a titration pH curve as a titration end point.

A=56.11×Vs×0.1×f/w

A: acid value (mgKOH/g)

Vs: amount (mL) of 0.1 mol/L aqueous sodium hydroxide solution required for titration

f: titer of 0.1 mol/L aqueous sodium hydroxide solution

w: measurement sample mass (g) (in terms of solid content)

The polymerizable group value of the first polymer compound in the present disclosure is preferably 0.1 mmol/g or more and more preferably 0.3 mmol/g or more, from the viewpoint of the pattern cross-sectional shape and the adhesiveness to the substrate. The upper limit of the polymerizable group value is not particularly limited and is preferably 5 mmol/g or less.

In the present disclosure, the polymerizable group value of the polymer chain is calculated, for example, by adding an aqueous sodium hydroxide solution to a polymer solution, confirming from ¹H-NMR that the peak of the polymerizable group introduced into the polymer has disappeared, and then quantifying the amount of monomer generated by decomposition of the polymer by means of HPLC.

The molecular weight of the first polymer compound in the present disclosure is preferably 3000 to 100000, more preferably 5000 to 80000, and particularly preferably 7000 to 60000 in terms of weight-average molecular weight from the viewpoint of dispersibility and dispersion stability in the curable composition.

The first polymer compound is a polymer compound having a specific absorbance E represented by Expression Aλ of less than 5 at a maximum absorption wavelength within a range of 400 nm to 800 nm.

Specific absorbance E=A/(c×L) Expression Aλ

In Expression Aλ, A represents an absorbance at the maximum absorption wavelength within the range of 400 nm to 800 nm, L represents an optical path length at the time of measuring the absorbance, which is expressed in cm, and c represents a concentration of a polymer compound of a coloring agent in a solution, which is expressed in mg/mL.

The specific absorbance is measured by dissolving the first polymer compound in tetrahydrofuran (THF), adjusting the concentration of the resulting solution such that the maximum absorbance at a wavelength of 400 nm to 800 nm is 1.0, and measuring the absorbance at 25° C. of the solution using a cell having an optical path length of 1 cm and using a measurement apparatus (Cary 5000 UV-Vis-NIR spectrophotometer, manufactured by Agilent Technologies, Inc.).

The specific absorbance E is preferably 0 to 4 and more preferably 0 to 3.

[Synthesis Method]

The polymer compound represented by Formula I (including the polymer compound represented by General Formula (2)) is not particularly limited, and can be synthesized by a method of introducing a polymerizable group by the foregoing polymer reaction into the polymer compound synthesized by any one of the following methods 1 to 5.

1. A method in which a polymer having a functional group selected from a carboxyl group, a hydroxyl group, an amino group, and the like introduced at the terminal thereof is polymerized with an acid halide having a plurality of the foregoing adsorption sites, an alkyl halide having a plurality of the foregoing adsorption sites, or an isocyanate having a plurality of the foregoing adsorption sites.

2. A method in which a Michael addition reaction is carried out between a polymer having a carbon-carbon double bond introduced at the terminal thereof and a mercaptan having a plurality of the foregoing adsorption sites.

3. A method in which a polymer having a carbon-carbon double bond introduced at the terminal thereof is reacted with a mercaptan having the foregoing adsorption site in the presence of a radical generator.

4. A method in which a polymer having a plurality of mercaptans introduced at the terminal thereof is reacted with a compound having a carbon-carbon double bond and the foregoing adsorption site in the presence of a radical generator.

5. A method in which vinyl monomers are radically polymerized in the presence of a mercaptan compound having a plurality of the foregoing adsorption sites.

Among the above, the method for synthesizing the polymer compound according to the present disclosure is preferably the synthesis method 2, 3, 4, or 5 and more preferably the synthesis method 3, 4, or 5, from the viewpoint of ease of synthesis. In particular, in a case where the polymer compound according to the present disclosure has a structure represented by General Formula (2), it is most preferable to synthesize the polymer compound by the synthesis method 5, from the viewpoint of ease of synthesis.

More specifically, the synthesis method 5 is preferably a method in which vinyl monomers are radically polymerized in the presence of a compound represented by General Formula (3).

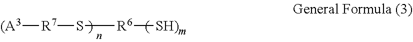

In General Formula (3), R⁶, R⁷, A³, m, and n have the same definition as R³, R⁴, A², m, and n in General Formula (2), respectively and preferred aspects thereof are also the same.

The compound represented by General Formula (3) can be synthesized by the following methods or the like, but the following method 7 is more preferable from the viewpoint of ease of synthesis.

6. A method in which a halide compound having a plurality of the foregoing adsorption sites is converted into a mercaptan compound (examples of which includes a method in which the halide compound is reacted with thiourea and the resulting reaction product is hydrolyzed; a method in which the halide compound is directly reacted with NaSH; and a method in which the halide compound is reacted with CH₃COSNa and the resulting reaction product is hydrolyzed) 7. A method in which an addition reaction is carried out between a compound having 3 to 10 mercapto groups in one molecule and a compound having the foregoing adsorption site and having a functional group capable of reacting with a mercapto group

Suitable examples of the “functional group capable of reacting with a mercapto group” in the synthesis method 7 include an acid halide, an alkyl halide, an isocyanate, and a carbon-carbon double bond.

It is particularly preferable that the “functional group capable of reacting with a mercapto group” is a carbon-carbon double bond, and the addition reaction is a radical addition reaction. The carbon-carbon double bond is more preferably a mono- or di-substituted vinyl group from the viewpoint of reactivity with a mercapto group.

Specific examples [specific examples (18) to (34)] of the compound having 3 to 10 mercapto groups in one molecule include the following compounds.

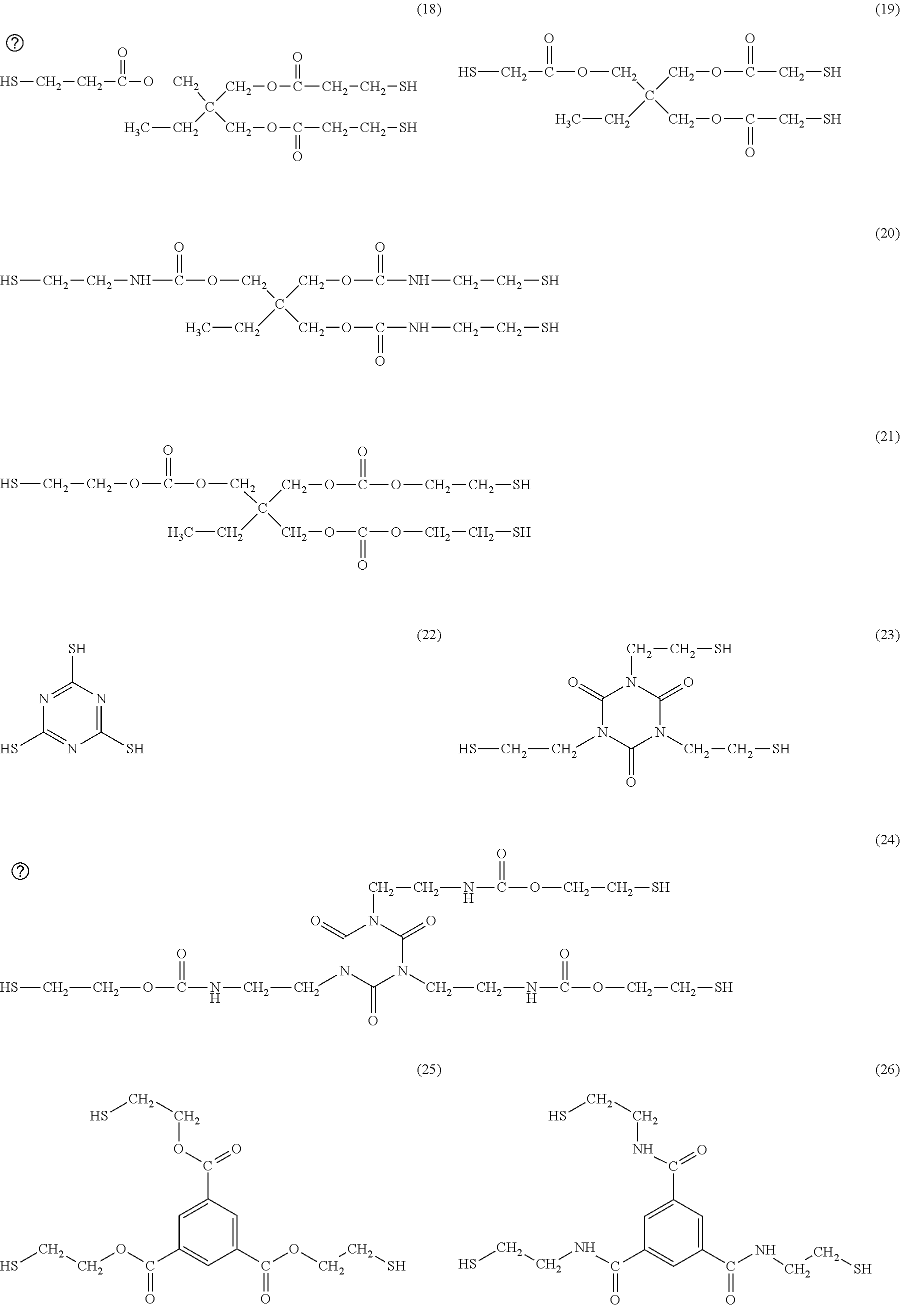

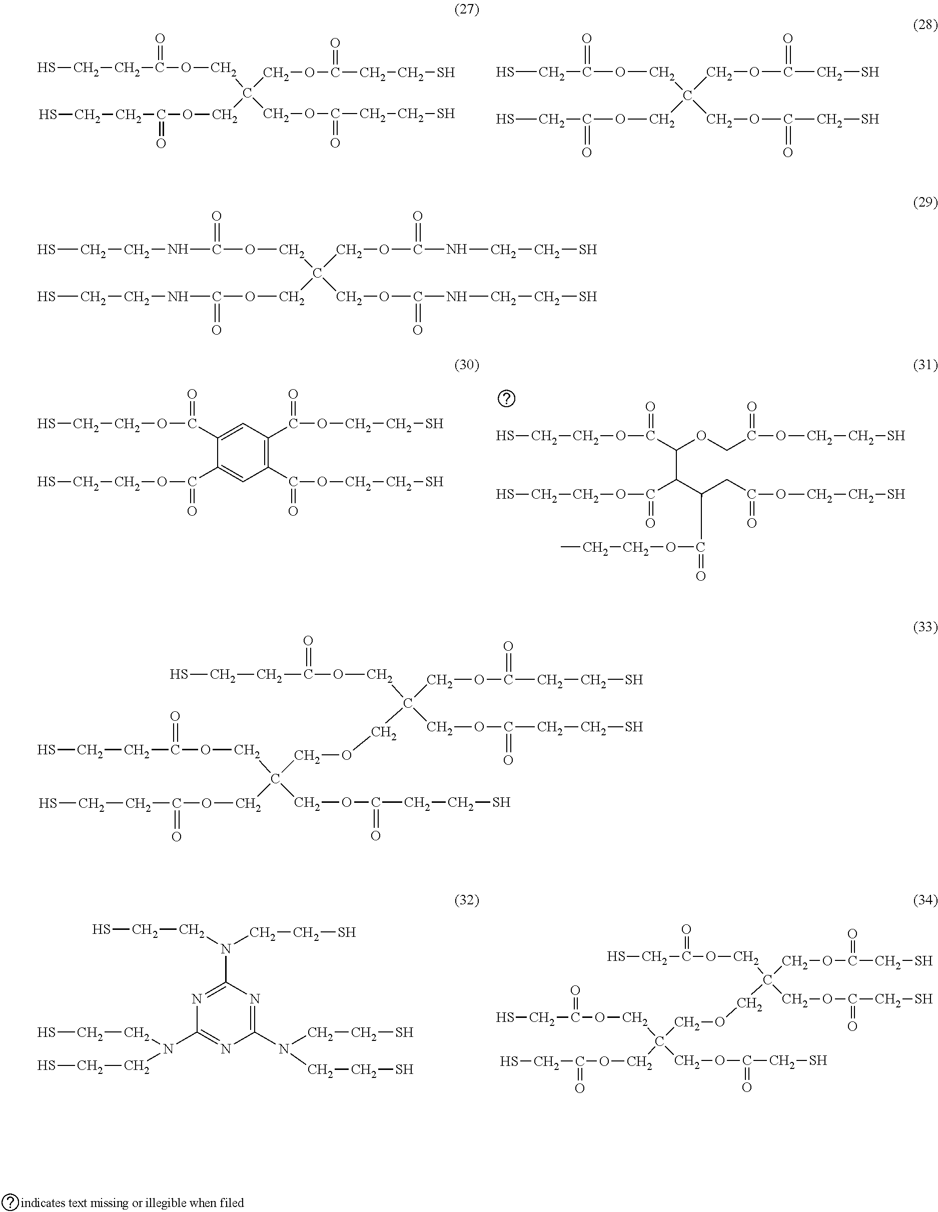

Among these, the following compounds are particularly preferable from the viewpoint of availability of raw materials, ease of synthesis, and solubility in various solvents.

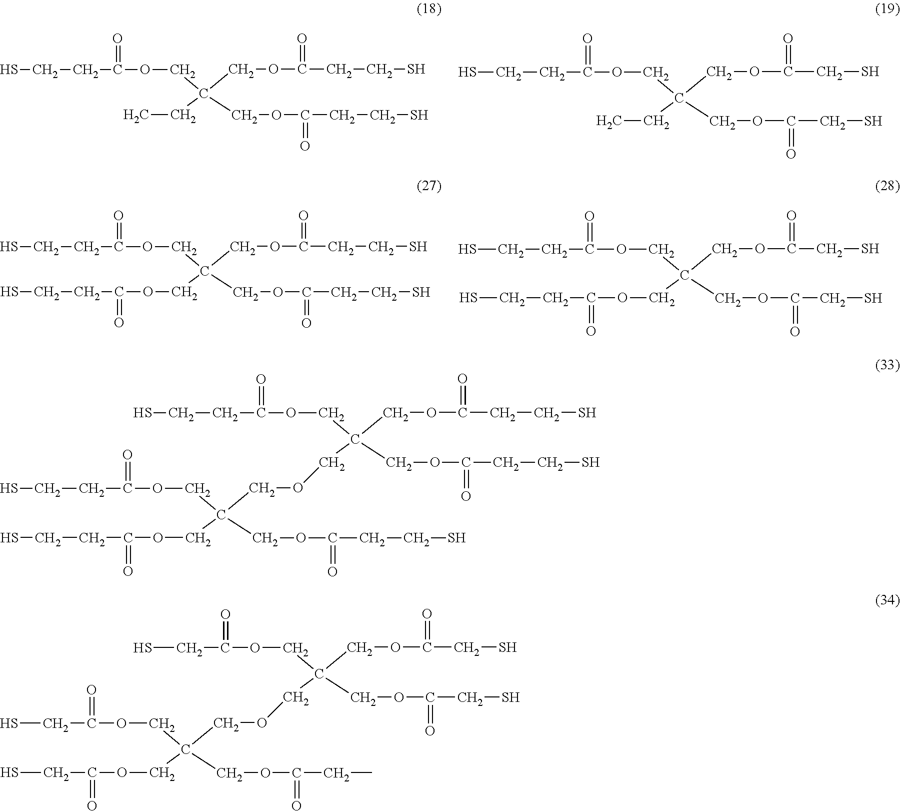 [SMILES: CCC(COC(=O)CCS)(COC(=O)CCS)COC(=O)CCS ; CCC(COC(=O)CS)(COC(=O)CS)COC(=O)CCS ; O=C(CCS)OCC(COC(=O)CCS)(COC(=O)CCS)COC(=O)CCS ; O=C(CS)OCC(COC(=O)CS)(COC(=O)CCS)COC(=O)CCS ; O=C(CCS)OCC(COCC(COC(=O)CCS)(COC(=O)CCS)COC(=O)CCS)(COC(=O)CCS)COC(=O)CCS ; CCC(=O)OCC(COCC(COC(=O)CS)(COC(=O)CS)COC(=O)CS)(COC(=O)CS)COC(=O)CS]

The compound having the foregoing adsorption site and having a carbon-carbon double bond (specifically, the compound having at least one moiety selected from an organic coloring agent structure, a heterocyclic structure, an acid group, a group having a basic nitrogen atom, a urea group, a urethane group, a group having a coordinating oxygen atom, a hydrocarbon group having 4 or more carbon atoms, an alkoxysilyl group, an epoxy group, an isocyanate group, and a hydroxyl group and having a carbon-carbon double bond) is not particularly limited, and examples thereof include the following.

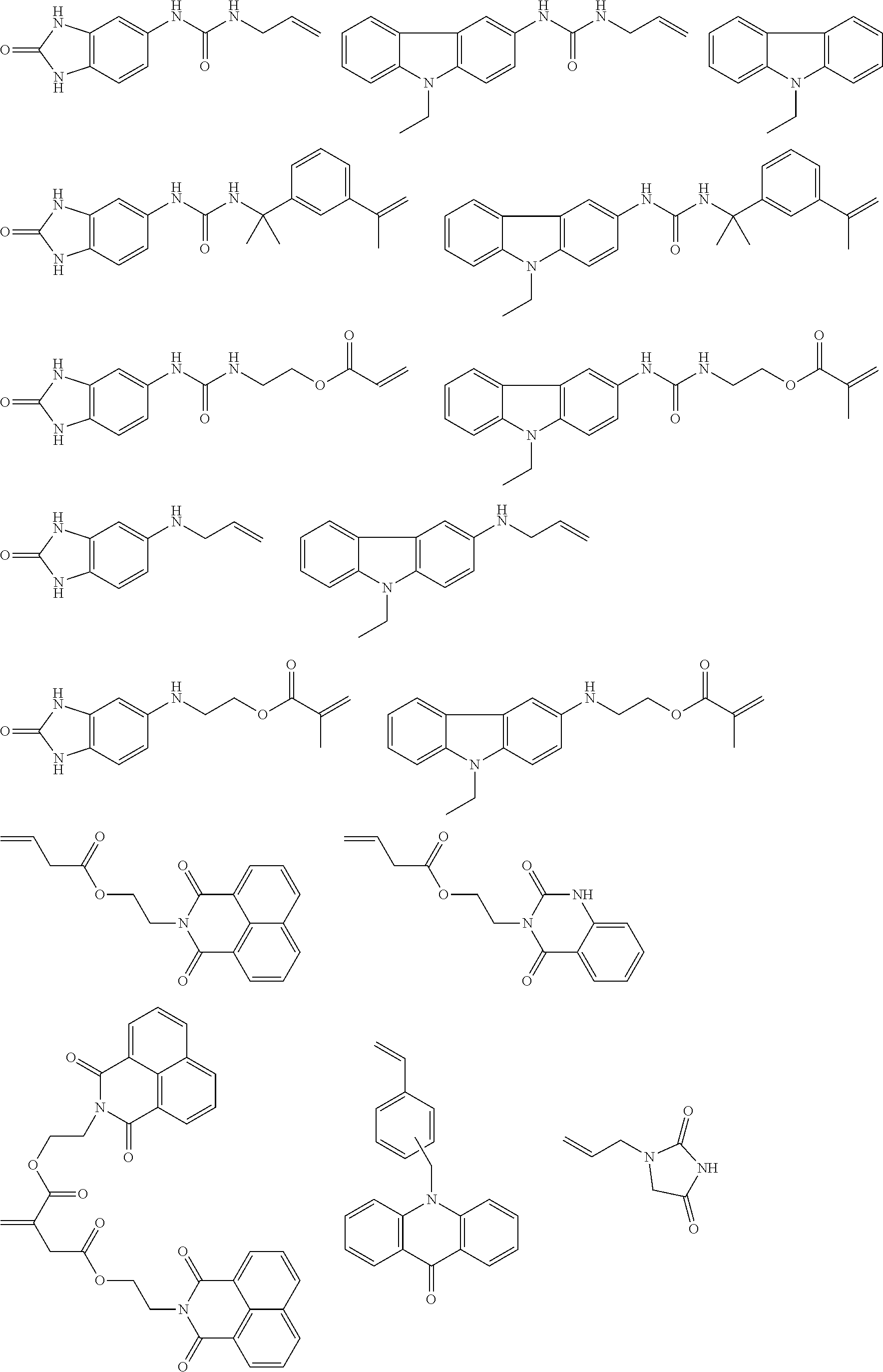

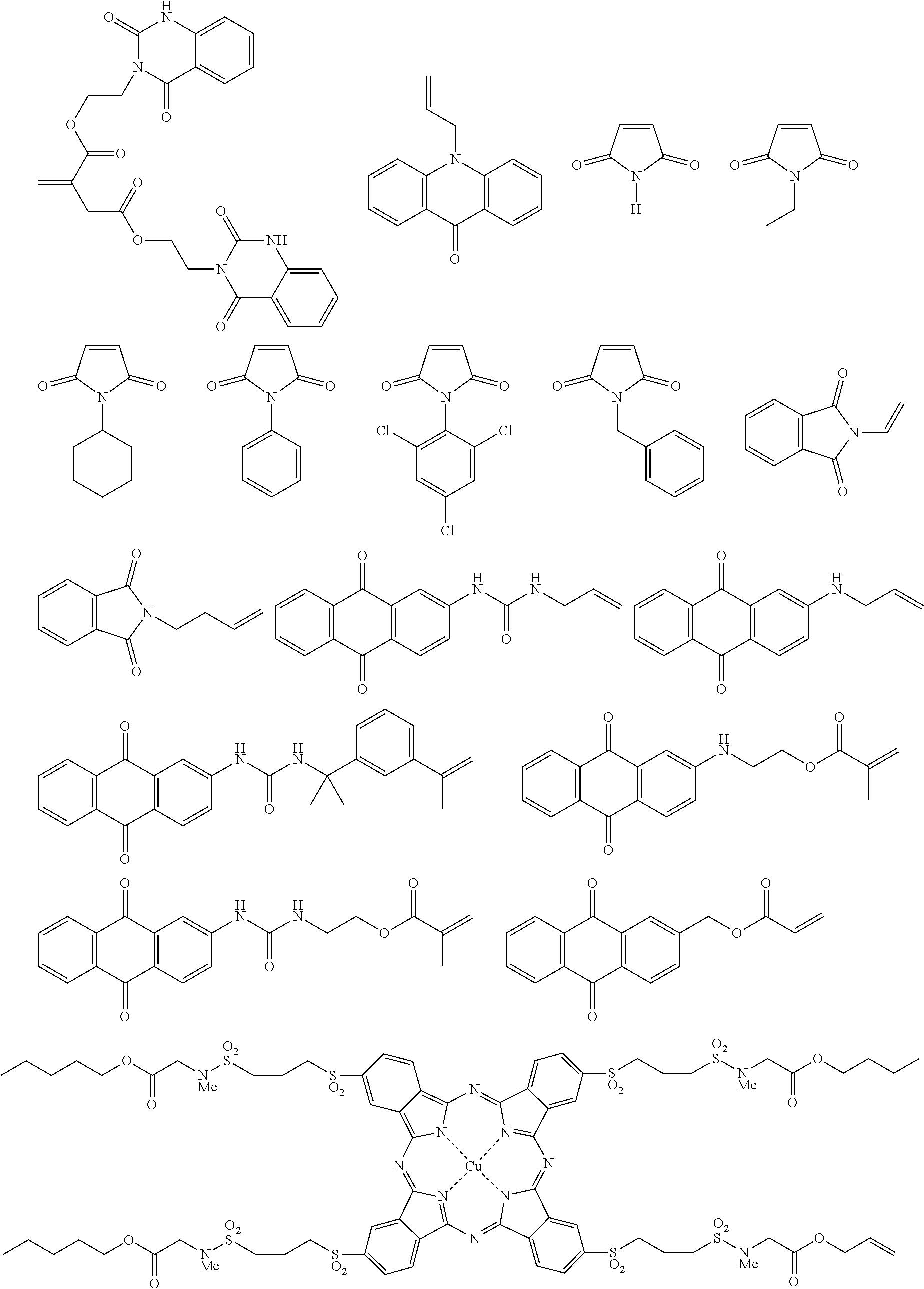

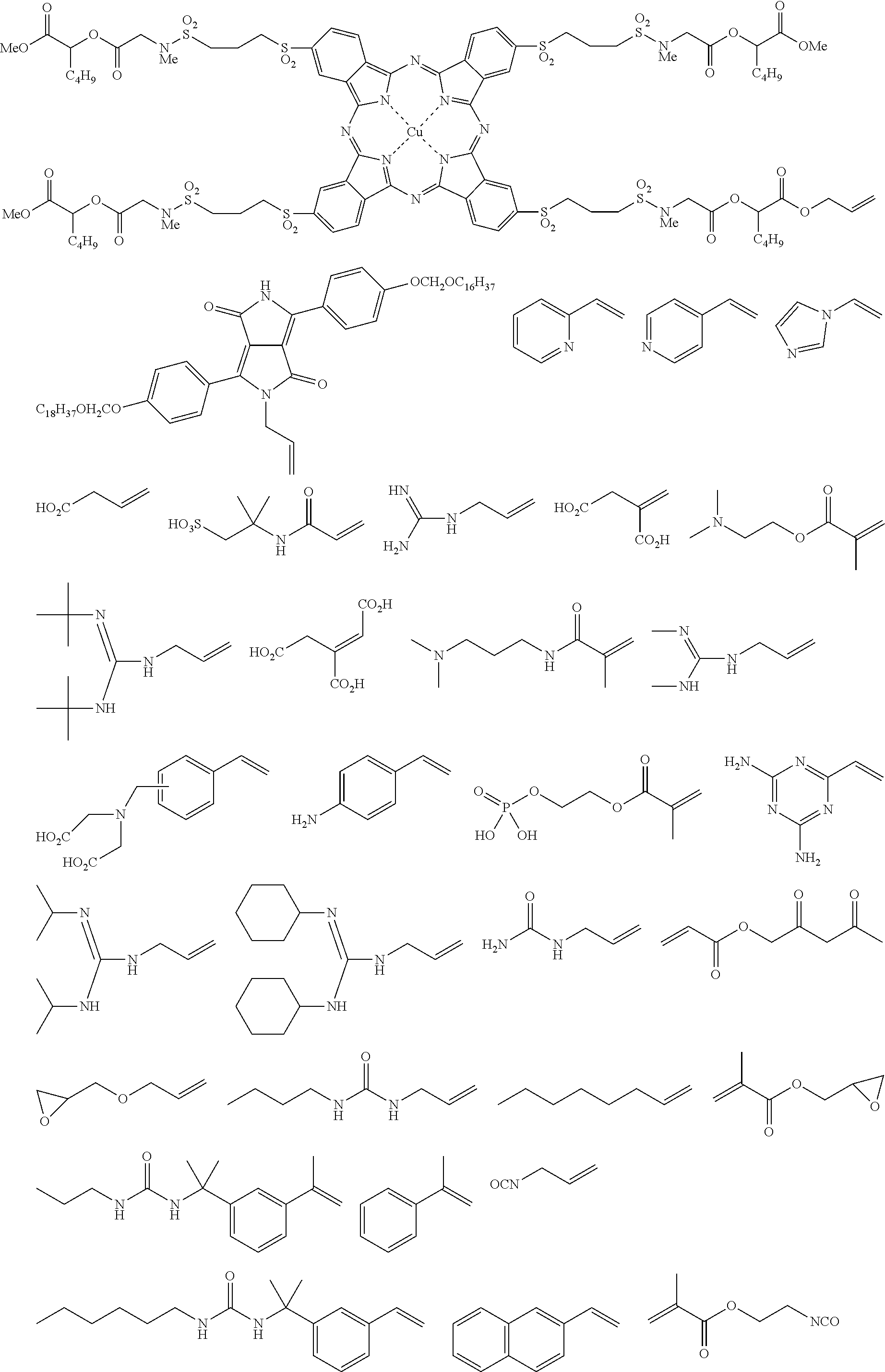

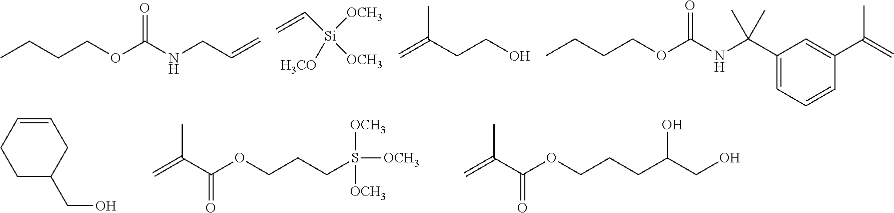

The product of the radical addition reaction between the “compound having 3 to 10 mercapto groups in one molecule” and the “compound having the foregoing adsorption site and having a carbon-carbon double bond” is obtained, for example, using a method (a thiol-ene reaction method) in which the “compound having 3 to 10 mercapto groups in one molecule” and the “compound having the foregoing adsorption site and having a carbon-carbon double bond” are dissolved in a suitable solvent and a radical generator is added thereto to induce an addition reaction at about 50° C. to 100° C.

The suitable solvent for use in the thiol-ene reaction method can be randomly selected according to the solubility of the “compound having 3 to 10 mercapto groups in one molecule”, the “compound having the foregoing adsorption site and having a carbon-carbon double bond”, and the “radical addition reaction product to be produced”.

Examples of the suitable solvent include methanol, ethanol, propanol, isopropanol, 1-methoxy-2-propanol, 1-methoxy-2-propyl acetate, acetone, methyl ethyl ketone, methyl isobutyl ketone, methoxy propyl acetate, ethyl lactate, ethyl acetate, acetonitrile, tetrahydrofuran, dimethyl formamide, chloroform, and toluene. These solvents may be used in admixture of two or more thereof.

Examples of the radical generator that can be used include an azo compound such as 2,2′-azobis(isobutyronitrile) (AIBN), 2,2′-azobis(2,4′-dimethylvaleronitrile), or dimethyl 2,2′-azobisisobutyrate, a peroxide such as benzoyl peroxide, and a persulfate such as potassium persulfate or ammonium persulfate.

The vinyl monomer for use in the above synthesis method 5 is not particularly limited. For example, a vinyl monomer identical to that used in obtaining the polymer skeleton represented by P¹¹ in Formula I can be used.

The vinyl monomers may be polymerized alone or may be copolymerized in combination of two or more thereof.

In addition, in a case of being applied to a curable composition that requires an alkali development treatment, it is more preferable that the polymer compound according to the present disclosure is obtained by copolymerizing a vinyl monomer having one or more acid groups with a vinyl monomer not having one or more acid groups.

The polymer compound according to the present disclosure is preferably obtained by polymerizing these vinyl monomers and the compound represented by General Formula (3) according to a conventional known method. In addition, the compound represented by General Formula (3) in the present disclosure functions as a chain transfer agent, and may be simply referred to as “chain transfer agent” hereinafter.

For example, the polymer compound according to the present disclosure is obtained using a method in which these vinyl monomers and the above chain transfer agent are dissolved in a suitable solvent, a radical polymerization initiator is added thereto, and polymerization is carried out in a solution at about 50° C. to 220° C. (solution polymerization method).

The suitable solvent for use in the solution polymerization method can be randomly selected according to the solubility of the monomers to be used and the copolymer to be produced. Examples of the suitable solvent include methanol, ethanol, propanol, isopropanol, 1-methoxy-2-propanol, 1-methoxy-2-propyl acetate, acetone, methyl ethyl ketone, methyl isobutyl ketone, methoxy propyl acetate, ethyl lactate, ethyl acetate, acetonitrile, tetrahydrofuran, dimethyl formamide, chloroform, and toluene. These solvents may be used in admixture of two or more thereof.

Examples of the radical polymerization initiator that can be used include an azo compound such as 2,2′-azobis(isobutyronitrile) (AIBN), 2,2′-azobis(2,4′-dimethylvaleronitrile), or dimethyl 2,2′-azobisisobutyrate, a peroxide such as benzoyl peroxide, and a persulfate such as potassium persulfate or ammonium persulfate.

As specific examples of the first polymer compound in the present disclosure, polymer compounds 1-1 to 1-10 are described below, but the first polymer compound in the present disclosure is not limited thereto.

In the following exemplary compounds, the sulfur atom bonded to the polymer chain may be bonded to any constitutional unit, and the other terminal not bonded to the sulfur atom of the polymer chain indicated by “poly” is not marked in the following chemical formula, but may be any atom or group that is allowed at the terminal of the polymer chain.

In addition, each constitutional unit contained in the polymer chain may be contained at a certain content ratio (mass ratio).

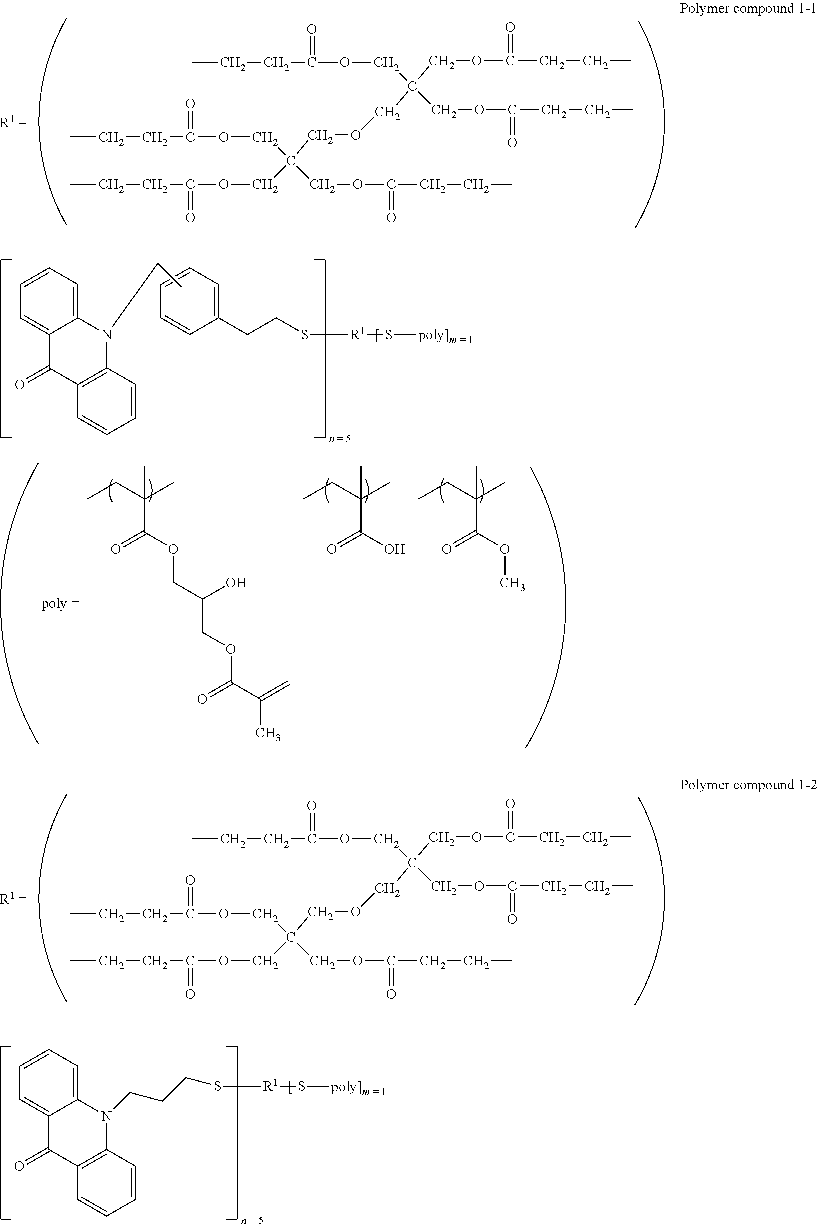

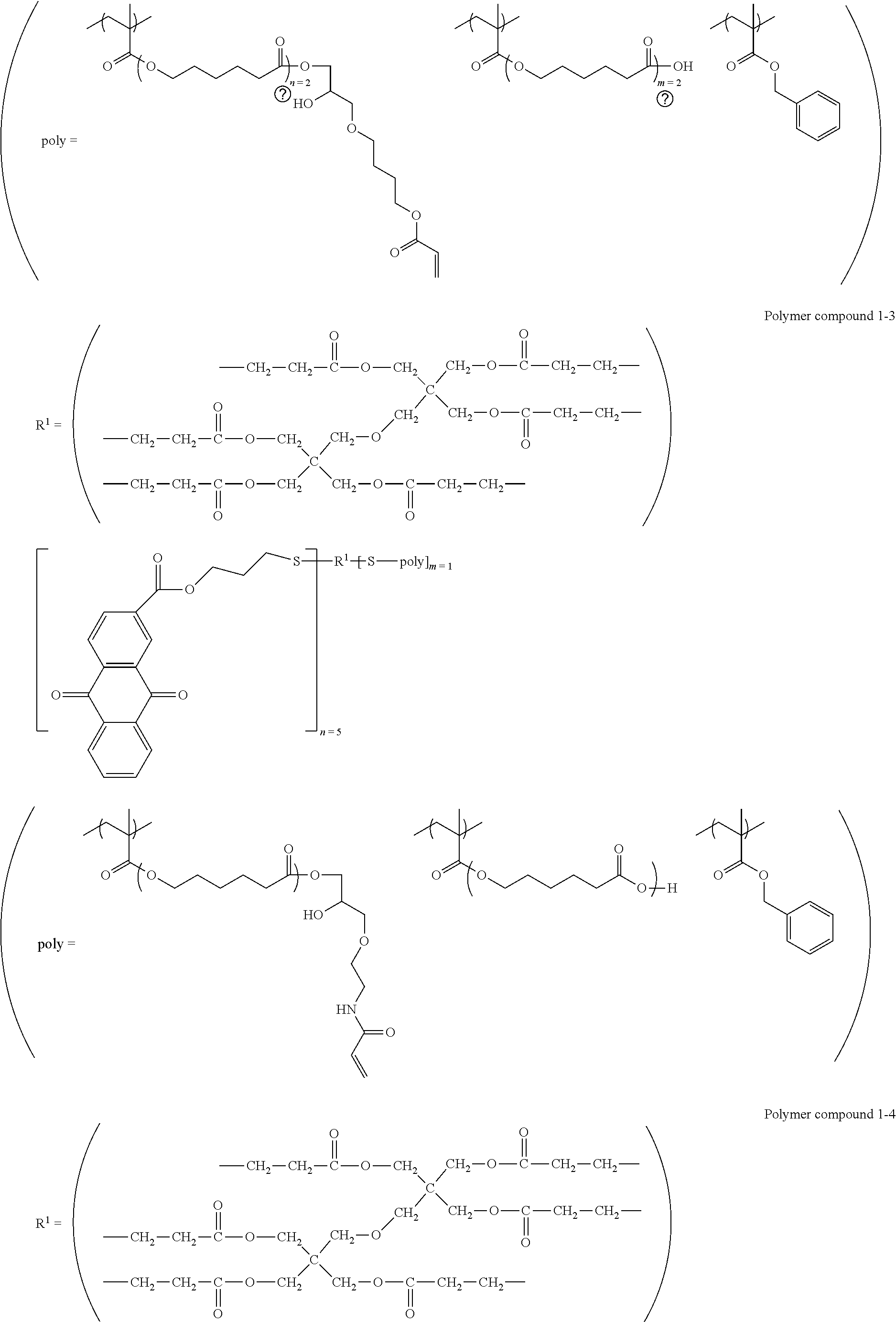

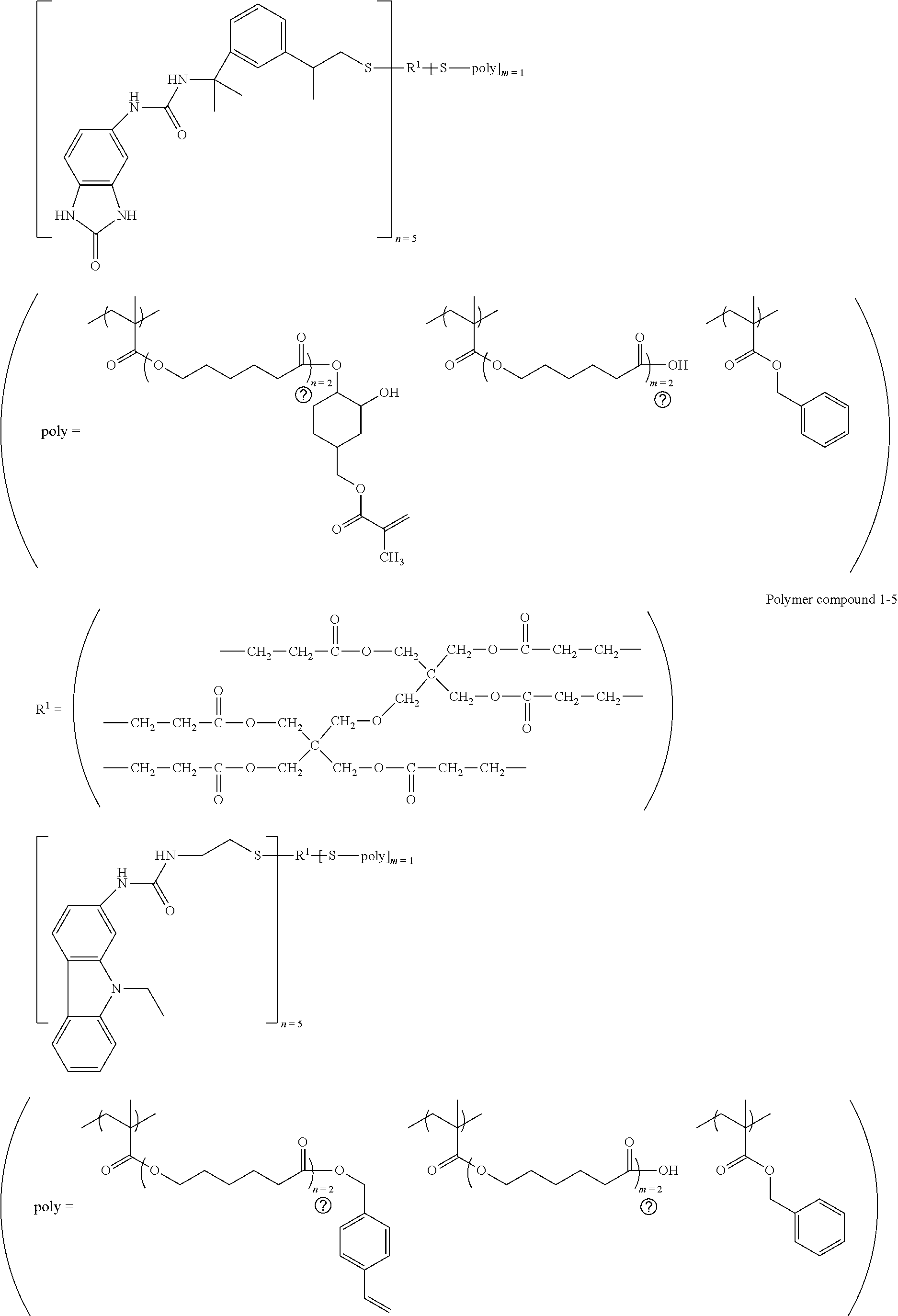

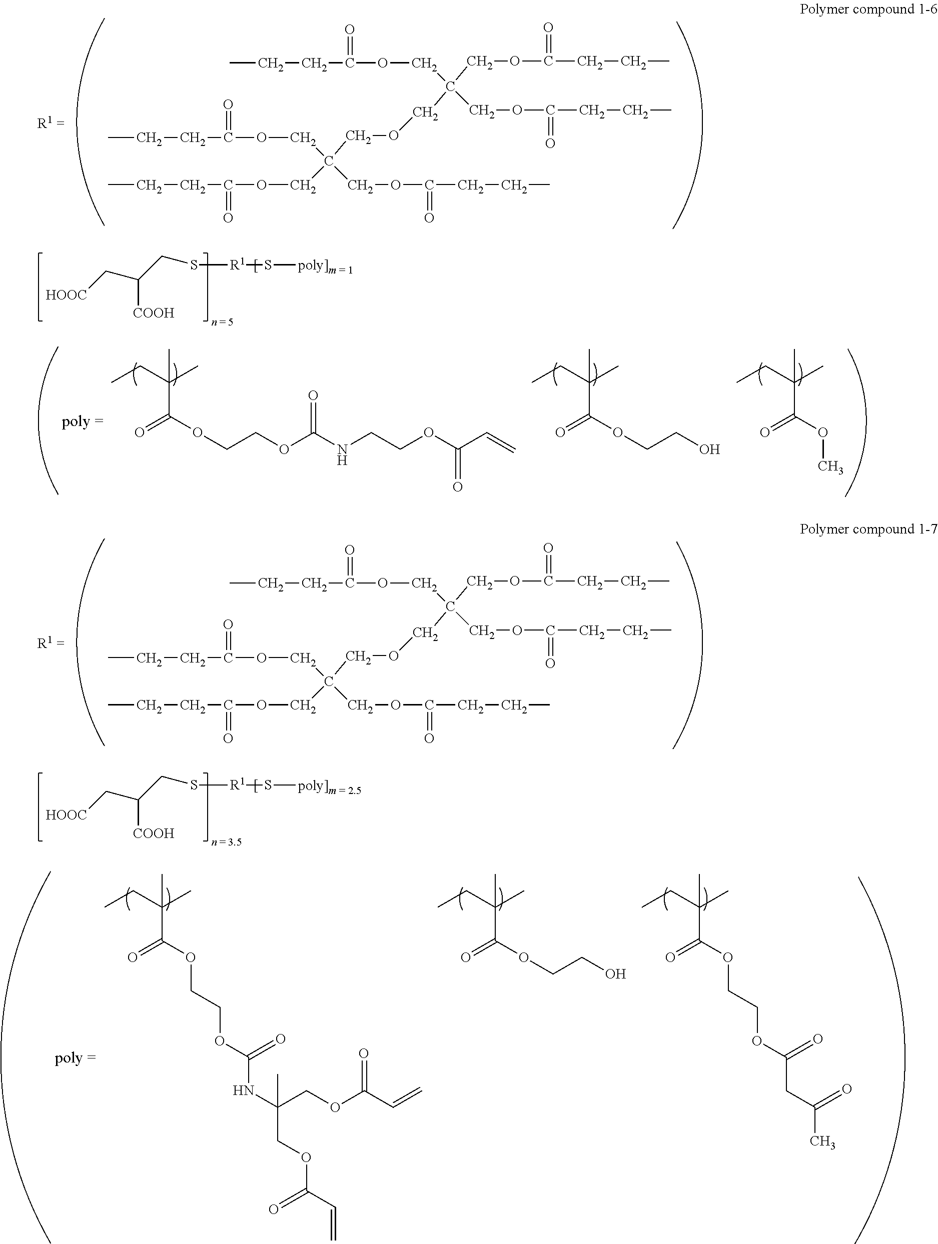

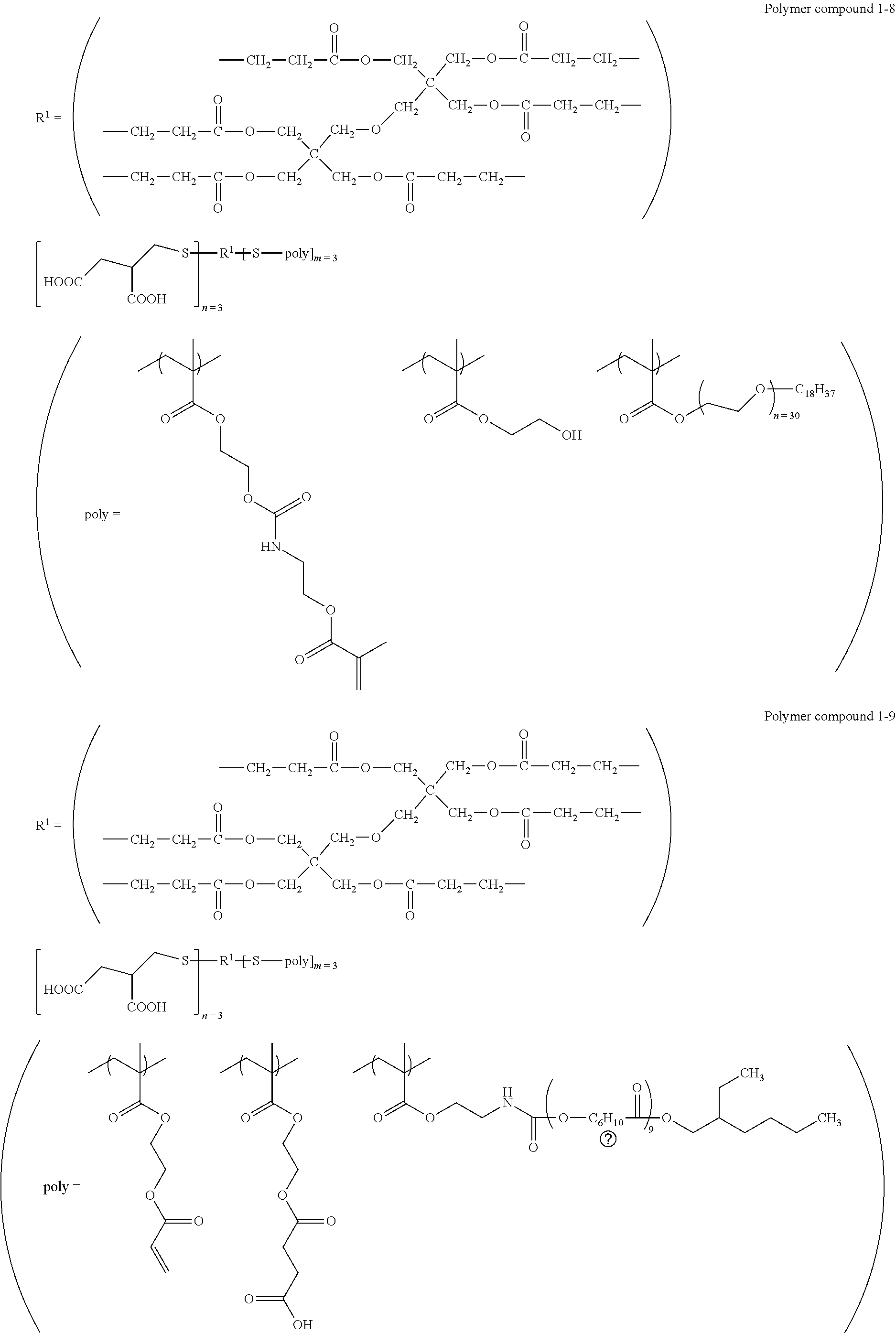

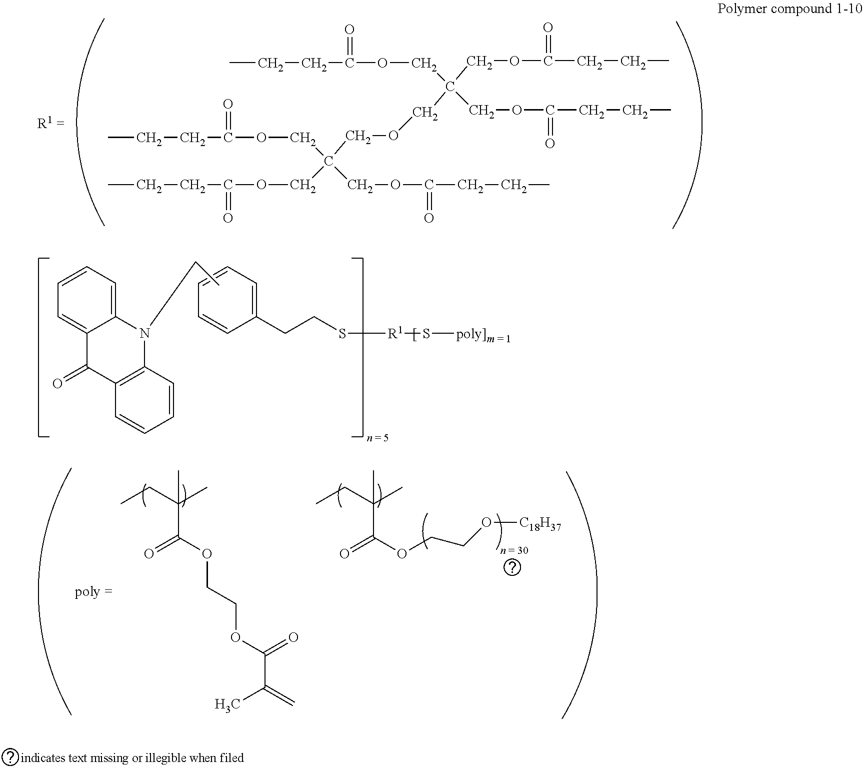

<Second Polymer Compound>

The curable composition according to the present disclosure preferably contains a second polymer compound.

The second polymer compound is a polymer compound represented by Formula II and having a specific absorbance E represented by Expression Aλ of less than 5 at a maximum absorption wavelength within a range of 400 nm to 800 nm.

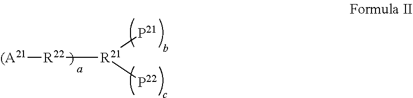

In Formula II, R²¹ represents an (a+b+c)-valent organic linking group, and A²¹'s each independently represent a monovalent organic group containing at least one moiety selected from an organic coloring agent structure, a heterocyclic structure, an acid group, a group having a basic nitrogen atom, a urea group, a urethane group, a group having a coordinating oxygen atom, a hydrocarbon group having 4 or more carbon atoms, an alkoxysilyl group, an epoxy group, an isocyanate group, or a hydroxyl group, R²²'s each independently represent a single bond or a divalent organic linking group, a represents 0 to 8.5, b represents 1 to 10, c represents 1 to 8.5, a+b+c is 3 to 10, and P²¹'s each independently represent a polymer chain having an acid value of 10 mgKOH/g or less and containing a constitutional unit having a polymerizable group, and P²²'s each independently represent a polymer chain having an acid value of 20 mgKOH/g or more and containing a constitutional unit having an acid group.

[A²¹ and R²²]

In Formula II, a number of A²¹'s and R²²'s each may be the same as or different from one another.

A²¹ and R²² each have the same definition as A¹¹ and R¹² in the above-mentioned first polymer compound, and preferred aspects thereof are also the same.

[a]

In Formula II, a represents 0 to 8.5, preferably 0 to 6, and more preferably 0 to 4. From the viewpoint of dispersion stability, a is preferably 0, and from the viewpoint of developability, a is preferably 1 to 8.5.

[R^{2′}]

In Formula II, R²¹ represents an (a+b+c)-valent organic linking group. a+b+c satisfies 3 to 10.

The organic linking group represented by R²¹ has the same definition as that obtained by replacing (m+n) with (a+b+c) in the (m+n)-valent organic linking group in Formula I, and a preferred aspect thereof is also the same.

Among these organic linking groups, the organic linking group represented by R^{2′} is preferably an organic linking group having no acid group and more preferably an organic linking group having no acid group and no polymerizable group.

Examples of a preferred aspect of the organic linking group represented by R²¹ include, but are not limited to, the following specific examples in addition to the specific examples (1) to (17) described above.

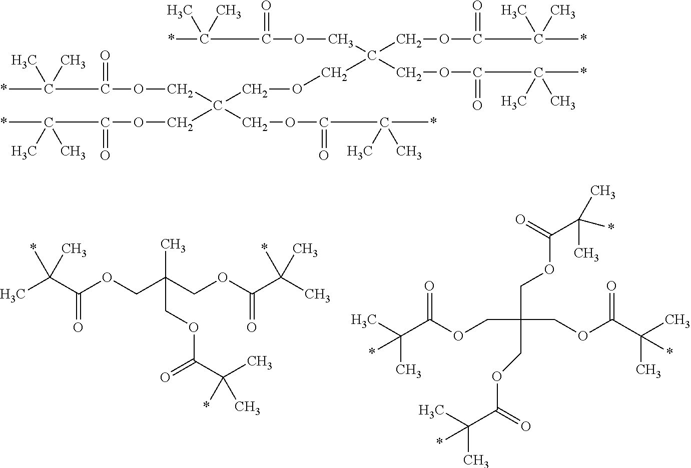 [SMILES: *C(C)(C)C(=O)OCC(COCC(COC(=O)C(*)(C)C)(COC(=O)C(*)(C)C)COC(=O)C(*)(C)C)(COC(=O)C(*)(C)C)COC(=O)C(*)(C)C ; *C(C)(C)C(=O)OCC(C)(COC(=O)C(*)(C)C)COC(=O)C(*)(C)C ; *C(C)(C)C(=O)OCC(COC(=O)C(*)(C)C)(COC(=O)C(*)(C)C)COC(=O)C(*)(C)C]

In the above specific examples, * represents a binding site with another structure.

[P²¹]

In Formula II, P²¹ is a polymer chain having an acid value of 10 mgKOH/g or less and containing a constitutional unit having a polymerizable group. b number of P²¹'s may be the same as or different from one another.

In Formula II, P²¹ can be selected from known polymers or the like according to the purpose or the like as long as the polymer chain has an acid value of 10 mgKOH/g or less and contains a constitutional unit having a polymerizable group.

Among the polymers, the polymer for constituting a polymer chain is preferably at least one selected from the group consisting of a homopolymer or copolymer of vinyl monomers, an ester-based polymer, an ether-based polymer, a urethane-based polymer, an amide-based polymer, an epoxy-based polymer, a silicone-based polymer, and a modification product or copolymer thereof [for example, a polyether/polyurethane copolymer, or a copolymer of a polymer of polyether/vinyl monomer (which may be any of a random copolymer, a block copolymer, and a graft copolymer, among which a random copolymer is more preferable)]; more preferably at least one selected from the group consisting of a homopolymer or copolymer of vinyl monomers, an ester-based polymer, an ether-based polymer, a urethane-based polymer, and a modification product or copolymer thereof; and particularly preferably a polymer or copolymer of vinyl monomers.

Further, the polymer is preferably soluble in an organic solvent. In a case where the polymer has a low affinity for the organic solvent, the affinity for a dispersion medium becomes low in a case where the polymer is used as a pigment dispersant, whereby a sufficient adsorption layer required for dispersion stabilization may not be secured.

The vinyl monomer is the same as the vinyl monomer in description of P¹¹ in Formula I and a preferred aspect thereof is also the same.

—Acid Value—

P²¹ has an acid value of 10 mgKOH/g or less.

The acid value of P²¹ is preferably 8 mgKOH/g or less and more preferably 5 mgKOH/g or less.

In addition, the lower limit of the acid value of P²¹ is not particularly limited and may be 0 mgKOH/g or more.

In a case where the acid value of P²¹ is within the above range and the acid value of P²² is 20 mgKOH/g or more, a curable composition having excellent storage stability can be obtained.

This is presumably because the state in which the second polymer compound adsorbs to two or more particles and crosslinks between the particles is less likely to occur.

The acid value of P²¹ is measured by the following method.

The structure corresponding to P^{H} in the second polymer compound is determined, the polymer chain corresponding to P²¹ is synthesized as a polymer compound, and the acid value of the obtained polymer compound is measured by the titration method described above.

In order to keep the acid value within the above range, it is preferable that the polymer chain represented by P^{H} does not contain the constitutional unit having an acid group, or the content of the constitutional unit having an acid group in the polymer chain represented by 1321 is an amount that makes the acid value within the above range.

In a case where the polymer chain represented by P²¹ contains a constitutional unit having an acid group, the polymer chain represented by P²¹ can contain the same constitutional unit as the constitutional unit having an acid group in P¹¹ described above, and a preferred aspect thereof is also the same.

In addition, in a case where the polymer chain represented by P²¹ contains a constitutional unit having an acid group, the constitutional unit having an acid group is introduced into the polymer chain, by using, for example, the same monomer as the vinyl monomer having an acid group in P¹¹ described above.

—Polymerizable Group—

P²¹ in the present disclosure includes a constitutional unit having a polymerizable group.

The polymerizable group is not particularly limited and is preferably an ethylenically unsaturated group.

The method for introducing a constitutional unit having a polymerizable group is not particularly limited, and examples thereof include polymer reactions such as a method of forming a polymer chain containing a constitutional unit having a carboxyl group and then reacting the carboxyl group with a compound having a polymerizable group such as an epoxy group or a (meth)acryloxy group; a method of forming a polymer chain having a constitutional unit having a hydroxy group and then reacting the hydroxy group with a compound having a polymerizable group such as an isocyanate group or a (meth)acryloxy group; a method of forming a polymer chain containing a halogen atom and then desorbing a hydrogen halide to form a double bond; and a method of forming a polymer chain containing a constitutional unit having a carboxyl group and then reacting the formed polymer chain with a compound containing a halogenated alkyl group and a polymerizable group.

The polymerizable group contained in P²¹ is not particularly limited, and it is preferable to contain at least one selected from the group consisting of a (meth)acryloxy group, a (meth)acrylamide group, and a vinyl phenyl group, from the viewpoint of reactivity.

The polymerizable group is preferably a (meth)acryloxy group from the viewpoint of the pattern cross-sectional shape and the adhesiveness to the substrate.

In addition, the polymerizable group is preferably a (meth)acrylamide group from the viewpoint of alkali developability.

Further, the polymerizable group is preferably a vinyl phenyl group from the viewpoint of storage stability.

The constitutional unit having a polymerizable group in P²¹ is preferably a constitutional unit represented by any one of Formula B-1, B-2, B-3, or B-4 in P¹¹ described above.

The polymerizable group value in P²¹ is preferably 0.01 mol/g to 6 mol/g, more preferably 0.1 mol/g to 6.0 mol/g, and still more preferably 0.3 mol/g to 5.0 mol/g, from the viewpoint of the pattern cross-sectional shape and the adhesiveness to the substrate.

—Molecular Weight—

The molecular weight (the weight-average molecular weight in a case of having a molecular weight distribution) of P²¹ is preferably 5000 to 50000 and more preferably 5000 to 30000.

[P²²]

In Formula II, P²² is a polymer chain having an acid value of 20 mgKOH/g or more and containing a constitutional unit having an acid group. c number of P²²'s may be the same as or different from one another.

In Formula II, P²² can be selected from known polymers or the like according to the purpose or the like as long as the polymer chain has an acid value of 20 mgKOH/g or more and contains a constitutional unit having an acid group.

Among the polymers, the polymer for constituting a polymer chain is preferably at least one selected from the group consisting of a homopolymer or copolymer of vinyl monomers, an ester-based polymer, an ether-based polymer, a urethane-based polymer, an amide-based polymer, an epoxy-based polymer, a silicone-based polymer, and a modification product or copolymer thereof [for example, a polyether/polyurethane copolymer, or a copolymer of a polymer of polyether/vinyl monomer (which may be any of a random copolymer, a block copolymer, and a graft copolymer, among which a random copolymer is more preferable)]; more preferably at least one selected from the group consisting of a homopolymer or copolymer of vinyl monomers, an ester-based polymer, an ether-based polymer, a urethane-based polymer, and a modification product or copolymer thereof; and particularly preferably a polymer or copolymer of vinyl monomers.

Further, the polymer is preferably soluble in an organic solvent. In a case where the polymer has a low affinity for the organic solvent, the affinity for a dispersion medium becomes low in a case where the polymer is used as a pigment dispersant, whereby a sufficient adsorption layer required for dispersion stabilization may not be secured.

The vinyl monomer is the same as the vinyl monomer in description of in Formula I and a preferred aspect thereof is also the same.

—Acid Value—

P²² has an acid value of 20 mgKOH/g or more.

The acid value of P²² is preferably 30 mgKOH/g or more and more preferably 40 mgKOH/g or more.

The upper limit of the acid value of P²² is not particularly limited and is preferably 200 mgKOH/g or less.

The acid value of P²² is measured by the same method as in the acid value of P^{2′} described above.

—Acid Group—

P²² has an acid group.

The amount of the acid group may be an amount that makes the acid value of P²² within the above range.

The acid group is, for example, preferably a carboxylic acid group, a sulfonic acid group, a monosulfate group, a phosphoric acid group, a monophosphate group, a boric acid group, or a phenolic hydroxyl group; more preferably a carboxylic acid group, a sulfonic acid group, a monosulfate group, a phosphoric acid group, or a monophosphate group; still more preferably a carboxylic acid group, a sulfonic acid group, or a phosphoric acid group; and particularly preferably a carboxylic acid group.

The constitutional unit having an acid group in P²² is preferably the same constitutional unit as the constitutional unit represented by Formula A in P^{H}, and a preferred aspect in the constitutional unit represented by Formula A is also the same.

In addition, in a case where the polymer chain represented by P²² contains a constitutional unit having an acid group, the constitutional unit having an acid group is introduced into the polymer chain, by using, for example, the same monomer as the vinyl monomer having an acid group in P¹¹ described above.

—Polymerizable Group—

P²² may have a polymerizable group.

The polymerizable group in P²² has the same definition as the polymerizable group in P²¹ described above and a preferred aspect thereof is also the same.

In addition, in a case where P²² has a polymerizable group, the polymerizable group can be introduced, for example, by the same method as that for the polymerizable group in P²¹.

The polymerizable group value in P²² is preferably 0 mol/g to 1 mol/g, more preferably 0 mol/g to 0.5 mol/g, and still more preferably 0 mol/g.

—Molecular Weight—

The molecular weight (the weight-average molecular weight in a case of having a molecular weight distribution) of P²² is preferably 5000 to 50000 and more preferably 5000 to 30000.

[b and c]

In Formula II, b represents 1 to 10. b is preferably 2 to 8, more preferably 2 to 7, and particularly preferably 3 to 6.

In Formula II, c represents 1 to 8.5, preferably 2 to 6, and more preferably 3 to 6.

a+b+c is 3 to 10, preferably 4 to 10, and more preferably 4 to 8.

b+c is preferably 3 to 10 and more preferably 4 to 8.

In a case where b+c is 3 or more, the generation of residues during development is likely to be suppressed.

This is presumed to be because, in a case where b+c is 3 or more, the entanglement of the polymer chains in the second polymer compound is suppressed and therefore the solubility in the developer is improved.

In addition, in a case where b+c is 3 or more, a curable composition having excellent curability is easily obtained.

This is presumed to be because, in a case where b+c is 3 or more, the occurrence of an intramolecular polymerization reaction (intramolecular crosslinking) in the second polymer compound is suppressed and therefore an intermolecular polymerization reaction is likely to proceed.

[Physical Properties of Second Polymer Compound]

The acid value of the second polymer compound in the present disclosure is not particularly limited, and is preferably 10 to 200 (mgKOH/g), more preferably 15 to 150 (mgKOH/g), and particularly preferably 50 to 120 (mg KOH/g) from the viewpoint of developability.

The molecular weight of the second polymer compound in the present disclosure is preferably 3000 to 100000, more preferably 5000 to 80000, and particularly preferably 7000 to 60000 in terms of weight-average molecular weight from the viewpoint of dispersibility and dispersion stability in the curable composition.

The second polymer compound is a polymer compound having a specific absorbance E represented by Expression Aλ of less than 5 at a maximum absorption wavelength within a range of 400 nm to 800 nm.

Specific absorbance E=A/(c×L) Expression Aλ

The specific absorbance is measured by the same method as that for the first polymer compound.

The specific absorbance E is preferably 0 to 4 and more preferably 0 to 3.

—Method for Producing Second Polymer Compound—

As the method for producing the second polymer compound according to the present disclosure, for example, a known method for synthesizing a star polymer can be used.

As an example of the production method, the second polymer compound according to the present disclosure is obtained by introducing a polymerizable group into a polymer compound, which is obtained by a method of reacting a terminal halogen atom of a polyfunctional halogen compound described later with a polymer chain having a terminal capable of reacting with the halogen atom, prepared by a living anion polymerization method. As the polymer chain, a precursor of P²¹ and a precursor of P²² are used.

In a case where a in Formula II in the second polymer compound is 1 or more (in a case where the second polymer compound has a group represented by A²¹-R²²— in Formula II), before reacting the polyfunctional halogen atom with the precursor of P²¹ and the precursor of P²², a part of terminal halogen atoms of the polyfunctional halogen compound may be reacted with a precursor of the group represented by A²¹-R²²— to bond the group represented by A²¹-R²²— to the polyfunctional halogen atom.

The precursor of the group represented by A²¹-R²²— may be, for example, a compound in which a structure capable of reacting with a halogen atom is bonded to an organic group represented by A²¹. Examples of the structure capable of reacting with a halogen atom include a carboxyl group, a thiol group, and a hydroxyl group.

As the precursor of P²¹, for example, a polymer chain having a hydroxy group or a carboxyl group is used. In order to form P²¹, the hydroxy group is reacted with a compound having an isocyanate group and a polymerizable group. Alternatively, a polymer chain corresponding to P²¹ is obtained by reacting the carboxyl group with a compound having an epoxy group and a polymerizable group.

As the precursor of P²², for example, a polymer chain having an acid group such as a carboxyl group is used. The acid group may be bonded with a known protecting group for protecting the acid group from the above-mentioned reaction of introducing a polymerizable group into P²¹. For example, the polymer chain corresponding to P²² is obtained by deprotecting the protecting group from the precursor of P²² after the reaction of introducing a polymerizable group into P²¹.

Specific examples of the above-mentioned production method include the production methods in Examples which will be described later.

—Polyfunctional Halogen Compound—

The polyfunctional halogen compound may be, for example, a compound in which a halogen atom is bonded to the terminal of the (a+b+c)-valent organic linking group represented by R²¹.

Examples of the halogen atom include a fluorine atom, a chlorine atom, a bromine atom, and an iodine atom, among which a chlorine atom or a bromine atom is preferable.

As an example of a method for synthesizing a polyfunctional halogen atom, there is a method of esterifying a polyfunctional alcohol compound having a plurality of hydroxy groups with an acid halide compound (preferably a carboxylic acid halide compound) having a halogen atom in addition to a halide group.

Specific examples of the polyfunctional halogen atom include, but are not limited to, those in which a halogen atom is bonded to the binding site of the (a+b+c)-valent organic linking group represented by R²¹.

As specific examples of the second polymer compound in the present disclosure, polymer compounds 2-1 and 2-2 are described below, but the second polymer compound in the present disclosure is not limited thereto.

In the following exemplary compounds, the description of “—Br” indicates that the terminal of the polymer chain is a bromine atom, and the bromine atom may be bonded to any constitutional unit.

In addition, each constitutional unit contained in the polymer chain may be contained at a certain content ratio (mass ratio).

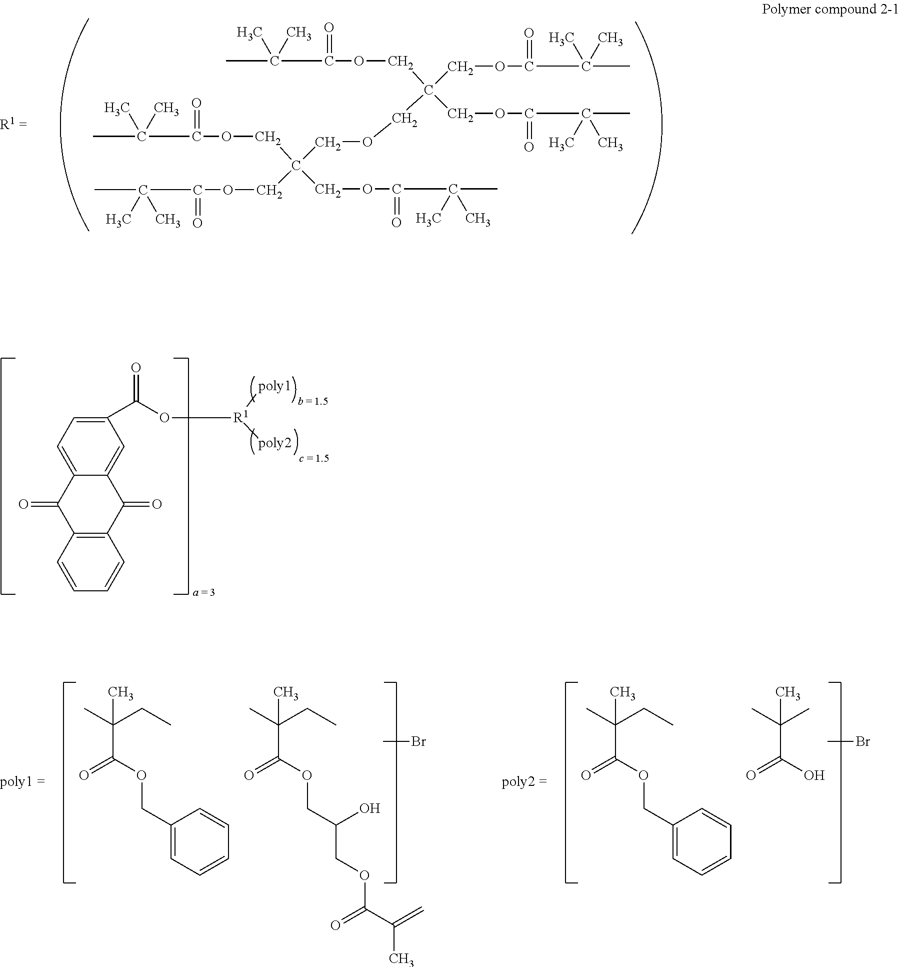

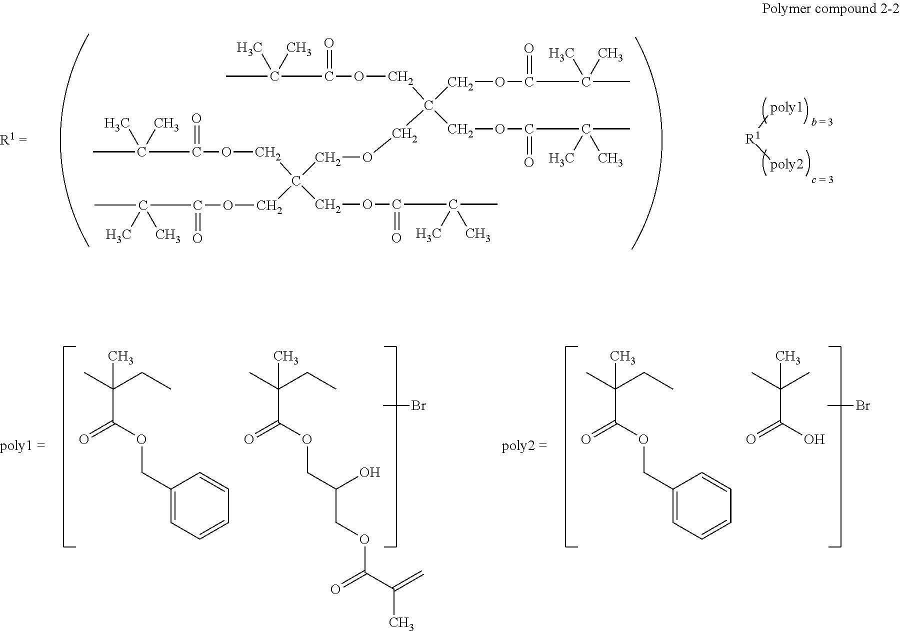

<Other Components>

The curable composition according to the present disclosure is preferably a composition that can be finally cured to obtain a cured film.

In addition, the curable composition according to the present disclosure is preferably a composition capable of forming a pattern of a cured film by, for example, pattern-wise exposure, and may be a negative composition or a positive composition as long as a cured film is finally obtained.

In a case where the curable composition according to the present disclosure is a negative composition, for example, an aspect including a polymerization initiator, a polymerizable compound, and an alkali-soluble resin is preferable.

In addition, in a case where the curable composition according to the present disclosure is a positive composition, for example, there is an aspect including a photoacid generator, a polymer having a constitutional unit having a group in which an acid group is protected by an acid-decomposable group, and a polymer having a constitutional unit having a crosslinkable group.

Hereinafter, individual components included in the aspect in which the curable composition according to the present disclosure is a negative composition will be described.

The individual components included in the aspect in which the curable composition according to the present disclosure is a positive composition include the individual components described in WO2014/003111A, and preferred aspects thereof are also the same.

<Polymerization Initiator>

The curable composition according to the present disclosure preferably contains a polymerization initiator.

The polymerization initiator is not particularly limited and is preferably a photopolymerization initiator.

The photopolymerization initiator is not particularly limited as long as it has an ability to initiate polymerization of a polymerizable compound, and can be appropriately selected from known photopolymerization initiators. For example, a compound having photosensitivity to light in the ultraviolet region to the visible region is preferable. In addition, the photopolymerization initiator may be a compound that generates an active radical by causing some action with a photoexcited sensitizer. The photopolymerization initiator is preferably a photo-radical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxy ketone compound, and an α-amino ketone compound. From the viewpoint of exposure sensitivity, the photopolymerization initiator is preferably a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyloxadiazole compound, or a 3-aryl-substituted coumarin compound; more preferably a compound selected from an oxime compound, an α-hydroxyketone compound, an α-aminoketone compound, and an acylphosphine compound; and still more preferably an oxime compound. Regarding the photopolymerization initiator, reference can be made to the description of paragraphs [0065] to [0111] of JP2014-130173A and paragraphs [0274] to [0306] of JP2013-029760A, the contents of which are incorporated herein by reference.

Examples of commercially available α-hydroxyketone compounds include IRGACURE-184, DAROCUR-1173, IRGACURE-500, IRGACURE-2959, and IRGACURE-127 (all of which are manufactured by BASF SE). Examples of commercially available α-aminoketone compounds include IRGACURE-907, IRGACURE-369, IRGACURE-379, and IRGACURE-379EG (all of which are manufactured by BASF SE). Examples of commercially available acylphosphine compounds include IRGACURE-819 and DAROCUR-TPO (both of which are manufactured by BASF SE).

Examples of the oxime compound include compounds described in JP2001-233842A, compounds described in JP2000-080068A, compounds described in JP2006-342166A, compounds described in J. C. S. Perkin II (1979, pp. 1653 to 1660), compounds described in J. C. S. Perkin II (1979, pp. 156 to 162), compounds described in Journal of Photopolymer Science and Technology (1995, pp. 202 to 232), compounds described in JP2000-066385A, compounds described in JP2000-080068A, compounds described in JP2004-534797A, compounds described in JP2006-342166A, compounds described in JP2017-019766A, compounds described in JP6065596B, compounds described in WO2015/152153A, and compounds described in WO2017/051680A. Specific examples of the oxime compound include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutan-2-one, and 2-ethoxycarbonyloxyimino-1-phenylpropan-1-one. As commercially available oxime compounds, IRGACURE-OXE01, IRGACURE-OXE02, IRGACURE-OXE03, and IRGACURE-OXE04 (all of which are manufactured by BASF SE) are also suitably used. In addition, TRONLY TR-PBG-304, TRONLY TR-PBG-309, and TRONLY TR-PBG-305 (all of which are manufactured by CHANGZHOU TRONLY NEW ELECTRONIC MATERIALS CO., LTD), and ADEKA ARKLS NCI-930 and ADEKAOPTOMER N-1919 (photopolymerization initiator 2 of JP2012-014052A) (both of which are manufactured by ADEKA Corporation) can be mentioned as commercially available oxime compounds.

In addition, as oxime compounds other than the above, compounds described in JP2009-519904A in which an oxime is linked to an N-position of a carbazole ring; compounds described in U.S. Pat. No. 7,626,957B in which a hetero substituent is introduced into a benzophenone moiety; compounds described in JP2010-015025A and US2009-292039A in which a nitro group is introduced into a coloring agent moiety; ketoxime compounds described in WO2009/131189A; compounds described in U.S. Pat. No. 7,556,910B, which contain a triazine skeleton and an oxime skeleton in the same molecule; and compounds described in JP2009-221114A, which have a maximum absorption at 405 nm and satisfactory sensitivity to a g-ray light source, may be used.

In the present invention, an oxime compound having a fluorene ring can also be used as the photopolymerization initiator. Specific examples of the oxime compound having a fluorene ring include compounds described in JP2014-137466A, the contents of which are incorporated herein by reference.

In the present invention, an oxime compound having a benzofuran skeleton can also be used as the photopolymerization initiator. Specific examples thereof include compounds OE-01 to OE-75 described in WO2015/036910A.

In the present invention, an oxime compound having a skeleton in which at least one benzene ring of a carbazole ring became a naphthalene ring can also be used as the photopolymerization initiator. Specific examples of such an oxime compound include compounds described in WO2013/083505A.

In the present invention, an oxime compound having a fluorine atom can also be used as the photopolymerization initiator. Specific examples of the oxime compound having a fluorine atom include compounds described in JP2010-262028A, the contents of which are incorporated herein by reference, Compounds 24 and 36 to 40 described in JP2014-500852A, the contents of which are incorporated herein by reference, and Compound (C-3) described in JP2013-164471A, the contents of which are incorporated herein by reference.

In the present invention, an oxime compound having a nitro group can be used as the photopolymerization initiator. The oxime compound having a nitro group is also preferably a dimer. Specific examples of the oxime compound having a nitro group include compounds described in paragraphs [0031] to [0047 of JP2013-114249A, and paragraphs [0008] to [0012] and [0070] to [0079] of JP2014-137466A, compounds described in paragraphs [0007] to [0025] of JP4223071B, and ADEKA ARKLS NCI-831 (manufactured by ADEKA Corporation).

Specific examples of the oxime compound preferably used in the present invention are shown below, but the present invention is not limited thereto.

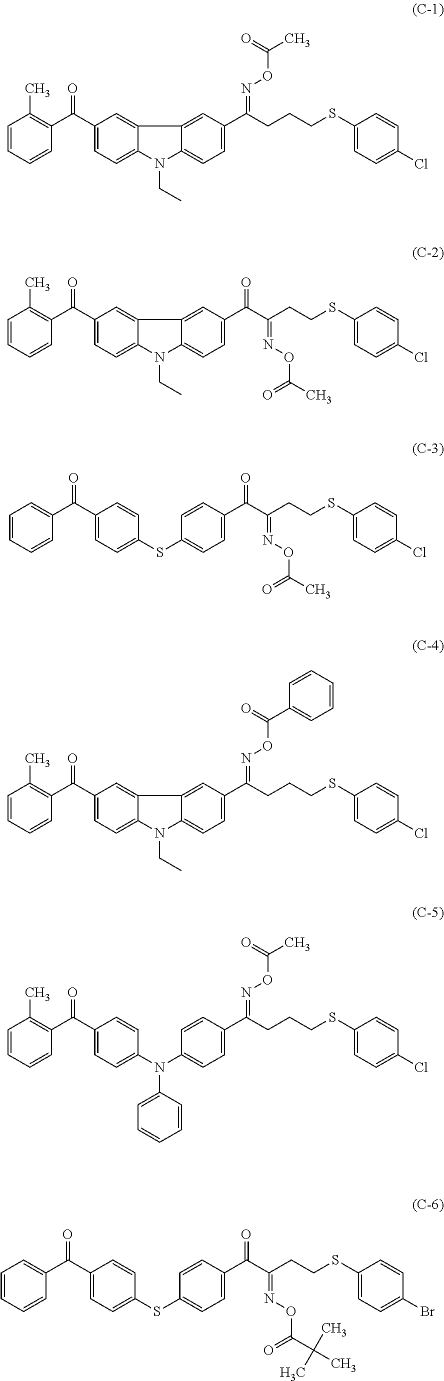 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

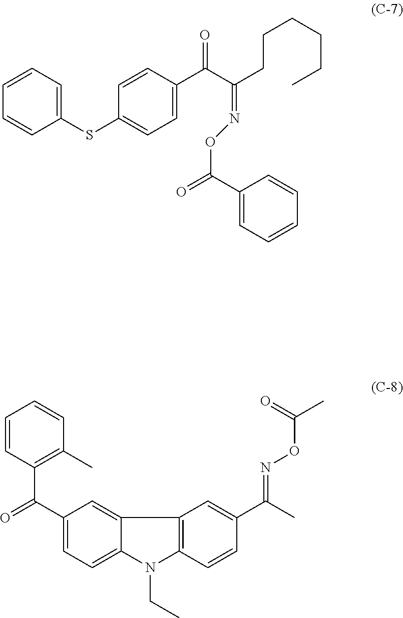 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21]

The oxime compound is preferably a compound having a maximum absorption wavelength in the wavelength range of 350 nm to 500 nm, and more preferably a compound having a maximum absorption wavelength in the wavelength range of 360 nm to 480 nm. In addition, the oxime compound is preferably a compound having high absorbance at 365 nm and 405 nm.

The molar extinction coefficient at 365 nm or 405 nm of the oxime compound is preferably 1,000 to 300,000, more preferably 2,000 to 300,000, and particularly preferably 5,000 to 200,000 from the viewpoint of sensitivity. The molar extinction coefficient of the compound can be measured using a known method. For example, it is preferable to measure the molar extinction coefficient of the compound with an ultraviolet-visible spectrophotometer (Cary-5 spectrophotometer manufactured by Varian Medical Systems, Inc.) using an ethyl acetate solvent at a concentration of 0.01 g/L.

In the present invention, a difunctional or tri- or higher functional photopolymerization initiator may be used as the photopolymerization initiator. Specific examples of such a photopolymerization initiator include dimers of oxime compounds described in paragraphs [0417] to [0412] of JP2010-527339A, JP2011-524436A, WO2015/004565A, paragraphs [0417] to [0412] of JP2016-532675A, and paragraphs [0039] to [0055] of WO2017/033680A, Compound (E) and Compound (G) described in JP2013-522445A, and Cmpd 1 to 7 described in WO2016/034963A.

The polymerization initiators may be used alone or in combination of two or more thereof.

The content of the polymerization initiator in the curable composition is preferably 0.1% to 50% by mass, more preferably 0.5% to 30% by mass, and particularly preferably 1% to 20% by mass, with respect to the total solid content of the composition. Within this range, satisfactory sensitivity and pattern formability can be obtained.

<Polymerizable Compound>

The curable composition according to the present disclosure preferably contains a polymerizable compound. The polymerizable compound that can be used in the present disclosure is preferably an ethylenically unsaturated compound and more preferably a compound having a terminal ethylenically unsaturated group.

As a group of such a compound, known compounds can be used without any particular limitation.

These compounds have a chemical form such as a monomer, a prepolymer, that is, a dimer, a trimer or an oligomer, or a mixture thereof and a copolymer thereof. Examples of the monomer and the copolymer thereof include unsaturated carboxylic acids (for example, acrylic acid, methacrylic acid, itaconic acid, crotonic acid, isocrotonic acid, and maleic acid), and esters and amides thereof, among which an ester of an unsaturated carboxylic acid with an aliphatic polyhydric alcohol compound, or an amide of an unsaturated carboxylic acid with an aliphatic polyvalent amine compound is preferably used. In addition, a product of an addition reaction of an unsaturated carboxylic acid ester or amide having a nucleophilic substituent such as a hydroxyl group, an amino group, or a mercapto group with a monofunctional or polyfunctional isocyanate or epoxy, and a product of a dehydration condensation reaction of such an unsaturated carboxylic acid ester or amide with a monofunctional or polyfunctional carboxylic acid are also suitably preferably used. In addition, a product of an addition reaction of an unsaturated carboxylic acid ester or amide having an electrophilic substituent such as an isocyanate group or an epoxy group with a monofunctional or polyfunctional alcohol, amine or thiol, and further a product of a substitution reaction of an unsaturated carboxylic acid ester or amide having a leaving substituent such as a halogen group or a tosyloxy group with a monofunctional or polyfunctional alcohol, amine or thiol are also suitable. In addition, as another example, it is also possible to use a group of compounds substituted with unsaturated phosphonic acid, styrene, vinyl ether, or the like in place of the foregoing unsaturated carboxylic acid.

Specific examples of the monomer of an ester of an aliphatic polyhydric alcohol compound with an unsaturated carboxylic acid include acrylic acid esters such as ethylene glycol diacrylate, triethylene glycol diacrylate, 1,3-butanediol diacrylate, tetramethylene glycol diacrylate, propylene glycol diacrylate, neopentyl glycol diacrylate, trimethylolpropane triacrylate, trimethylolpropane tri(acryloyloxypropyl)ether, trimethylolethane triacrylate, hexanediol diacrylate, 1,4-cyclohexanediol diacrylate, tetraethylene glycol diacrylate, pentaerythritol diacrylate, pentaerythritol triacrylate, pentaerythritol tetraacrylate, dipentaerythritol diacrylate, dipentaerythritol hexaacrylate, sorbitol triacrylate, sorbitol tetraacrylate, sorbitol pentaacrylate, sorbitol hexaacrylate, tri (acryloyloxyethyl) isocyanurate, polyester acrylate oligomer, and isocyanuric acid EO-modified triacrylate.

Examples of the methacrylic acid esters include tetramethylene glycol dimethacrylate, triethylene glycol dimethacrylate, neopentyl glycol dimethacrylate, trimethylolpropane trimethacrylate, trimethylolethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, bis[p-(3-methacryloxy-2-hydroxypropoxy)phenyl]dimethylmethane, and bis[p-(methacryloxyethoxy)phenyl]dimethylmethane.

In addition, a urethane-based addition polymerizable compound produced by using an addition reaction of an isocyanate with a hydroxyl group is also suitable, and specific examples thereof include a vinyl urethane compound containing two or more polymerizable vinyl groups in one molecule, which is obtained by addition of a vinyl monomer containing a hydroxyl group in the compound represented by General Formula (I) to a polyisocyanate compound having two or more isocyanate groups in one molecule, which is described in JP1973-041708B (JP-S-48-041708B).

CH₂═C(R)COOCH₂CH(R′)OH (I)

in which R and R′ each represent H or CH₃.

In addition, urethane acrylates described in JP1976-037193A (JP-S-51-037193A), JP1990-032293B (JP-H-02-032293B), and JP1990-016765B (JP-H-02-016765B), and urethane compounds having an ethylene oxide-based skeleton described in JP1983-049860B (JP-S-58-049860B), JP1981-017654B (JP-S-56-017654B), JP1987-039417B (JP-S-62-039417B), and JP1987-039418B (JP-S-62-039418B) are also suitable. Further, use of addition polymerizable compounds having an amino structure or a sulfide structure in the molecule, described in JP1989-277653A (JP-S-63-277653A), JP1989-260909A (JP-S-63-260909A), and JP1989-105238A (JP-H-01-105238A), makes it possible to obtain a curable composition having a very excellent photosensitizing speed.

Other examples of the polymerizable compound include compounds described in paragraphs [0178] to [0190] of JP2007-277514A.

The content of the polymerizable compound in the curable composition is preferably 1% to 90% by mass, more preferably 5% to 80% by mass, and still more preferably 10% to 70% by mass with respect to the total solid content of the composition. In a case where the content of the polymerizable compound is within the above range, the curability of the curable composition is excellent.

In particular, in a case where the curable composition according to the present disclosure is used for forming a colored pattern of a color filter, the content of the polymerizable compound is preferably 5% to 50% by mass, more preferably 7% to 40% by mass, and still more preferably 10% to 35% by mass.

<Alkali-Soluble Resin>

The curable composition according to the present disclosure preferably contains at least one alkali-soluble resin.

The alkali-soluble resin is a high molecular weight polymer, and can be appropriately selected from alkali-soluble resins having at least one group (for example, a carboxyl group, a phosphoric acid group, or a sulfonic acid group) that promotes alkali solubility in a molecule (preferably a molecule having an acrylic-based copolymer or a styrene-based copolymer as a main chain). Of these, more preferred is an alkali-soluble resin which is soluble in an organic solvent and can be developed with a weak alkaline aqueous solution.

For example, a known radical polymerization method can be applied to the production of the alkali-soluble resin. Polymerization conditions such as temperature, pressure, type and amount of radical initiator, and type of solvent in a case of producing an alkali-soluble resin by a radical polymerization method can be easily set by those skilled in the art, and the polymerization conditions can also be determined experimentally.

The high molecular weight polymer is preferably a polymer having a carboxylic acid in a side chain thereof. Examples of such a high molecular weight polymer include polymers having a carboxylic acid in a side chain thereof, such as methacrylic acid copolymers, acrylic acid copolymers, itaconic acid copolymers, crotonic acid copolymers, maleic acid copolymers, and partially esterified maleic acid copolymers, such as those described in, for example, JP1984-044615A (JP-S-59-044615A), JP1979-034327B (JP-S-54-034327B), JP1983-012577B (JP-S-58-012577B), JP1979-025957B (JP-S-54-025957B), JP1984-053836A (JP-59-053836A), and JP1984-071048A (JP-S-59-071048A); acidic cellulose derivatives having a carboxylic acid in a side chain thereof, and polymers obtained by adding an acid anhydride to a polymer having a hydroxyl group. Further, high molecular weight polymers further having a (meth)acryloyl group in a side chain thereof are also preferred.

Specifically, a copolymer of (meth)acrylic acid and other monomers copolymerizable therewith is particularly suitable as the alkali-soluble resin.

Examples of other monomers copolymerizable with (meth)acrylic acid include (meth)acrylic acid esters, crotonic acid esters, vinyl esters, maleic acid diesters, fumaric acid diesters, itaconic acid diesters, (meth)acrylamides, styrenes, vinyl ethers, vinyl ketones, olefins, maleimides, and (meth)acrylonitriles.

Examples of (meth)acrylic acid esters include methyl (meth)acrylate, ethyl (meth)acrylate, n-propyl (meth)acrylate, isopropyl (meth)acrylate, n-butyl (meth)acrylate, isobutyl (meth)acrylate, t-butyl (meth)acrylate, amyl (meth)acrylate, n-hexyl (meth)acrylate, cyclohexyl (meth)acrylate, t-butyl cyclohexyl (meth)acrylate, 2-ethylhexyl (meth)acrylate, t-octyl (meth)acrylate, dodecy (meth)acrylate, octadecyl (meth)acrylate, acetoxyethyl (meth)acrylate, phenyl (meth)acrylate, 2-hydroxy ethyl (meth)acrylate, 2-hydroxypropyl (meth)acrylate, 3-hydroxypropyl (meth)acrylate, 4-hydroxybutyl (meth)acrylate, 2-methoxyethyl (meth)acrylate, 2-ethoxyethyl (meth)acrylate, 2-(2-methoxyethoxy)ethyl (meth)acrylate, 3-phenoxy-2-hydroxypropyl (meth)acrylate, 2-chloroethyl (meth)acrylate, glycidyl (meth)acrylate, 3,4-epoxycyclohexylmethyl (meth)acrylate, vinyl (meth)acrylate, 2-phenylvinyl (meth)acrylate, 1-propenyl (meth)acrylate, allyl (meth)acrylate, 2-aryloxyethyl (meth)acrylate, propargyl (meth)acrylate, benzyl (meth)acrylate, diethylene glycol monomethyl ether (meth)acrylate, diethylene glycol monoethyl ether (meth)acrylate, triethylene glycol monomethyl ether (meth)acrylate, triethylene glycol monoethyl ether (meth)acrylate, polyethylene glycol monomethyl ether (meth)acrylate, polyethylene glycol monoethyl ether (meth)acrylate, β-phenoxyethoxyethyl (meth)acrylate, nonylphenoxy polyethylene glycol (meth)acrylate, dicyclopentenyl (meth)acrylate, dicyclopentenyloxyethyl (meth)acrylate, trifluoroethyl (meth)acrylate, octafluoropentyl (meth)acrylate, perfluorooctylethyl (meth)acrylate, dicyclopentanyl (meth)acrylate, tribromophenyl (meth)acrylate, tribromophenyloxyethyl (meth)acrylate, and γ-butyrolactone (meth)acrylate.

The weight-average molecular weight of the alkali-soluble resin that can be used in the present disclosure is preferably 5,000 or more and more preferably 10,000 to 300,000, and the number-average molecular weight of the alkali-soluble resin that can be used in the present disclosure is preferably 1,000 or more and more preferably 2,000 to 250,000. The polydispersity (weight-average molecular weight/number-average molecular weight) is preferably in the range of 1.1 to 10 and more preferably in the range of 1.2 to 5.

The alkali-soluble resin may be any of a random polymer, a block polymer, a graft polymer, or the like.

Other examples of the alkali-soluble resin include compounds described in paragraphs [0162] to [0175] of JP2007-277514A.

In addition, at least one selected from the group consisting of the first polymer compound and the second polymer compound according to the present disclosure can also be used as the alkali-soluble resin.

The content of the alkali-soluble resin in the curable composition is preferably 1% by mass to 20% by mass, more preferably 2% by mass to 15% by mass, and particularly preferably 3% by mass to 12% by mass with respect to the total solid content of the curable composition.

<Solvent>

The curable composition according to the present disclosure may contain a solvent.

Examples of the solvent include esters such as ethyl acetate, n-butyl acetate, isobutyl acetate, amyl formate, isoamyl acetate, isobutyl acetate, butyl propionate, isopropyl butyrate, ethyl butyrate, butyl butyrate, alkyl esters, methyl lactate, ethyl lactate, alkyl oxyacetates (such as methyl oxyacetates, ethyl oxyacetates, and butyl oxyacetates (for example, methyl methoxyacetate, ethyl methoxyacetate, butyl methoxyacetate, methyl ethoxyacetate, and ethyl ethoxyacetate), alkyl 3-oxypropionates (such as methyl 3-oxypropionates and ethyl 3-oxypropionates (for example, methyl 3-methoxypropionate, ethyl 3-methoxypropionate, methyl 3-ethoxypropionate, and ethyl 3-ethoxypropionate), alkyl 2-oxypropionates (such as methyl 2-oxypropionates, ethyl 2-oxypropionates, and propyl 2-oxypropionates (for example, methyl 2-methoxypropionate, ethyl 2-methoxypropionate, propyl 2-methoxypropionate, methyl 2-ethoxypropionate, ethyl 2-ethoxypropionate, methyl 2-oxy-2-methylpropionate, ethyl 2-oxy-2-methylpropionate, methyl 2-methoxy-2-methylpropionate, and ethyl 2-ethoxy-2-methylpropionate), methyl pyruvate, ethyl pyruvate, propyl pyruvate, methyl acetoacetate, ethyl acetoacetate, methyl 2-oxobutanoate, and ethyl 2-oxobutanoate;

ethers such as diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol methyl ether acetate, propylene glycol ethyl ether acetate, and propylene glycol propyl ether acetate; ketones such as methyl ethyl ketone, cyclohexanone, 2-heptanone, and 3-heptanone; and aromatic hydrocarbons such as toluene and xylene.

Among these, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, ethyl carbitol acetate, butyl carbitol acetate, propylene glycol methyl ether acetate, and the like are suitable.

Solvents may be used alone or in combination of two or more thereof.

<Sensitizer>

The curable composition according to the present disclosure may contain a sensitizer for the purpose of improving the radical generation efficiency of the radical initiator and widening the photosensitive wavelength. The sensitizer that can be used in the present disclosure is preferably a sensitizer that sensitizes the above-mentioned photopolymerization initiator by an electron transfer mechanism or an energy transfer mechanism.

The sensitizer that can be used in the present disclosure includes those belonging to the compounds listed below and having an absorption wavelength in the wavelength range of 300 nm to 450 nm.

Preferred examples of the sensitizer include those belonging to the following compounds and having an absorption wavelength in the wavelength range of 330 nm to 450 nm.

Examples of the sensitizer include polynuclear aromatics (for example, phenanthrene, anthracene, pyrene, perylene, triphenylene, and 9,10-dialkoxyanthracene), xanthenes (for example, fluorescein, eosin, erythrosine, rhodamine B, and rose bengal), thioxanthones (isopropyl thioxanthone, diethyl thioxanthone, and chlorothioxanthone), cyanines (for example, thiacarbocyanine and oxacarbocyanine), merocyanines (for example, merocyanine and carbomerocyanine), phthalocyanines, thiazines (for example, thionine, methylene blue, and toluidine blue), acridines (for example, acridine orange, chloroflavin, and acriflavine), anthraquinones (for example, anthraquinone), squaryliums (for example, squarylium), acridine orange, coumarins (for example, 7-diethylamino-4-methylcoumarin), ketocoumarins, phenothiazines, phenazines, styrylbenzenes, azo compounds, diphenylmethane, triphenylmethane, di styrylbenzenes, carbazoles, porphyrins, spiro compounds, quinacridones, indigo, styryl, pyrylium compounds, pyrromethene compounds, pyrazolotriazole compounds, benzothiazole compounds, barbituric acid derivatives, thiobarbituric acid derivatives, aromatic ketone compounds such as acetophenone, benzophenone, thioxanthone, and Michler's ketone, and heterocyclic compounds such as N-aryloxazolidinone. Further, other examples of the sensitizer include compounds described in EP568993B, U.S. Pat. Nos. 4,508,811A, 5,227,227A, JP2001-125255A, JP1999-271969A (JP-H-11-271969A), and the like.

Sensitizers may be used alone or in combination of two or more thereof.

From the viewpoint of light absorption efficiency in a deep portion and initiation decomposition efficiency, the content of the sensitizer in the curable composition according to the present disclosure is preferably 0.1% to 20% by mass and more preferably 0.5% to 15% by mass with respect to the total solid content of the curable composition.

<Co-Sensitizer>

The curable composition according to the present disclosure may contain a co-sensitizer. The co-sensitizer has a function such as further improving the sensitivity of a sensitizing coloring agent and an initiator to actinic radiation, or preventing the inhibition of polymerization of a polymerizable compound due to oxygen.

In addition, examples of the co-sensitizer include compounds described in paragraphs [0233] to [0241] of JP2007-277514A.

From the viewpoint of improving the curing rate by balancing polymerization growth rate and chain transfer, the content of the co-sensitizer is preferably in the range of 0.1% to 30% by mass, more preferably in the range of 1% to 25% by mass, and still more preferably in the range of 0.5% to 20% by mass with respect to the mass of the total solid content of the curable composition.

<Other Colorants>

The curable composition according to the present disclosure may further contain a colorant other than the particles described above.

Examples of other colorants include a dye.

Examples of the dye include dyes described in JP1989-090403A (JP-S-64-090403A), JP1989-091102A (JP-S-64-091102A), JP1989-094301A (JP-H-01-094301A), JP1994-011614A (JP-H-06-011614A), U.S. Pat. No. 4,808,501A, US0505950A, U.S. Pat. No. 5,667,920A, JP1993-333207A (JP-H-05-333207A), JP1994-035183A (JP-H-06-035183A), JP1994-051115A (JP-H-06-051115A), JP1994-194828A (JP-H-06-194828A), and the like. In a case of being classified as chemical structures, a pyrazole azo compound, a pyromethene compound, an anilinoazo compound, a triarylmethane compound, an anthraquinone compound, a benzylidene compound, an oxonol compound, a pyrazolotriazole azo compound, a pyridone azo compound, a cyanine compound, a phenothiazine compound, a pyrrolopyrazole azomethine compound, and the like can be mentioned.

In addition, a coloring agent multimer may be used as the colorant. The coloring agent multimer is preferably a dye used by being dissolved in a solvent, but may form particles. In a case where the coloring agent multimer is a particle, the coloring agent multimer is used by being dispersed in a solvent or the like. The coloring agent multimer in the particle state can be obtained, for example, by emulsion polymerization. Examples of the coloring agent multimer in the particle state include compounds described in JP2015-214682A. In addition, compounds described in JP2011-213925A, JP2013-041097A, JP2015-028144A, JP2015-030742A, and the like can also be used as the coloring agent multimer.

<Other Components>

The curable composition according to the present disclosure may contain, as necessary, various additives such as a fluorine-based organic compound, a thermal polymerization inhibitor, a photopolymerization initiator, other fillers, a polymer compound other than the polymer compound represented by Formula I, the polymer compound represented by Formula II and the alkali-soluble resin, a surfactant, an adhesion promoter, an antioxidant, an ultraviolet absorber, and an aggregation inhibitor.

Examples of other components include compounds described in paragraphs [0238] to

of JP2007-277514A.

<Preparation of Curable Composition>

The method for preparing the curable composition according to the present disclosure is not particularly limited, and the curable composition can be obtained by mixing individual components contained in the curable composition by a known method.

In addition, in order to improve the dispersibility of particles, the curable composition according to the present disclosure may be obtained in such a manner that the particles are mixed with at least one of the first polymer compound or the second polymer compound to prepare a particle dispersion, and then other components are further added and mixed therewith.

In addition, filtration may be carried out through a filter in order to remove a foreign material or reduce defects. Any filter can be used without particular limitation as long as it has been conventionally used for filtration or the like.

(Cured Product)

The cured product according to the present disclosure is a cured product obtained by curing the curable composition according to the present disclosure.

The curing method is not particularly limited, and examples thereof include curing by exposure to actinic rays such as ultraviolet light and curing by heating.

The cured product according to the present disclosure is preferably in the form of a thin film, for example.

The cured product according to the present disclosure is suitably used as a color filter, an infrared absorption filter, a black matrix provided between pixels of the color filter, a refractive index adjusting film, or the like, and is particularly suitably used as the color filter.

(Color Filter and Production Method Thereof)

The color filter according to the present disclosure comprises the cured product according to the present disclosure.

The color filter according to the present disclosure preferably comprises the cured product according to the present disclosure on a support.

In the color filter, the cured product according to the present disclosure may be a pixel of the color filter or a black matrix provided between the pixels of the color filter, or may be both the pixel of the color filter and the black matrix.

Hereinafter, the color filter according to the present disclosure will be described in detail through the production method thereof.

(First Aspect of Method for Producing Color Filter)

A first aspect of the method for producing a color filter according to the present disclosure includes a step of applying the curable composition according to the present disclosure onto a support to form a composition film (composition film forming step), a step of exposing the formed composition film in a pattern-wise manner (hereinafter, abbreviated as “exposing step” where appropriate), and a step of developing the composition film after exposure to form a pattern (hereinafter, abbreviated as “developing step” where appropriate).

Hereinafter, individual steps will be described.

<Composition Film Forming Step>

In the composition film forming step, the curable composition according to the present disclosure is applied onto a support to form a composition film.

Examples of the support which can be used in the present step include a soda glass, a Pyrex (registered trademark) glass, a quartz glass, and those glasses with a transparent conductive film attached thereto which are used in a liquid crystal display element or the like, a photoelectric conversion element substrate used in an imaging element or the like, for example, a silicon substrate, and a complementary metal oxide film semiconductor (CMOS). On these substrates, a black stripe, which isolates individual pixels, is formed in some cases.

In addition, on these substrates, as necessary, an undercoat layer (another layer) may be provided for improving adhesion with an upper layer, preventing diffusion of a substance, or flattening a substrate surface.

As the method for applying the curable composition according to the present disclosure onto the support, various application methods such as slit coating, ink jet method, spin coating, cast coating, roll coating, and screen printing can be applied.

The coating film thickness of the curable composition is preferably 0.1 μm to 10 μm, more preferably 0.2 μm to 5 μm, and still more preferably 0.2 μm to 3 μm.

The composition film applied onto the support may be dried (pre-baked) at a temperature of 50° C. to 140° C. for 10 seconds to 300 seconds using a hot plate, an oven, or the like.

<Exposing Step>

In the exposing step, the composition film formed in the composition film forming step is exposed in a pattern-wise manner. The method of exposing the composition film in a pattern-wise manner may be, for example, a method of exposing the composition film through a mask having a predetermined mask pattern.

In the present step, in a case where the curable composition according to the present disclosure is a negative curable composition, a light-irradiated portion can be cured. In a case where the curable composition according to the present disclosure is a positive curable composition, the solubility of the light-irradiated portion in a developer increases.

As the radiation that can be used in the exposure, ultraviolet rays such as g-line and i-line are particularly preferably used. The exposure amount is preferably 5 mJ/cm² to 1500 mJ/cm², more preferably 10 mJ/cm² to 1000 mJ/cm², and most preferably 10 mJ/cm² to 500 mJ/cm².

In a case where the color filter according to the present disclosure is for a liquid crystal display element, the exposure amount is preferably 5 mJ/cm² to 200 mJ/cm², more preferably 10 mJ/cm² to 150 mJ/cm², and most preferably 10 mJ/cm² to 100 mJ/cm², in the above range. In addition, in a case where the color filter according to the present disclosure is for a solid-state imaging element, the exposure amount is preferably 30 mJ/cm² to 1500 mJ/cm², more preferably 50 mJ/cm² to 1000 mJ/cm², and most preferably 80 mJ/cm² to 500 mJ/cm², in the above range.

<Developing Step>

Next, by carrying out a development treatment, an unexposed portion in the exposing step is eluted in a developer, and therefore a photocured portion is obtained as a pattern. The developer is not particularly limited as long as it can remove the curable composition in an uncured portion, and a known developer can be used. Specifically, a combination of various organic solvents or an alkaline aqueous solution can be used as the developer.

The development temperature is preferably 20° C. to 30° C., and the development time is preferably 20 seconds to 90 seconds.

Examples of the organic solvent include the above-mentioned solvents that can be used in a case of preparing the pigment dispersion composition or curable composition according to the present disclosure.

As the alkaline aqueous solution, an alkaline aqueous solution obtained by diluting an alkaline compound, such as sodium hydroxide, potassium hydroxide, sodium carbonate, sodium hydrogen carbonate, sodium silicate, sodium metasilicate, ammonia water, ethylamine, diethylamine, dimethylethanolamine, tetramethylammonium hydroxide, tetraethylammonium hydroxide, choline, pyrrole, piperidine, or 1,8-diazabicyclo-[5.4.0]-7-undecene, with pure water so as to have a concentration of 0.001% by mass to 10% by mass and preferably 0.01% by mass to 1% by mass is preferably used as the developer.

In addition, in a case where the developer consisting of such an alkaline aqueous solution is used, an aspect of washing (rinsing) with pure water after development is also preferred.

After the developing step, an excess developer may be washed away and drying may be carried out, followed by a heat treatment (post-baking).

The post-baking is a heat treatment after development, and preferably a heat curing treatment at 100° C. to 240° C. is carried out. In a case where the substrate is a glass substrate or a silicon substrate, 200° C. to 240° C. is preferable in the above temperature range.

The post-baking treatment can be carried out continuously or batchwise using a heating means such as a hot plate, a convection oven (hot air circulation dryer), or a high-frequency heater such that the coating film after development is in the above condition.

A color filter having desired hues is produced by repeating the above-mentioned steps of the composition film forming step, the exposing step, and the developing step (further, the heat treatment when necessary) only a number of times corresponding to the number of desired hues.

In a case where a film is formed by applying the curable composition according to the present disclosure onto a substrate, the dry thickness of the film is preferably 0.3 μm to 5.0 μm, more preferably 0.5 μm to 3.5 μm, and still more preferably 1.0 μm to 2.5 μm.

Examples of the substrate include a non-alkali glass, a soda glass, a Pyrex (registered trademark) glass, a quartz glass, and those glasses with a transparent conductive film attached thereto which are used in a liquid crystal display element or the like, a photoelectric conversion element substrate used in a solid-state imaging element or the like, for example, a silicon substrate, and a plastic substrate. A black stripe for isolating individual pixels is preferably formed on these substrates.

The plastic substrate preferably has a gas barrier layer and/or a solvent resistant layer on the surface thereof.

The above production method is a method for producing a pixel of a color filter, but according to the curable composition according to the present disclosure, for example, a black matrix provided between the pixels of the color filter is also produced. The black matrix can be formed, for example, by carrying out pattern-wise exposure, alkali development, and then post-baking to accelerate the curing of the film in the same manner as in the above-mentioned pixel production method, except that a black colorant such as carbon black or titanium black is added as the colorant to the curable composition according to the present disclosure.

(Second Aspect of Method for Producing Color Filter)

A second aspect of the method for producing a color filter according to the present disclosure includes a step of applying the curable composition according to the present disclosure onto a support and curing the applied curable composition to form a cured product (cured product forming step); a step of forming a photoresist layer on the cured product (photoresist layer forming step); a step of exposing the photoresist layer in a pattern-wise manner and developing the exposed photoresist layer to form a resist pattern (resist pattern forming step); and a step of etching the cured product through the resist pattern (etching step). Hereinafter, individual steps will be described.

<Cured Product Forming Step>

In the cured product forming step, the curable composition according to the present disclosure is applied onto a support and cured to form a cured product.

The support in the composition film forming step described above is preferably used as the support.

In addition, the application method in the composition film forming step described above is preferably used as the method for applying the curable composition.

The method for curing the applied curable composition is not particularly limited, and it is preferable to cure the applied curable composition by light or heat.

In a case where the curable composition is cured by light, the light may be appropriately selected according to the initiator contained in the composition. For example, ultraviolet rays such as g-line and i-line are preferably used. The exposure amount is preferably 5 mJ/cm² to 1500 mJ/cm², more preferably 10 mJ/cm² to 1000 mJ/cm², and most preferably 10 mJ/cm² to 500 mJ/cm².

In a case where the curable composition is cured by heat, the heating temperature is preferably 120° C. to 250° C. and more preferably 160° C. to 230° C. The heating time varies depending on the heating means, but is preferably about 3 to 30 minutes in a case of being heated on a hot plate and preferably about 30 to 90 minutes in a case of being heated in an oven.

<Photoresist Layer Forming Step>

In the photoresist layer forming step, a photoresist layer is formed on the cured product.

In the formation of the photoresist layer, for example, a known negative or positive photosensitive composition is used, and a positive photosensitive composition is preferable.

The photoresist layer is obtained by applying the photosensitive composition onto the cured product and drying the applied photosensitive composition as necessary.

The method for forming the photoresist layer is not particularly limited, and may be carried out by a known method.

The thickness of the photoresist layer is preferably 0.1 μm to 3 μm, more preferably 0.2 μm to 2.5 μm, and still more preferably 0.3 μm to 2 μm.

<Resist Pattern Forming Step>

In the resist pattern forming step, the photoresist layer is exposed in a pattern-wise manner and developed to form a resist pattern.

The exposure and development are not particularly limited and are carried out by a known method.

<Etching Step>

In the etching step, the colored layer is etched through the resist pattern.

The etching method is not particularly limited, and may be carried out by a known method, for example, a dry etching method.

<Step of Peeling Resist Pattern>

The second aspect of the method for producing a color filter according to the present disclosure may further include a step of peeling the resist pattern after the etching step.

The method of peeling the resist pattern is not particularly limited, and a known method is used.

(Image Display Device)

The image display device according to the present disclosure (for example, a liquid crystal display device, an organic electroluminescence (EL) display device, or an electronic paper) includes the color filter according to the present disclosure.

Specifically, for example, an alignment film is formed on an inner surface side of the color filter, the alignment film is opposed to an electrode substrate, and a gap portion therebetween is filled with liquid crystal and then sealed, whereby a liquid crystal panel that is the image display device according to the present disclosure is obtained.

The definition of the liquid crystal display device or details of the respective display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd., published in 1989), and the like. In addition, the liquid crystal display device is described in, for example, “Next-Generation Liquid Crystal Display Technology (edited by Tatsuo Uchida, Kogyo Chosakai Publishing Co., Ltd., published in 1994)”. The liquid crystal display device to which the present disclosure can be applied is not particularly limited, and for example, the present disclosure can be applied to various types of liquid crystal display devices described in the “Next-Generation Liquid Crystal Display Technology”.

(Solid-State Imaging Element)

The solid-state imaging element according to the present disclosure (for example, an image sensor such as a charge coupled device (CCD) or a complementary metal oxide semiconductor (CMOS)) includes the color filter according to the present disclosure.

For example, the solid-state imaging element according to the present disclosure can be obtained by forming a color filter on a light-receiving element.

Specifically, the solid-state imaging element according to the present disclosure has a configuration which has a plurality of photodiodes constituting a light-receiving area of a solid-state imaging element (a CCD image sensor, a CMOS image sensor, or the like) and transfer electrodes formed of polysilicon or the like, on a substrate; a light shielding film formed of tungsten or the like onto the photodiodes and the transfer electrodes, which has openings only over the light-receiving portion of the photodiode; a device protecting film formed of silicon nitride or the like, which is formed so as to cover the entire surface of the light shielding film and the light-receiving portion of the photodiodes, on the light shielding film; and a color filter for a solid-state imaging element according to the present disclosure on the device protecting film.

In addition, the solid-state imaging element according to the present disclosure may have a configuration in which a light-collecting means (for example, a microlens, the same applies hereinafter) is disposed on the device protecting film and under the color filter (on the side closer to the support), a configuration in which a light-collecting means is disposed on the color filter, or the like.

### EXAMPLES

Hereinafter, the present disclosure will be described in more detail with reference to Examples, but the present disclosure is not limited thereto.

In the Examples, “%” and “part(s)” refer to “% by mass” and “part(s) by mass”, respectively, unless otherwise specified. In addition, unless otherwise specified, in the polymer compound, the molecular weight is a weight-average molecular weight (Mw), and the ratio of the constitutional repeating units is a mole percentage.

The weight-average molecular weight (Mw) is a value measured as a polystyrene conversion value by a gel permeation chromatography (GPC) method.

In the Examples, the description of polymer compounds 1-1 to 1-10 and 2-1 and 2-2 represents the same compounds as the polymer compounds 1-1 to 1-10 and 2-1 and 2-2 described as the foregoing specific examples.

### Synthesis Example 1: Synthesis of Polymer Compound 1-1

A mixed solution of 36.25 parts of a 20% by mass solution of chain transfer agent B-1 (structure shown below) obtained by the synthesis method described in JP2007-177514A, 14.54 parts of methacrylic acid (MAA; monomer 1), and 20 parts of methyl methacrylate (MMA; monomer 2) was adjusted to a 30% by mass 1-methoxy-2-propanol solution which was then heated to 75° C. under a nitrogen stream.

0.5 parts of dimethyl 2,2′-azobis(isobutyrate) (initiator, V-601, manufactured by Wako Pure Chemical Industries, Ltd.) were added thereto, followed by heating for 3 hours, and 0.5 parts of V-601 were further added, followed by reaction at 90° C. for 3 hours under a nitrogen stream. This was followed by cooling to room temperature (25° C., the same applies hereinafter) and purging with air, and 12.46 parts of glycidyl methacrylate (epoxy monomer, GMA), 1.02 parts of dimethyldodecylamine, and 0.023 parts of TEMPO were added, followed by heating and stirring at 90° C. for 36 hours.

This was followed by cooling to room temperature and dilution with acetone. After reprecipitation using a large amount of methanol, vacuum drying was carried out to obtain 35 parts of a solid of polymer compound 1-1 (weight-average molecular weight in terms of polystyrene: 12000, acid value: 84 mgKOH/g).

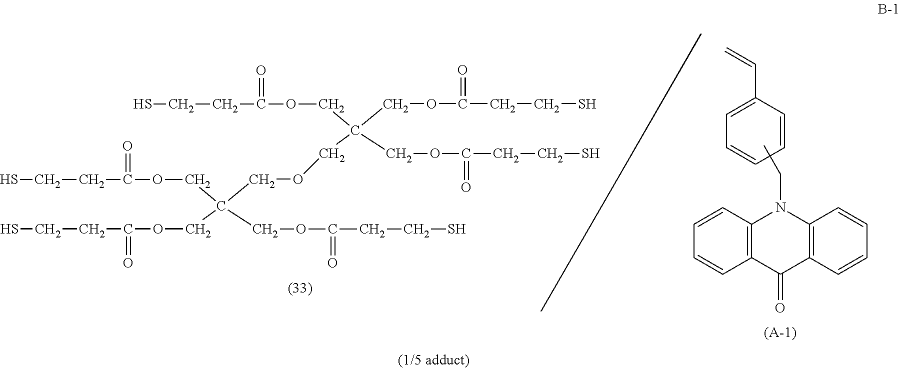

### Synthesis Examples 2 to 4: Synthesis of Polymer Compounds 1-2 to 1-4

Polymer compounds 1-2 to 1-4 were synthesized in the same manner as in Synthesis Example 1, except that the chain transfer agent, monomer 1, monomer 2, and initiator used were changed as shown in Table 1.

In Table 1, the description in the column of specific absorbance indicates “specific absorbance represented by Expression Aλ”.

TABLE 1

| | | | | | | | | | Poly- | | | | | |
|---|---|---|---|---|---|---|---|---|---|---|---|---|---|---|
| | | | | | | | | | merization | | | Weight- | Acid | |
| | Chain | Parts | Mon- | Parts | Mon- | Parts | | Parts | concen- | | Parts | average | value | Specific |
| | transfer | by | omer | by | omer | by | | by | tration | Epoxy | by | molecular | mgKOH/ | absor- |
| | agent | mass | 1 | mass | 2 | mass | Initiator | mass | % by mass | monomer | mass | weight | g | bance |
| Polymer | B-1 | 7.25 | MAA | 14.54 | MMA | 20 | V-601 | 0.50 | 30 | GMA | 12.46 | 12000 | 84 | 1 |
| compound | | | | | | | | | | | | | | |
| 1-1 | | | | | | | | | | | | | | |
| Polymer | B-2 | 7.25 | M-5300 | 19 | BzMA | 20 | V-601 | 0.75 | 30 | 4-HBAGE | 8 | 9800 | 24 | 1 |
| compound | | | | | | | | | | | | | | |
| 1-2 | | | | | | | | | | | | | | |
| Polymer | B-3 | 7.25 | M-5300 | 19.74 | BzMA | 40 | V-601 | 0.50 | 30 | GAM | 7.26 | 13700 | 18 | 1 |
| compound | | | | | | | | | | | | | | |
| 1-3 | | | | | | | | | | | | | | |
| Polymer | B-4 | 7.25 | M-5300 | 32.1 | BzMA | 80 | V-601 | 0.50 | 30 | CYCLO- | 7.9 | 25900 | 41 | 0 |
| compound | | | | | | | | | | MER | | | | |
| 1-4 | | | | | | | | | | M-100 | | | | |

Among the compounds shown in Table 1, details of compounds other than the above-mentioned compounds are as follows.

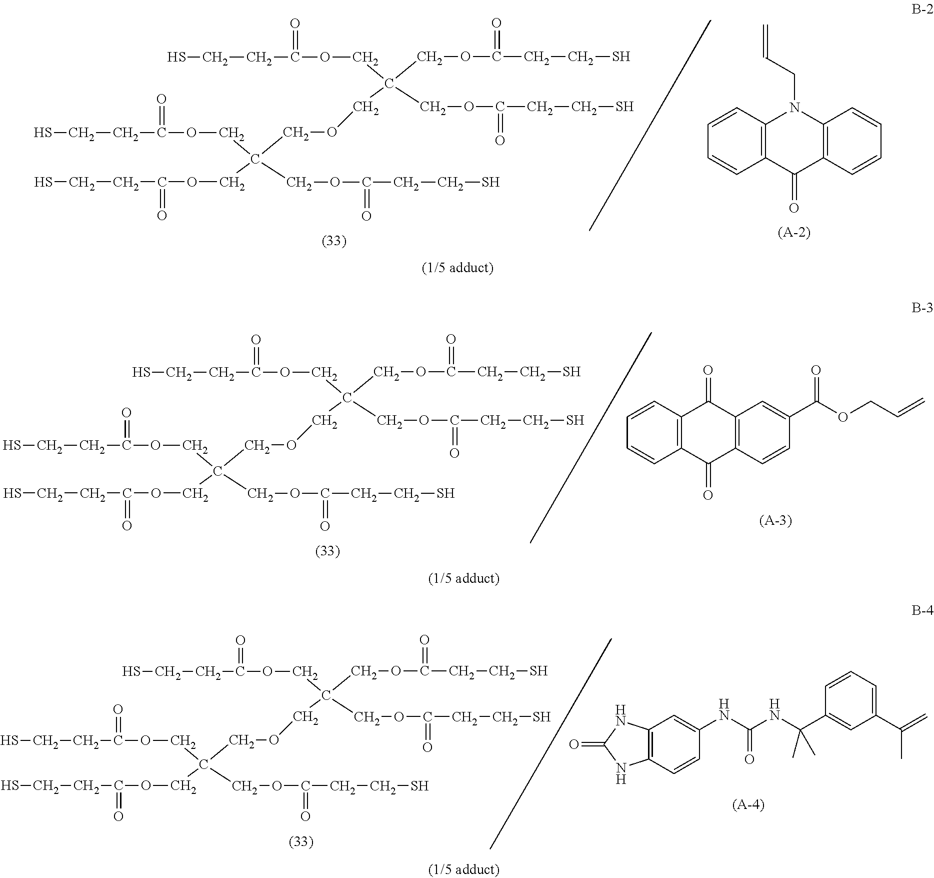

M-5300: ω-carboxy-polycaprolactone (n≈2) monoacrylate, manufactured by Toagosei Co., Ltd.
BzMA: benzyl methacrylate, manufactured by Tokyo Chemical Industry Co., Ltd.
4-HBAGE: 4-hydroxybutyl acrylate glycidyl ether, manufactured by Nihon Kasei Co., Ltd.
GAM: N,N-hydroxyethylacrylamide glycidyl ether (synthesized with reference to WO2015/146876A)
Cyclomer M-100: 3,4-epoxycyclohexylmethyl methacrylate, manufactured by Daicel Corporation

### Synthesis Example 5: Synthesis of Polymer Compound 1-5

A mixed solution of 36.25 parts of a 20% by mass solution of chain transfer agent B-5 (structure shown below) obtained by the synthesis method described in JP2007-177514A, 20 parts of BzMA, and 21.4 parts of ARONIX M-5300 (manufactured by Toagosei Co., Ltd.) was adjusted to a 30% by mass 1-methoxy-2-propanol solution which was then heated to 75° C. under a nitrogen stream.

0.5 parts of V-601 were added thereto, followed by heating for 3 hours, and 0.5 parts of V-601 were further added, followed by reaction at 90° C. for 3 hours under a nitrogen stream. This was followed by cooling to room temperature and purging with air, and 12.46 parts of glycidyl methacrylate, 1.02 parts of dimethyldodecylamine, and 0.023 parts of TEMPO were added, followed by heating and stirring at 90° C. for 36 hours.

Thereafter, 0.23 parts of TEMPO, 7.31 parts of chlorostyrene, and 40.9 parts of potassium carbonate were added thereto, followed by stirring at 80° C. for 5 hours. This was followed by cooling to 5° C. and dilution with acetone, and 800 parts of 1 mol/L aqueous hydrochloric acid were added dropwise, and 400 parts of butyl acetate were added, followed by extraction. Thereafter, 400 parts of water were added to carry out washing with water, and concentration under reduced pressure was carried out to distill off residual water and butyl acetate in the system. 35 parts of a solid of polymer compound 1-5 (weight-average molecular weight in terms of polystyrene: 12000, acid value: 84 mgKOH/g) were obtained by addition of PGMEA such that the solid content was 30 wt %, reprecipitation, and then vacuum drying.

The specific absorbance represented by Expression Aλ of compound 1-5 was 0.

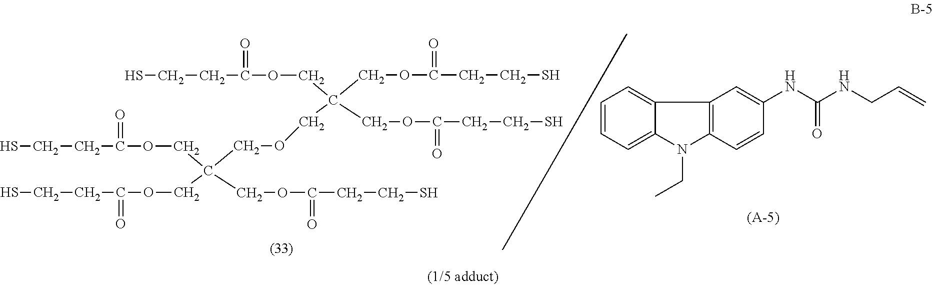 [SMILES: O=C(CCS)OCC(COCC(COC(=O)CCS)(COC(=O)CCS)COC(=O)CCS)(COC(=O)CCS)COC(=O)CCS ; C=CCNC(=O)Nc1ccc2c(c1)c1ccccc1n2CC ; "(A-5)"]

### Synthesis Example 6: Synthesis of Polymer Compound 1-6

A mixed solution of 24.17 parts of a 30% by mass solution of chain transfer agent B-15 (structure shown below) obtained by the synthesis method described in JP2007-177514A, 20 parts of MMA, and 29.59 of hydroxyethyl methacrylate (HEMA) was adjusted to a 30% by mass 1-methoxy-2-propanol solution which was then heated to 75° C. under a nitrogen stream.

0.5 parts of V-601 were added thereto, followed by heating for 3 hours, and 0.5 parts of V-601 were further added, followed by reaction at 90° C. for 3 hours under a nitrogen stream. This was followed by cooling to room temperature and purging with air, and 10.41 parts of KARENZ AOI (manufactured by Showa Denko KK), 0.5 parts of NEOSTAN U600 (manufactured by Nitto Kasei Co., Ltd.), and 0.023 parts of TEMPO were added, followed by heating and stirring at 90° C. for 36 hours.

This was followed by cooling to room temperature and dilution with acetone. After reprecipitation using a large amount of methanol, vacuum drying was carried out to obtain 51 parts of a solid of polymer compound 1-6 (weight-average molecular weight in terms of polystyrene: 17300, acid value: 21 mgKOH/g).

The specific absorbance represented by Expression Aλ of compound 1-6 was 0.

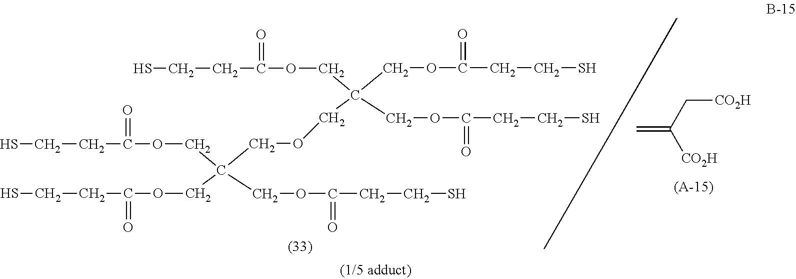

### Synthesis Example 7: Synthesis of Polymer Compound 1-7

A mixed solution of 24.17 parts of a 30% by mass solution of chain transfer agent B-24 (structure shown below) obtained by the synthesis method described in JP2007-177514A, 20 parts of acetoxyethyl methacrylate (AAEM), and 27.04 parts of HEMA was adjusted to a 30% by mass 1-methoxy-2-propanol solution which was then heated to 75° C. under a nitrogen stream.

0.5 parts of V-601 were added thereto, followed by heating for 3 hours, and 0.5 parts of V-601 were further added, followed by reaction at 90° C. for 3 hours under a nitrogen stream. This was followed by cooling to room temperature and purging with air, and 12.96 parts of KARENZ BEI (manufactured by Showa Denko KK), 0.61 parts of NEOSTAN U600 (manufactured by Nitto Kasei Co., Ltd.), and 0.023 parts of TEMPO were added, followed by heating and stirring at 90° C. for 36 hours.

This was followed by cooling to room temperature and dilution with acetone. After reprecipitation using a large amount of methanol, vacuum drying was carried out to obtain 53 parts of a solid of polymer compound 1-7 (weight-average molecular weight in terms of polystyrene: 16500, acid value: 17 mgKOH/g).

The specific absorbance represented by Expression Aλ of polymer compound 1-7 was 0.

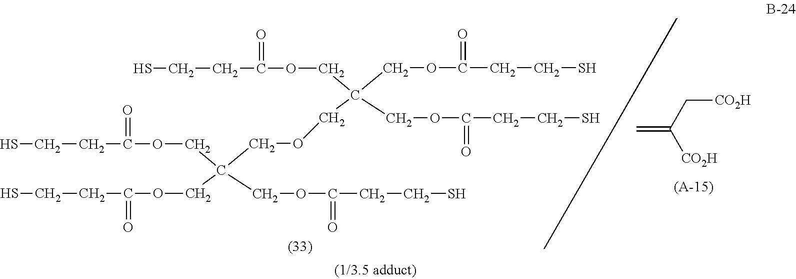

### Synthesis Example 8: Synthesis of Polymer Compound 1-8

A mixed solution of 24.17 parts of a 30% by mass solution of chain transfer agent B-23 (structure shown below) obtained by the synthesis method described in JP2007-177514A, 20 parts of PSE1300 (manufactured by NOF Corporation), and 33.68 parts of HEMA was adjusted to a 30% by mass 1-methoxy-2-propanol solution which was then heated to 75° C. under a nitrogen stream.

0.5 parts of V-601 were added thereto, followed by heating for 3 hours, and 0.5 parts of V-601 were further added, followed by reaction at 90° C. for 3 hours under a nitrogen stream. This was followed by cooling to room temperature and purging with air, and 16.32 parts of KARENZ MOI (manufactured by Showa Denko KK), 0.5 parts of NEOSTAN U600 (manufactured by Nitto Kasei Co., Ltd.), and 0.023 parts of TEMPO were added, followed by heating and stirring at 90° C. for 36 hours.

This was followed by cooling to room temperature and dilution with acetone. After reprecipitation using a large amount of methanol, vacuum drying was carried out to obtain 58 parts of a solid of polymer compound 1-8 (weight-average molecular weight in terms of polystyrene: 21000, acid value: 13 mgKOH/g).

The specific absorbance represented by Expression Aλ of polymer compound 1-8 was 0.

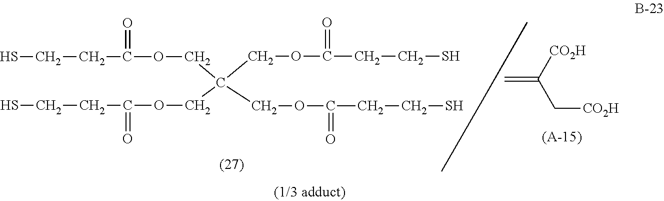

### Synthesis Example 9: Synthesis of Polymer Compound 1-9

<Synthesis of Polyester Chain-Containing Monomer>

1256.6 g of ε-caprolactone and 143.38 g of 2-ethyl-1-hexanol were introduced into a three-neck flask and dissolved by stirring while blowing nitrogen. 0.628 g of monobutyltin oxide was added to the flask, and the contents of the flask were heated to 90° C.

After 5 hours, it was confirmed by gas chromatography that ε-caprolactone had disappeared, followed by stirring at 110° C. for 2 hours. The contents of the flask were then cooled to 80° C. After 0.785 g of 2,6-di-t-butyl-4-methylphenol was added to the flask, 174.15 g of 2-methacryloyloxyethyl isocyanate was further added dropwise thereto. After 3 hours, it was confirmed by ¹H-NMR that the raw material had disappeared, and then the contents of the flask were cooled to room temperature to obtain 1575.6 g of a solid polyester chain-containing monomer.

A mixed solution of 24.17 parts of a 30% by mass solution of chain transfer agent B-23 (structure shown above) obtained by the synthesis method described in JP2007-177514A, 20 parts of the above-mentioned polyester chain-containing monomer, 20 parts of 2-methacryloyloxyethyl succinate, and 40 parts of 2-((3-chloropropanoyl)oxy)ethyl methacrylate was adjusted to a 30% by mass 1-methoxy-2-propanol solution which was then heated to 75° C. under a nitrogen stream.

0.5 parts of V-601 were added thereto, followed by heating for 3 hours, and 0.5 parts of V-601 were further added, followed by reaction at 90° C. for 3 hours under a nitrogen stream.

This was followed by cooling to room temperature and purging with air, and 46 parts of triethylamine and 0.1 parts of TEMPO were added, followed by heating and stirring at 60° C. for 6 hours. This was followed by cooling to room temperature, and 12.4 parts of methanesulfonic acid were added dropwise in an ice bath. After reprecipitation using a large amount of methanol:water=1:1 mixed solution, vacuum drying was carried out to obtain 58 parts of a solid of polymer compound 1-9 (weight-average molecular weight in terms of polystyrene: 24500, acid value: 68 mgKOH/g).

The specific absorbance represented by Expression Aλ of polymer compound 1-9 was 0.

### Synthesis Example 10: Synthesis of Polymer Compound 1-10

A mixed solution of 36.25 parts of a 30% by mass solution of chain transfer agent B-23 (structure shown above) obtained by the synthesis method described in JP2007-177514A, 20 parts of PSE1300 (manufactured by NOF Corporation), and 60 parts of ethylene glycol mono-2-bromoisobutyrate monomethacrylate was adjusted to a 30% by mass 1-methoxy-2-propanol solution which was then heated to 75° C. under a nitrogen stream.

0.5 parts of V-601 were added thereto, followed by heating for 3 hours, and 0.5 parts of V-601 were further added, followed by reaction at 90° C. for 3 hours under a nitrogen stream. This was followed by cooling to room temperature and purging with air, and 69.1 parts of diazabicycloundecene (DBU) and 0.2 parts of TEMPO were added, followed by heating and stirring at room temperature for 16 hours.

Thereafter, 43.7 parts of methanesulfonic acid were added dropwise in an ice bath. After reprecipitation using a large amount of methanol:water=1:1 mixed solution, vacuum drying was carried out to obtain 64 parts of a solid of polymer compound 1-10 according to the present disclosure shown below (weight-average molecular weight in terms of polystyrene: 15300).

The specific absorbance represented by Expression Aλ of polymer compound 1-10 was 0.71.

### Synthesis Example 11: Synthesis of Polymer Compound 2-1

<Synthesis of Polyfunctional Halogen Compound H-1>

25.3 parts of dipentaerythritol, 91.8 parts of sodium bromide, and 182.3 parts of dimethylacetamide were placed in a three-neck flask and stirred in an ice bath, and 151.7 parts of 2-bromoisobutyrobromide were added dropwise thereto over 1 hour.

This was followed by stirring for 2 hours in a water bath, 170 parts of ethyl acetate and 170 parts of cyclohexane were added dropwise while stirring again in an ice bath, and then 67.5 parts of water and 360 parts of 8% by mass sodium bicarbonate water were continuously added dropwise. After discarding the aqueous layer, 360 parts of 10% by mass aqueous sodium sulfate were added dropwise while stirring the organic layer. After 10 minutes of stirring, the aqueous layer was discarded. The resulting organic layer was concentrated under reduced pressure to obtain 110 parts of polyfunctional halogen compound H-1 (structure shown below).

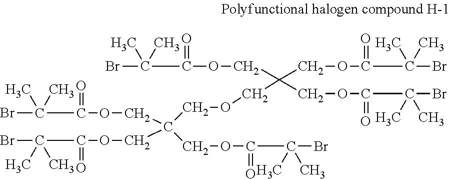 [SMILES: CC(C)(Br)C(=O)OCC(COCC(COC(=O)C(C)(C)Br)(COC(=O)C(C)(C)Br)COC(=O)C(C)(C)Br)(COC(=O)C(C)(C)Br)COC(=O)C(C)(C)Br]

<Synthesis of Polyfunctional Halogen Compound H-2>

57.4 parts of polyfunctional halogen compound H-1 and 90 parts of dimethylacetamide were placed in a three-neck flask, and 37.8 parts of anthraquinone-2-carboxylic acid and 31.1 parts of potassium carbonate were added thereto, followed by stirring at 80° C. for 6 hours.

The reaction solution was stirred in an ice bath, and 1000 parts of 1 mol/1 aqueous hydrochloric acid were added dropwise thereto, followed by extraction with 1000 parts of ethyl acetate. Thereafter, the aqueous layer was discarded, 1000 parts of water were added to carry out washing with water, and the resulting organic layer was concentrated under reduced pressure to obtain 81 parts of polyfunctional halogen compound H-2.

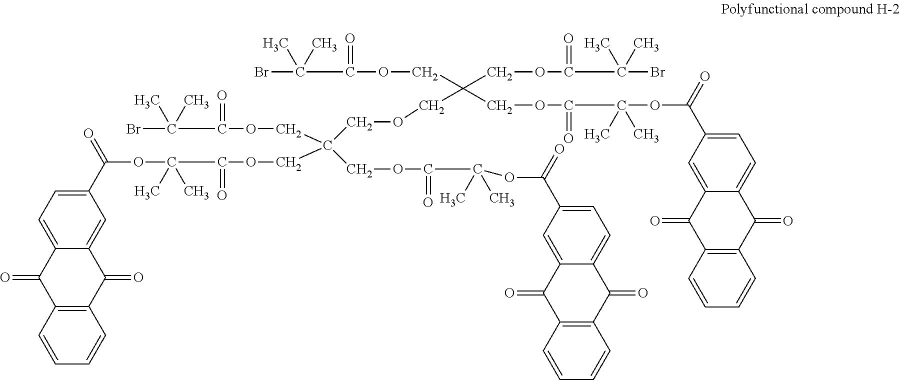 [SMILES: CC(C)(Br)C(=O)OCC(COCC(COC(=O)C(C)(C)Br)(COC(=O)C(C)(C)OC(=O)c1ccc2c(c1)C(=O)c1ccccc1C2=O)COC(=O)C(C)(C)OC(=O)c1ccc2c(c1)C(=O)c1ccccc1C2=O)(COC(=O)C(C)(C)Br)COC(=O)C(C)(C)OC(=O)c1ccc2c(c1)C(=O)c1ccccc1C2=O]

<Synthesis of Polymer Compound 2-1>

280 parts of tetrahydrofuran (THF) and 55 parts of lithium chloride (2.6% by mass THF solution) were added to a flask which was then cooled to −60° C. 7.4 parts of n-butyllithium (15.4% by mass hexane solution) were added thereto, followed by stirring for 5 minutes, and 3 parts of diphenylethylene were added thereto, followed by stirring for 15 minutes. A mixed monomer solution of 66.8 parts of benzyl methacrylate and 53.8 parts of tert-butyl methacrylate was added dropwise thereto, and the reaction was continued for 30 minutes. Then, gas chromatography (GC) was measured to confirm the disappearance of the monomer, and resin solution P-1 was obtained.

Subsequently, 280 parts of tetrahydrofuran (THF) and 55 parts of lithium chloride (2.6% by mass THF solution) were added to a flask which was then cooled to −60° C. 7.4 parts of n-butyllithium (15.4% by mass hexane solution) were added thereto, followed by stirring for 5 minutes, and 3 parts of diphenylethylene were added thereto, followed by stirring for 15 minutes. A mixed monomer solution of 66.8 parts of benzyl methacrylate and 59.9 parts of 1-ethoxyethyl methacrylate was added dropwise, and the reaction was continued for 30 minutes. Then, gas chromatography (GC) was measured to confirm the disappearance of the monomer and resin solution P-2 was obtained.

While the obtained resin solution P-1 was kept at −60° C., it was quickly added to the resin solution P-2 which was also kept at −60° C. so as not to exceed −60° C. After stirring for 5 minutes, 195 g of a THF solution containing 10% by mass of 19.5 g of polyfunctional halogen compound H-2 was added dropwise thereto over 30 minutes while maintaining the temperature at −60° C. Then, the temperature was returned to room temperature over 10 hours and the reaction was finished. This was followed by adjustment to a 30% by mass 1-methoxy-2-propanol solution by concentration under reduced pressure, and then heating to 160° C. to be adjusted to a 40% by mass 1-methoxy-2-propanol solution while reducing the pressure. 53.8 parts of glycidyl methacrylate, 10 parts of dimethyldodecylamine, and 0.5 parts of TEMPO were added to this solution which was then heated at 90° C. for 36 hours. Thereafter, the temperature was returned to room temperature, 30 parts of trifluoroacetic acid were added thereto, followed by stirring for 1 hour, and the reaction solution was added dropwise to a large amount of methanol:water=1:1 mixed solution to obtain 201 parts of polymer compound 2-1.

The specific absorbance represented by Expression Aλ of polymer compound 2-1 was 2.

In polymer compound 2-1, the polymer chain corresponding to P²¹ in Formula II, which is a structure derived from the resin contained in resin solution P-1, had a weight-average molecular weight of 4800, an acid value of 211, and a polymerizable group value of 0.

In addition, the polymer chain corresponding to P²² in Formula II, which is a structure derived from the resin contained in resin solution P-2, had a weight-average molecular weight of 4400, an acid value of 2, and a polymerizable group value of 2.31.

(Synthesis Example 12: Synthesis of polymer compound 2-2) 280 parts of tetrahydrofuran (THF) and 55 parts of lithium chloride (2.6% by mass THF solution) were added to a flask which was then cooled to −60° C. 7.4 parts of n-butyllithium (15.4% by mass hexane solution) were added thereto, followed by stirring for 5 minutes, and 3 parts of diphenylethylene were added thereto, followed by stirring for 15 minutes. A mixed monomer solution of 66.8 parts of benzyl methacrylate and 53.8 parts of tert-butyl methacrylate was added dropwise thereto, and the reaction was continued for 30 minutes. Then, gas chromatography (GC) was measured to confirm the disappearance of the monomer, and resin solution P-1 was obtained.

Subsequently, 280 parts of tetrahydrofuran (THF) and 55 parts of lithium chloride (2.6% by mass THF solution) were added to a flask which was then cooled to −60° C. 7.4 parts of n-butyllithium (15.4% by mass hexane solution) were added thereto, followed by stirring for 5 minutes, and 3 parts of diphenylethylene were added thereto, followed by stirring for 15 minutes. A mixed monomer solution of 66.8 parts of benzyl methacrylate and 59.9 parts of 1-ethoxyethyl methacrylate was added dropwise, and the reaction was continued for 30 minutes. Then, gas chromatography (GC) was measured to confirm the disappearance of the monomer and resin solution P-2 was obtained.

While the obtained resin solution P-1 was kept at −60° C., it was quickly added to the resin solution P-2 which was also kept at −60° C. so as not to exceed −60° C. After stirring for 5 minutes, 67.5 g of a THF solution containing 10% by mass of 6.75 g of polyfunctional halogen compound H-1 was added dropwise thereto over 30 minutes while maintaining the temperature at −60° C. Then, the temperature was returned to room temperature over 10 hours and the reaction was finished. This was followed by adjustment to a 30% by mass 1-methoxy-2-propanol solution by concentration under reduced pressure, and then heating to 160° C. to be adjusted to a 40% by mass 1-methoxy-2-propanol solution while reducing the pressure. 53.8 parts of glycidyl methacrylate, 10 parts of dimethyldodecylamine, and 0.5 parts of TEMPO were added to this solution which was then heated at 90° C. for 36 hours. Thereafter, the temperature was returned to room temperature, 30 parts of trifluoroacetic acid were added thereto, followed by stirring for 1 hour, and the reaction solution was added dropwise to a large amount of methanol:water=1:1 mixed solution to obtain 179 parts of polymer compound 2-2.

The specific absorbance represented by Expression Aλ of polymer compound 2-2 was 2.

In polymer compound 2-2, the polymer chain corresponding to P²¹ in Formula II, which is a structure derived from the resin contained in resin solution P-1, had a weight-average molecular weight of 4800, an acid value of 211, and a polymerizable group value of 0.

In addition, the polymer chain corresponding to P²² in Formula II, which is a structure derived from the resin contained in resin solution P-2, had a weight-average molecular weight of 4400, an acid value of 2, and a polymerizable group value of 2.31.

(Synthesis of Comparative Compound 1)

17.46 g of methacrylic acid as a monomer containing an acid group, 32.54 g of benzyl methacrylate as a monomer capable of reacting with the monomer containing an acid group, and 116.7 g of propylene glycol monomethyl ether acetate (PGMEA) were added to a flask which was then purged with nitrogen. After confirming that the internal temperature of the reaction system became 75° C., 3.00 g of pentaerythritol tetramercaptan propionate (PEMP) as a chain transfer agent and 0.7 parts of V-601 as a polymerization initiator were added thereto, followed by reaction at 75° C. for 6 hours and then at 90° C. for 2 hours. After returning the temperature to room temperature and purging with air, 0.02 g of 4-methoxyhydroquinone (MEHQ) as a thermal polymerization inhibitor, 0.5 g of dimethyldodecylamine, and 29 g of glycidyl methacrylate were added thereto, and the reaction temperature was raised to 90° C. The reaction was carried out for 36 hours to synthesize Comparative Compound 1 (structure shown below). The weight-average molecular weight in terms of polystyrene measured by GPC of the alkali-soluble resin was 12800.

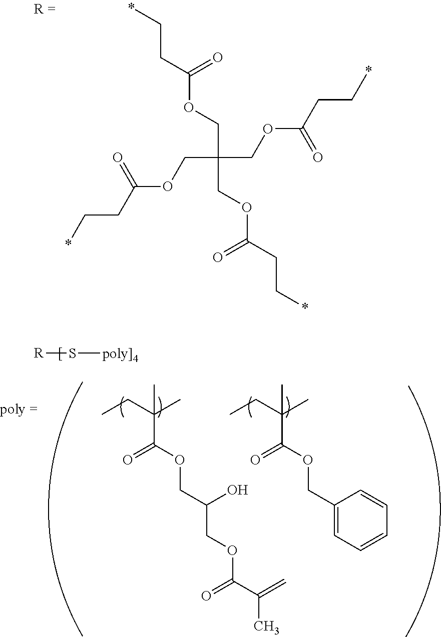

(Synthesis of Comparative Compound 2)

<Synthesis of Compound (S-27) Having Mercapto Group>

5 parts of dipentaerythritol and 80 parts of dimethylacetamide were added to a three-neck flask and stirred in a water bath at 20° C. under a nitrogen atmosphere. 31 parts of 6-bromohexanoyl chloride were added dropwise such that the temperature did not exceed 30° C., followed by stirring at room temperature for 2 hours. The reaction solution was added little by little to 350 parts of 1 mol/L aqueous hydrochloric acid to stop the reaction, and then 500 parts of ethyl acetate were added to carry out a liquid separation operation. Subsequently, the organic layer was washed with 250 parts of saturated sodium bicarbonate water, 250 parts of water, and 150 parts of saturated saline. Sodium sulfate was added to the obtained organic layer, followed by filtration, and the filtrate was concentrated under reduced pressure to obtain 24 parts of Intermediate 21.

Subsequently, 20 parts of Intermediate 21, 8.9 parts of thiourea, 200 parts of ethanol, and 17.6 parts of potassium iodide were added to a three-neck flask, and reacted for 18 hours under heating and reflux in a nitrogen atmosphere. Thereafter, 81 parts of a 20% aqueous potassium carbonate solution were added thereto, followed by reaction at 70° C. for 3 hours and then cooling. Subsequently, 150 parts of 1 mol/L aqueous hydrochloric acid and 300 parts of chloroform were added to carry out a liquid separation operation. After washing with 150 parts of saturated saline twice, sodium sulfate was added to the organic layer, followed by filtration, and the filtrate was concentrated under reduced pressure to obtain 14.7 parts of a compound (S-27) having a mercapto group.

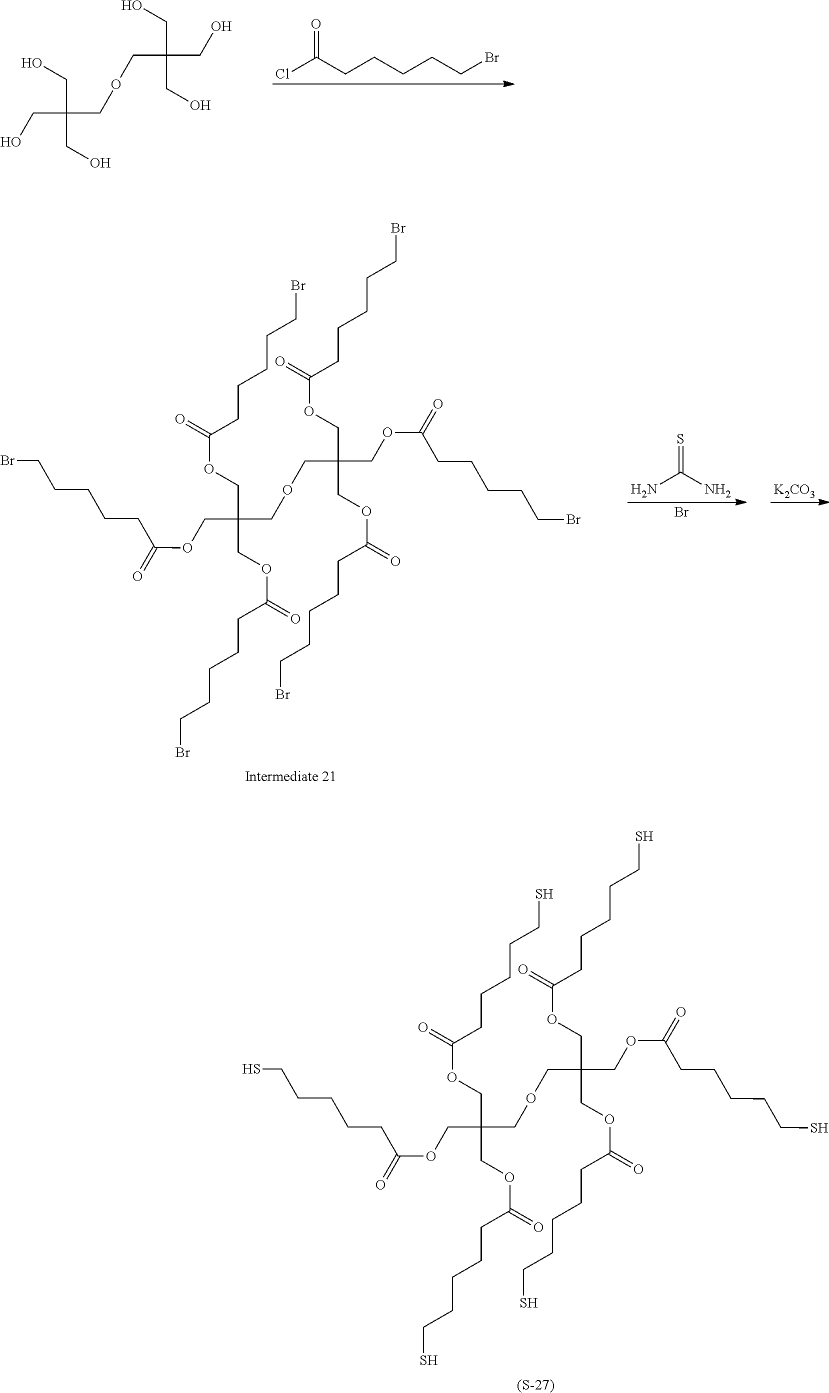

<Synthesis of Chain Transfer Agent B-43>

2.0 parts of the compound (S-27) having a mercapto group, 4.5 parts of a quinophthalone compound (A-qp-1, structure shown below), 0.78 parts of diazatriethylamine were dissolved in 39.8 parts of dimethylformamide (DMF), followed by stirring at 25° C. for 2 hours. After the reaction, the reaction solution was added dropwise to 250 parts of a mixed solvent of 1 mol/1 aqueous hydrochloric acid, followed by reprecipitation and filtration. The resulting solid was suspended in 250 parts of acetonitrile, washed, and filtered again to obtain 9.0 parts of a mercaptan compound (chain transfer agent B-43) shown below. It was confirmed that the ratio (molar ratio) of n number of coloring agent sites to the core site R³ in NMR measurement was 4.

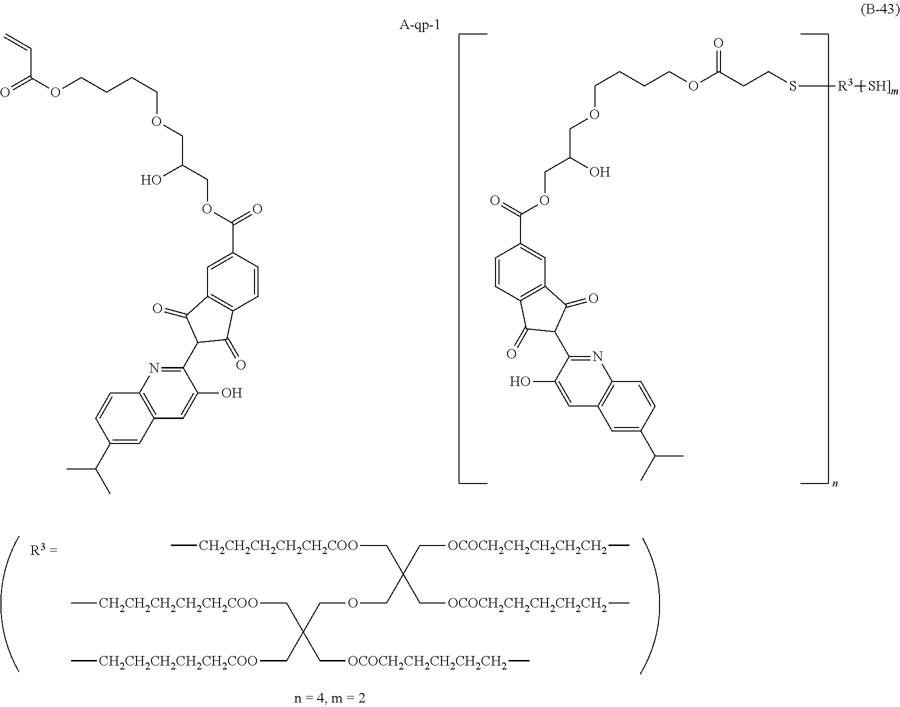

<Synthesis of Comparative Compound 2>

A mixed solution of 5.0 parts of chain transfer agent B-43, 1.55 parts of methacrylic acid (MAA), and 9.0 parts of cyclohexanone was heated to 80° C. under a nitrogen stream. 0.077 parts of V-601 were added thereto, followed by heating and stirring at 80° C. for 2 hours. 0.124 parts of V-601 were further added thereto, followed by heating and stirring at 80° C. for 2 hours and further heating and stirring at 90° C. for 2 hours. After cooling to room temperature, 30.7 parts of cyclohexanone, 0.23 parts of tetrabutylammonium bromide (TBAB), and 1.28 parts of glycidyl methacrylate (GMA) were added thereto, followed by heating and stirring at 80° C. for 18 hours. After cooling to room temperature, the reaction solution was added dropwise to a mixed solvent of 250 parts of hexane and 250 parts of ethyl acetate, followed by reprecipitation to obtain Comparative Compound 2 shown below.

Comparative Compound 2 had a weight-average molecular weight (in terms of polystyrene) of 8300 and an acid value of 64 mgKOH/g by titration with a 0.1 mol/1 aqueous sodium hydroxide solution.

In addition, from NMR, the molar ratio of the adduct of coloring agent structure/MAA/MAA and GMA was calculated to be 4/6/6, and the number of repetitions of the P part was calculated to be 6 on average. In addition, a solution containing 0.01 mg/ml of the coloring agent (C-1) was prepared by dissolving in tetrahydrofuran (THF) (concentration adjusted such that the maximum absorbance was 1.0). In a case where the absorbance at 25° C. of the solution was measured using a cell having an optical path length of 1 cm, the maximum absorption wavelength (λmax) was 615 nm, and the specific absorbance at the maximum absorption wavelength (λmax) was 60.

<Synthesis of Comparative Compound 3>

A mixed solution of 22.5 parts of ARONIX M-5300 (monomer, manufactured by Toagosei Co., Ltd.) and 37.5 parts of PSE1300 was adjusted to a 30% by mass 1-methoxy-2-propanol solution in a flask, followed by heating to 75° C. under a nitrogen stream. 0.96 parts of dodecyl mercaptan and 0.24 parts of V-601 were added thereto, followed by heating for 3 hours, and then 0.24 parts of V-601 were further added, followed by reaction at 90° C. for 3 hours in a nitrogen stream. This was followed by cooling to room temperature and purging with air, and 2.5 parts of 4-HBAGE, 1.8 parts of dimethyldodecylamine, and 0.05 parts of TEMPO were added, followed by heating and stirring at 90° C. for 36 hours. Thereafter, the reaction solution was adjusted with 1-methoxy-2-propanol (MFG) to a 30% by mass 1-methoxy-2-propanol solution, thereby obtaining Comparative Compound 3 (weight-average molecular weight in terms of polystyrene: 19600, acid value: 57 mgKOH/g).

(Preparation of Colorant Dispersion Liquid)

<Preparation of Colorant Dispersion Liquid Bk-1>

[Production of Colorant (Particle)]

—Production of Titanium Black A-1—

100 g of titanium oxide MT-150A (trade name: manufactured by Teika Co., Ltd.) having an average particle diameter of 15 nm, 25 g of silica particles AEROSIL300 (registered trademark) 300/30 (manufactured by Evonik Industries AG) having a BET (Brunauer, Emmett, Teller) specific surface area of 300 m²/g), and 100 g of Disperbyk190 (trade name: manufactured by BYK-Chemie GmbH) were weighed and added to 71 g of ion exchange water to obtain a mixture.

Thereafter, the mixture was treated for 30 minutes at a revolution speed of 1360 rpm and a rotation speed of 1047 rpm using a MURASTAR KK-400W (manufactured by Kurabo Industries Ltd.) to obtain a uniform aqueous mixture solution. This aqueous mixture solution was filled in a quartz container and heated to 920° C. in an oxygen atmosphere using a small rotary kiln (manufactured by Motoyama Inc.).

After the completion of the heating, the atmosphere in the small rotary kiln was purged with nitrogen, and a nitriding reduction treatment was carried out by flowing ammonia gas at 100 mL/min for 5 hours at the same temperature. After the completion of the treatment, the recovered powder was pulverized in a mortar to obtain a powdery titanium black containing Si atoms and having a specific surface area of 73 m²/g[a dispersed matter containing titanium black particles and Si atoms] (hereinafter, referred to as “titanium black A-1”).

—Production of Titanium Nitride-Containing Particles (TiN-1)—

First, Ti particles (TC-200, manufactured by Toho Technical Service Co., Ltd.) were formed into Ti nanoparticles by a plasma treatment in an Ar gas. The Ti nanoparticles after the plasma treatment were allowed to stand for 24 hours under an Ar gas atmosphere at an O₂ concentration of 50 ppm or less and 30° C., and then in a state where O₂ gas was introduced into the Ar atmosphere such that the O₂ concentration was 100 ppm, the Ti nanoparticles were allowed to stand at 30° C. for 24 hours (pretreatment of Ti particles).

Thereafter, the obtained Ti nanoparticles were classified using a TTSP separator (manufactured by Hosokawa Micron Corporation) under the condition of a yield of 10% to obtain a powder of Ti particles. The primary particle diameter of the obtained powder was 120 nm in a case where the average particle diameter of 100 particles was determined by arithmetic average by transmission electron microscope (TEM) observation.

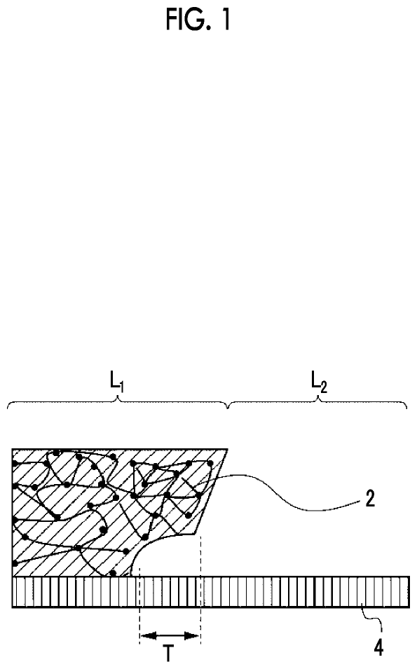

The titanium nitride-containing particles TiN-1 were produced using an apparatus according to the black composite fine particle production apparatus described in FIG. 1 of WO2010/147098A.

Specifically, in the black composite fine particle production apparatus, a high frequency voltage of about 4 MHz and about 80 kVA was applied to a high frequency oscillation coil of a plasma torch, and a mixed gas of 50 L/min of an argon gas and 50 L/min of a nitrogen gas was supplied as a plasma gas from a plasma gas supply source to generate an argon-nitrogen thermal plasma flame in the plasma torch. In addition, 10 L/min of a carrier gas was supplied from a spray gas supply source of a material supply apparatus.

Then, Fe powder (JIP270M, manufactured by JFE Steel Corporation) and Si powder (Silicon powder SI006031) were mixed with the Ti particles obtained as described above such that the respective mass ratios were Ti/Fe/Si=residue/0.05/0.05, which was then supplied to the thermal plasma flame in the plasma torch together with an argon gas as the carrier gas, evaporated in the thermal plasma flame, and therefore highly dispersed in a gas phase state.

In addition, nitrogen was used as a gas supplied into a chamber by a gas supply apparatus. The flow rate of nitrogen in the chamber at this time was 5 m/s, and the supply amount of nitrogen was 1000 L/min. The pressure in a cyclone was 50 kPa, and the supply rate of each raw material from the chamber to the cyclone was 10 m/s (average value).

In this manner, titanium nitride-containing particles TiN-1 were obtained.

The obtained titanium nitride-containing particles TiN-1 were measured for the content of titanium (Ti) atoms, iron (Fe) atoms, and silicon (Si) atoms by inductively coupled plasma (ICP) emission spectroscopic analysis method. For the ICP emission spectroscopic analysis method, an ICP emission spectrophotometer “SPS3000” (trade name, manufactured by Seiko Instruments Inc.) was used.

In addition, the content of nitrogen atoms was measured using an “oxygen/nitrogen analyzer EMGA-620W/C” (trade name, manufactured by Horiba, Ltd.), and calculated by an inert gas melting-thermal conductivity method. As a result, the mass ratio of each atom contained in the titanium nitride-containing particles TiN was Ti/N/Fe/Si=57/34/0.0030/0.0020.

X-ray diffraction of titanium nitride-containing particles TiN-1 was measured by a wide-angle X-ray diffraction method (trade name “RU-200R”, manufactured by Rigaku Corporation) with a powder sample placed in an aluminum standard sample holder. The measurement conditions were as follows: X-ray source: CuKα ray, output: 50 kV/200 mA, slit system: 1°-1°-0.15 mm-0.45 mm, measurement step (20): 0.02°, and scan speed: 2°/min.

Then, a diffraction angle of a peak derived from a TiN (200) plane observed near the diffraction angle 2θ (42.6°) was measured. Further, from a half-width of the peak derived from the (200) plane, the size of crystallites constituting the particle was determined using Scherrer's equation. As a result, the diffraction angle of the peak was 42.62° and the size of crystallites was 10 nm. In addition, no X-ray diffraction peak due to TiO₂ was observed.

[Preparation of Colorant Dispersion Liquid Bk-1]

The components shown in the composition below were mixed for 15 minutes using a stirrer (EUROSTAR (trade name), manufactured by IKA-Werke GmbH & Co. KG) to obtain a colorant dispersion liquid Bk-1.
Titanium black A-1 (titanium black having an average particle diameter of 30 nm or less): 25 parts
PGMEA 30% by mass solution of polymer compound 1-1: 25 parts
PGMEA: 50 parts

The obtained dispersion was subjected to a dispersion treatment under the following conditions using an Ultra Apex Mill UAM015 (trade name, manufactured by Kotobuki Industries Co., Ltd.).

—Dispersion Conditions—
Bead diameter: 0.05 mm (zirconia beads, YTZ, manufactured by Nikkato Corporation)
Bead filling rate: 65% by volume
Mill peripheral speed: 10 m/s
Separator peripheral speed: 13 m/s
Amount of mixed liquid to be dispersed: 15 kg
Circulating flow rate (pump supply amount): 90 kg/h
Treatment liquid temperature: 19° C. to 21° C.
Cooling water: water
Treatment time: about 22 hours

<Preparation of Colorant Dispersion Liquids Bk-2 to Bk-12 and Comparative Bk-1 to Bk-3>

Colorant dispersion liquids Bk-2 to Bk-12 and Comparative Bk-1 to Bk-3 were prepared in the same manner as the preparation of the colorant dispersion liquid Bk-1, except that the colorant and the polymer compound in the preparation of the colorant dispersion liquid Bk-1 were changed as shown in Table 2.

TABLE 2

| | Colorant | | Polymer compound | | Organic solvent | |
|---|---|---|---|---|---|---|
| Colorant | | Parts | | Parts | | Parts |
| dispersion | | by | | by | | by |
| liquid | Type | mass | Type | mass | Type | mass |
| Bk-1 | Titanium | 25 | Polymer compound 1-1 | 25 | PGMEA | 50 |
| | black A-1 | | PGMEA 30% solution | | | |
| Bk-2 | Titanium | 25 | Polymer compound 1-2 | 25 | PGMEA | 50 |
| | black A-1 | | PGMEA 30% solution | | | |
| Bk-3 | Titanium | 25 | Polymer compound 1-3 | 25 | PGMEA | 50 |
| | black A-1 | | PGMEA 30% solution | | | |
| Bk-4 | Titanium | 25 | Polymer compound 1-4 | 25 | PGMEA | 50 |
| | black A-1 | | PGMEA 30% solution | | | |
| Bk-5 | Titanium | 25 | Polymer compound 1-5 | 25 | PGMEA | 50 |
| | black A-1 | | PGMEA 30% solution | | | |
| Bk-6 | TiN-1 | 25 | Polymer compound 1-6 | 25 | PGMEA | 50 |
| | | | PGMEA 30% solution | | | |
| Bk-7 | TiN-1 | 25 | Polymer compound 1-7 | 25 | PGMEA | 50 |
| | | | PGMEA 30% solution | | | |
| Bk-8 | TiN-1 | 25 | Polymer compound 1-8 | 25 | PGMEA | 50 |
| | | | PGMEA 30% solution | | | |
| Bk-9 | TiN-1 | 25 | Polymer compound 1-9 | 25 | PGMEA | 50 |
| | | | PGMEA 30% solution | | | |
| Bk-10 | TiN-1 | 25 | Polymer compound 1-10 | 25 | PGMEA | 50 |
| | | | PGMEA 30% solution | | | |
| Bk-11 | TiN-1 | 25 | Polymer compound 2-1 | 25 | PGMEA | 50 |
| | | | PGMEA 31% solution | | | |
| Bk-12 | TiN-1 | 25 | Polymer compound 2-2 | 25 | PGMEA | 50 |
| | | | PGMEA 32% solution | | | |
| Comparative | Titanium | 25 | Comparative Compound 1 | 25 | PGMEA | 50 |
| Bk-1 | black A-1 | | PGMEA 30% solution | | | |
| Comparative | Titanium | 25 | Comparative Compound 2 | 25 | PGMEA | 50 |
| Bk-2 | black A-1 | | PGMEA 30% solution | | | |
| Comparative | Titanium | 25 | Comparative Compound 3 | 25 | PGMEA | 50 |
| Bk-3 | black A-1 | | MFG 30% solution | | | |

(Preparation of Curable Composition)

In Examples 1 to 12 and Comparative Examples 1 to 3, the colorant dispersion liquids, alkali-soluble resins, polymerizable compounds, photopolymerization initiators, surfactants, and organic solvents shown in Table 3 were mixed in parts by mass shown in Table 3 to obtain curable compositions in the respective examples.

TABLE 3

| | | | | | | | | | | | | Evaluation results | | | | |
|---|---|---|---|---|---|---|---|---|---|---|---|---|---|---|---|---|
| | Colorant | | Alkali- | | Poly- | | Photopoly- | | | | Organic | Undercut | | | | |
| | dispersion | | soluble | | merizable | | merization | | | | solvent | width | | | De- | |
| | liquid | | resin | | compound | | initiator | | Surfactant | | (solid | Under- | | | velop- | Stor- |
| | | Parts | | Parts | | Parts | | Parts | | Parts | content | cut | | Bor- | ment | age |
| | | by | | by | | by | | by | | by | 28%) | width | Eval- | der | res- | sta- |
| | Type | mass | Type | mass | Type | mass | Type | mass | Type | mass | Type | (μm) | uation | width | idue | bility |
| Example 1 | Bk-1 | 144 | Alkali- | 4 | M-1 | 15 | Oxime-based | 6 | Sur- | 0.12 | PGMEA | 0.2 | AA | AA | 5 | 4 |
| | | | soluble | | | | polymerization | | factant | | | | | | | |
| | | | resin 1 | | | | initiator 1 | | 1 | | | | | | | |
| Example 2 | Bk-2 | 144 | Alkali- | 4 | M-1 | 15 | Oxime-based | 6 | Sur- | 0.12 | PGMEA | 0.3 | A | A | 4 | 4 |
| | | | soluble | | | | polymerization | | factant | | | | | | | |
| | | | resin 2 | | | | initiator 2 | | 1 | | | | | | | |
| Example 3 | Bk-3 | 144 | Alkali- | 4 | M-1 | 15 | Oxime-based | 6 | Sur- | 0.12 | PGMEA | 0.3 | A | A | 4 | 4 |
| | | | soluble | | | | polymerization | | factant | | | | | | | |
| | | | resin 3 | | | | initiator 3 | | 1 | | | | | | | |
| Example 4 | Bk-4 | 144 | Alkali- | 4 | M-1 | 15 | Oxime-based | 6 | Sur- | 0.12 | PGMEA | 0.4 | A | A | 4 | 4 |
| | | | soluble | | | | polymerization | | factant | | | | | | | |
| | | | resin 1 | | | | initiator 4 | | 1 | | | | | | | |
| Example 5 | Bk-5 | 144 | Alkali- | 4 | M-2 | 15 | Oxime-based | 6 | Sur- | 0.12 | PGMEA | 0.3 | A | A | 4 | 4 |
| | | | soluble | | | | polymerization | | factant | | | | | | | |
| | | | resin 1 | | | | initiator 1 | | 1 | | | | | | | |
| Example 6 | Bk-6 | 144 | Alkali- | 4 | M-1/ | 10/5 | Oxime-based | 6 | Sur- | 0.12 | PGMEA | 0.2 | AA | AA | 4 | 5 |
| | | | soluble | | M-3 | | polymerization | | factant | | | | | | | |
| | | | resin 1 | | | | initiator 1 | | 1 | | | | | | | |
| Example 7 | Bk-7 | 144 | Alkali- | 4 | M-1 | 15 | Oxime-based | 6 | Sur- | 0.12 | PGMEA | 0.2 | AA | AA | 4 | 5 |
| | | | soluble | | | | polymerization | | factant | | | | | | | |
| | | | resin 1 | | | | initiator 1 | | 1 | | | | | | | |
| Example 8 | Bk-8 | 144 | Alkali- | 2/2 | M-1 | 15 | Oxime-based | 6 | Sur- | 0.12 | PGMEA | 0.2 | AA | AA | 4 | 5 |
| | | | soluble | | | | polymerization | | factant | | | | | | | |
| | | | resin 1/ | | | | initiator 1 | | 1 | | | | | | | |
| | | | Alkali- | | | | | | | | | | | | | |
| | | | soluble | | | | | | | | | | | | | |
| | | | resin 2 | | | | | | | | | | | | | |
| Example 9 | Bk-9 | 144 | Alkali- | 4 | M-1 | 15 | Oxime-based | 6 | Sur- | 0.12 | PGMEA | 0.1 | AA | AA | 5 | 5 |
| | | | soluble | | | | polymerization | | factant | | | | | | | |
| | | | resin 1 | | | | initiator 1 | | 1 | | | | | | | |
| Example 10 | Bk-10 | 144 | Alkali- | 4 | M-1 | 15 | Oxime-based | 6 | Sur- | 0.12 | PGMEA | 0.1 | AA | AA | 4 | 4 |
| | | | soluble | | | | polymerization | | factant | | | | | | | |
| | | | resin 1 | | | | initiator 1 | | 1 | | | | | | | |
| Example 11 | Bk-11 | 144 | Alkali- | 4 | M-1 | 15 | Oxime-based | 6 | Sur- | 0.12 | PGMEA | 0.1 | AA | AA | 5 | 4 |
| | | | soluble | | | | polymerization | | factant | | | | | | | |
| | | | resin 1 | | | | initiator 1 | | 1 | | | | | | | |
| Example 12 | Bk-12 | 144 | Alkali- | 4 | M-1 | 15 | Oxime-based | 6 | Sur- | 0.12 | PGMEA | 0.1 | AA | AA | 5 | 4 |
| | | | soluble | | | | polymerization | | factant | | | | | | | |
| | | | resin 1 | | | | initiator 1 | | 1 | | | | | | | |
| Compar- | Compar- | 144 | Alkali- | 4 | M-1 | 15 | Oxime-based | 6 | Sur- | 0.12 | PGMEA | 0.8 | B | B | 1 | 1 |
| ative | ative | | soluble | | | | polymerization | | factant | | | | | | | |
| Example 1 | Bk-1 | | resin 1 | | | | initiator 1 | | 1 | | | | | | | |
| Compar- | Compar- | 144 | Alkali- | 4 | M-1 | 15 | Oxime-based | 6 | Sur- | 0.12 | PGMEA | 1.5 | C | C | 3 | 3 |
| ative | ative | | soluble | | | | polymerization | | factant | | | | | | | |
| Example 2 | Bk-2 | | resin 1 | | | | initiator 1 | | 1 | | | | | | | |
| Compar- | Compar- | 144 | Alkali- | 4 | M-1 | 15 | Oxime-based | 6 | Sur- | 0.12 | PGMEA | 1.7 | C | C | 2 | 1 |
| ative | ative | | soluble | | | | polymerization | | factant | | | | | | | |
| Example 3 | Bk-3 | | resin 1 | | | | initiator 1 | | 1 | | | | | | | |

Details of the compounds shown in Table 3 are as follows.

<Alkali-Soluble Resin>
Alkali-soluble resin 1: benzyl methacrylate/acrylic acid copolymer [composition ratio: benzyl methacrylate/acrylic acid copolymer=80/20 (% by mass), Mw: 25000]
Alkali-developable resin 2: Cyclomer P (ACA) 230AA (manufactured by Daicel Corporation)
Alkali-developable resin 3: ACRYCURE RD-F8 (acrylic-based resin) (manufactured by Nippon Shokubai Co., Ltd.)

<Polymerizable Compound>
M-1: a mixture of dipentaerythritol hexaacrylate and dipentaerythritol pentaacrylate (mass ratio 7:3)
M-2: EO-modified pentaerythritol tetraacrylate (KAYARAD RP-1040, manufactured by Nippon Kayaku Co., Ltd.)
M-3: OGSOL EA-0300 (manufactured by Osaka Gas Chemicals Co., Ltd.)

<Photopolymerization Initiator>
Oxime-based polymerization initiator 1: IRGACURE OXE-02 (manufactured by BASF SE)
Oxime-based polymerization initiator 2: ADEKA ARKLS NCI-831 (which contains a nitro group, manufactured by ADEKA Corporation)
Oxime-based polymerization initiator 3: a compound having structure shown below

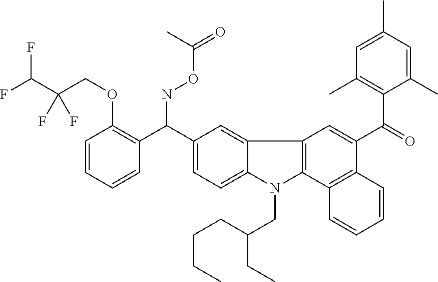 [SMILES: CCCCC(CC)Cn1c2ccc(C(NOC(C)=O)c3ccccc3OCC(F)(F)C(F)F)cc2c2cc(C(=O)c3c(C)cc(C)cc3C)c3ccccc3c21]

Oxime-based polymerization initiator 4: a compound having structure shown below

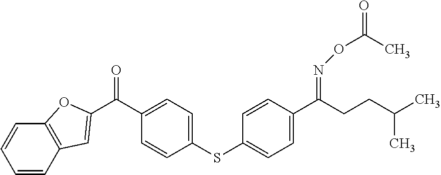 [SMILES: CC(=O)O/N=C(\CCC(C)C)c1ccc(Sc2ccc(C(=O)c3cc4ccccc4o3)cc2)cc1]

<Surfactant>
Surfactant 1: a aurfactant represented by the following formula (weight-average molecular weight (Mw)=15311)

In the following formula, the constitutional units represented by (A) and (B) in the formula are 62 mol % and 38 mol %, respectively. In the constitutional unit represented by Formula (B), a, b, and c are the number of repetitions, respectively, and satisfy the relationship of a+c=14 and b=17.

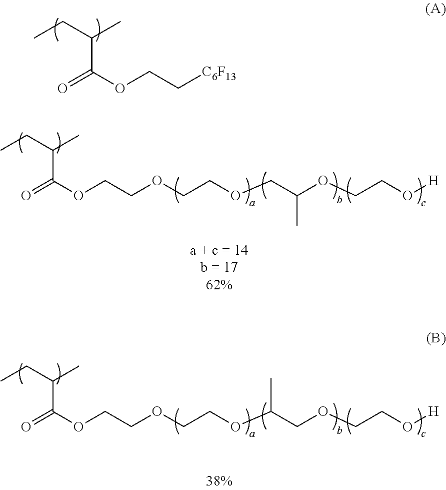

(Evaluation)

<Evaluation of Storage Stability>

[1. Exposure Sensitivity of Curable Composition (Initial)]

In each Example or Comparative Example, each curable composition immediately after the preparation thereof was applied onto a glass substrate by spin coating and dried to form a curable composition film having a film thickness of 1.0 μm. The spin coating conditions were as follows: first, the rotation speed: 300 rpm (rotation per minute) for 5 seconds, and then 800 rpm for 20 seconds. The drying conditions were 100° C. and 80 seconds.

Using an i-line stepper exposure apparatus FPA-3000i5+(manufactured by Canon Inc.), the coating film obtained as described above was irradiated with light having a wavelength of 365 nm at an exposure amount of 10 to 1600 mJ/cm² through a pattern mask having 1 μm lines and spaces. Next, using a 60% CD-2000 (manufactured by FujiFilm Electronics Materials Co., Ltd.) developer, the curable composition film after the exposure was developed under the conditions of 25° C. and 60 seconds to obtain a patterned cured film. Thereafter, the patterned cured film was rinsed with running water for 20 seconds and then air-dried.

In the above exposing step, the minimum exposure amount at which a pattern line width after the development of the region irradiated with light was 1.0 μm or more was defined as exposure sensitivity, and this exposure sensitivity was taken as initial exposure sensitivity.

[2. Exposure Sensitivity of Curable Composition (after Time: After 30 Days at 45° C.)]

The curable composition immediately after the preparation thereof was sealed in an airtight container, held in a thermostat (EYELA/LTI-700) whose internal temperature was set to 45° C., and taken out after 30 days. Using the taken out curable composition, the same test as that carried out using the curable composition immediately after the preparation thereof was carried out to obtain the exposure sensitivity. This exposure sensitivity was taken as exposure sensitivity after time.

[Evaluation]

The variation (%) of the exposure sensitivity obtained by the following expression was calculated from the initial exposure sensitivity and the exposure sensitivity after time. A smaller value of the variation (%) indicates excellent storage stability of a curable composition.

Variation=[(exposure sensitivity after time−initial exposure sensitivity)/initial exposure sensitivity]×100 (Expression)

In practice, an evaluation of “3” or higher is preferable, and “4” and “5” are evaluated as having excellent performance. The results are shown in Table 3.

—Evaluation Standards—

“5”: The variation was 0% to 3%.

“4”: The variation was more than 3% and 6% or less.

“3”: The variation was more than 6% and 10% or less.

“2”: The variation was more than 10% and 15% or less.

“1”: The variation was more than 15%.

<Evaluation of Development Residue (Unexposed Portion Residue)>

In the test of the [1. Exposure sensitivity of curable composition (initial)], the cured film obtained with the minimum exposure amount at which the pattern line width after the development becomes 1.0 μm or more was heated together with a glass substrate in an oven at 220° C. for 1 hour. After heating the cured film, the number of residues present on the glass substrate in the region not irradiated with light in the exposing step (unexposed portion) was observed with a scanning electron microscope (SEM, magnification: 20000×) to evaluate the unexposed portion residues. The evaluation was carried out according to the following standards. The results are shown in Table 3. In practice, an evaluation of “3” or higher is preferable, and “4” and “5” are evaluated as having excellent performance. —Evaluation standards—

“5”: A pattern was formed, and no residue was observed in an unexposed portion.

“4”: A pattern was formed, and 1 to 3 residues were observed in an unexposed portion of 1.0 μm square.

“3”: A pattern was formed, and 4 to 10 residues were observed in an unexposed portion of 1.0 μm square.

“2”: A pattern was formed, and 11 or more residues were observed in an unexposed portion of 1.0 μm square.

“1”: A pattern was not formed due to poor development.

<Evaluation of Edge Shape of Cured Product (Undercut/Border Width)>

The edge shape of the patterned cured product formed using each curable composition was evaluated by the following method.

[Curable Composition Film Forming Step]

A curable composition film (composition film) was formed on a silicon wafer such that the film thickness after drying was 1.5 The curable composition film was formed using spin coating. The rotation speed of the spin coating was adjusted so as to achieve the above film thickness. The curable composition film after application was placed on a hot plate with the silicon wafer facing down and then dried. The surface temperature of the hot plate was 100° C., and the drying time was 120 seconds.

[Exposing Step]

The obtained curable composition film was exposed under the following conditions.

The exposure was carried out using an i-line stepper exposure apparatus (trade name “FPA-3000iS+”, manufactured by Canon Inc.). The curable composition film was irradiated (exposed) with an exposure amount of 400 mJ/cm² (irradiation time of 0.5 seconds) through a mask having a linear shape of 20 μm (width: 20 μm, length: 4 mm).

[Developing Step]

The curable composition film after curing was developed under the following conditions to obtain a patterned cured film.

Using a 0.3% by mass aqueous solution of tetramethylammonium hydroxide (TMAH), puddle development for 60 seconds at 23° C. was repeated 5 times on the curable composition film after curing to obtain a patterned cured product. Thereafter, the patterned cured product was rinsed using a spin shower and further washed with pure water.

[Post-Baking Step]

The patterned cured product obtained above was heated at 220° C. for 300 seconds using a clean oven CLH-21CDH (manufactured by Koyo Thermo Systems Co., Ltd.).

Further, the patterned cured product after heating was placed on a hot plate having a surface temperature of 220° C. and heated for 300 seconds.

[Evaluation]

The patterned cured product was imaged with a scanning electron microscope, and the edge shape of a 20 μm pattern cross section was evaluated according to the following standards.

1. Measurement and Evaluation of Undercut Width (μm)

As shown in FIG. 1, a notch length T of a bottom portion of a pattern edge portion 2 of the patterned cured product formed on a wafer 4 was measured. In FIG. 1, L₁ corresponds to an exposed region, and L₂ corresponds to an unexposed region. The evaluation was carried out according to the following standards. The results are shown in Table 3.

—Evaluation Standards—

“AA”: The undercut width was 0 μm or more and 0.25 μm or less.

“A”: The undercut width was more than 0.25 μm and 0.5 μm or less.

“B”: The undercut width was more than 0.5 μm and 1.0 μm or less.

“C”: The undercut width was more than 1.0 μm.

2. Measurement and Evaluation of Pattern Border Width (μm)

As shown in FIG. 1, a length P of the eaves at the upper part of the pattern edge portion 2 of the patterned cured product formed on the wafer 4 was measured as a pattern border width (also simply referred to as “border width”). In FIG. 1, L₁ corresponds to an exposed region, and L₂ corresponds to an unexposed region. The evaluation was carried out according to the following standards. The results are shown in Table 3.

—Evaluation Standards—

“AA”: The border width was 0 μm or more and 0.25 μm or less.

“A”: The border width was more than 0.25 μm and 0.5 μm or less.

“B”: The border width was more than 0.5 μm and 1.0 μm or less.

“C”: The border width was more than 1.0 μm.

In a case where the measurement result of the undercut width is the evaluation standard “A” or “AA” and the measurement result of the border width is the evaluation standard “A” or “AA”, it can be said that the curable composition is excellent in the edge shape in a pattern of a cured product to be obtained.

### Examples 13 to 24 and Comparative Examples 4 to 6

<Preparation of Colorant Dispersion Liquids G-1 to G-12 and Comparative G-1 to

G-3>

[Synthesis of Halogenated Zinc Phthalocyanine Pigment]

Zinc phthalocyanine was produced using phthalonitrile, ammonia, and zinc chloride as raw materials. This 1-chloronaphthalene solution had light absorption at 750 to 850 nm.

The halogenation of zinc phthalocyanine was as follows.

First, sulfuryl chloride (45.5 parts by mass), anhydrous aluminum chloride (54.5 parts by mass), and sodium chloride (7 parts by mass) were mixed at 40° C., and a zinc phthalocyanine pigment (15 parts by mass) was added thereto. Bromine (35 parts by mass) was added dropwise thereto, and the temperature was raised to 130° C. over 19.5 hours and held for 1 hour. Thereafter, the reaction mixture was taken out into water, and a halogenated zinc phthalocyanine crude pigment was precipitated. This aqueous slurry was filtered, washed with hot water at 60° C., washed with a 1% aqueous sodium hydrogen sulfate solution, washed with hot water at 60° C., and dried at 90° C. to obtain 2.7 parts by mass of purified halogenated zinc phthalocyanine crude pigment A.

The purified halogenated zinc phthalocyanine crude pigment A (1 part by mass), pulverized sodium chloride (10 parts by mass), and diethylene glycol (1 part by mass) were charged into a double-arm kneader and kneaded at 100° C. for 8 hours. After kneading, the mixture was taken out into water (100 parts by mass) at 80° C., stirred for 1 hour, filtered, washed with hot water, dried, and pulverized to obtain a halogenated zinc phthalocyanine pigment.

The obtained halogenated zinc phthalocyanine pigment had an average composition of ZnPcBr₉₈Cl_{3.1}H₃₁ based on halogen content analysis by mass spectrometry and flask combustion-ion chromatography. Pc is an abbreviation for phthalocyanine.

[Preparation of Colorant Dispersion Liquids G-1 to G-12 and Comparative G-1 to G-3]

The halogenated zinc phthalocyanine pigment (Pigment 1), Pigment Yellow 150 (Pigment 2), a pigment derivative A, a polymer compound, and propylene glycol monomethyl ether acetate (PGMEA) as a solvent were mixed by a bead mill for 15 hours so as to have the composition shown in Table 4, and therefore green colorant dispersion liquids G-1 to G-12 and Comparative G-1 to G-3 were prepared.

TABLE 4

| | | | Pigment | | | | Organic | |
|---|---|---|---|---|---|---|---|---|
| | Colorant | | derivative | | Resin | | solvent | |
| Colorant | | Parts | | Parts | | Parts | | Parts |
| dispersion | | by | | by | | by | | by |
| liquid | Type | mass | Type | mass | Type | mass | Type | mass |
| G-1 | Pigment 1 | 50 | Pigment | 5 | Polymer compound 1-1 | 20 | PGMEA | 360 |
| | Pigment 2 | 15 | derivative A | | PGMEA 30% solution | | | |
| G-2 | Pigment 1 | 50 | Pigment | 5 | Polymer compound 1-2 | 20 | PGMEA | 360 |
| | Pigment 2 | 15 | derivative A | | PGMEA 30% solution | | | |
| G-3 | Pigment 1 | 50 | Pigment | 5 | Polymer compound 1-3 | 20 | PGMEA | 360 |
| | Pigment 2 | 15 | derivative A | | PGMEA 30% solution | | | |
| G-4 | Pigment 1 | 50 | Pigment | 5 | Polymer compound 1-4 | 20 | PGMEA | 360 |
| | Pigment 2 | 15 | derivative A | | PGMEA 30% solution | | | |
| G-5 | Pigment 1 | 50 | Pigment | 5 | Polymer compound 1-5 | 20 | PGMEA | 360 |
| | Pigment 2 | 15 | derivative A | | PGMEA 30% solution | | | |
| G-6 | Pigment 1 | 50 | Pigment | 5 | Polymer compound 1-6 | 20 | PGMEA | 360 |
| | Pigment 2 | 15 | derivative A | | PGMEA 30% solution | | | |
| G-7 | Pigment 1 | 50 | Pigment | 5 | Polymer compound 1-7 | 20 | PGMEA | 360 |
| | Pigment 2 | 15 | derivative A | | PGMEA 30% solution | | | |
| G-8 | Pigment 1 | 50 | Pigment | 5 | Polymer compound 1-8 | 20 | PGMEA | 360 |
| | Pigment 2 | 15 | derivative A | | PGMEA 30% solution | | | |
| G-9 | Pigment 1 | 50 | Pigment | 5 | Polymer compound 1-9 | 20 | PGMEA | 360 |
| | Pigment 2 | 15 | derivative A | | PGMEA 30% solution | | | |
| G-10 | Pigment 1 | 50 | Pigment | 5 | Polymer compound 1-10 | 20 | PGMEA | 360 |
| | Pigment 2 | 15 | derivative A | | PGMEA 30% solution | | | |
| G-11 | Pigment 1 | 50 | Pigment | 5 | Polymer compound 2-1 | 20 | PGMEA | 360 |
| | Pigment 2 | 15 | derivative A | | PGMEA 31% solution | | | |
| G-12 | Pigment 1 | 50 | Pigment | 5 | Polymer compound 2-2 | 20 | PGMEA | 360 |
| | Pigment 2 | 15 | derivative A | | PGMEA 32% solution | | | |
| Comparative | Pigment 1 | 50 | Pigment | 5 | Comparative Compound 1 | 20 | PGMEA | 360 |
| G-1 | Pigment 2 | 15 | derivative A | | PGMEA 30% solution | | | |
| Comparative | Pigment 1 | 50 | Pigment | 5 | Comparative Compound 2 | 20 | PGMEA | 360 |
| G-2 | Pigment 2 | 15 | derivative A | | PGMEA 30% solution | | | |
| Comparative | Pigment 1 | 50 | Pigment | 5 | Comparative Compound 3 | 20 | PGMEA | 360 |
| G-3 | Pigment 2 | 15 | derivative A | | MFG 30% solution | | | |

Details of the compounds used for the preparation of the colorant dispersion liquids G-1 to G-12 and Comparative G-1 to G-3 are as follows.

[Pigment Derivative]
Pigment derivative A: a compound having a structure shown below

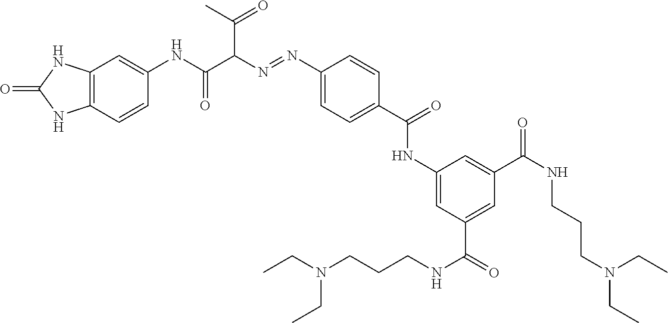 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

Individual components were mixed to prepare a curable composition in the same manner as in Example 1, except that the composition in each Example was changed into the composition shown in Table 5.

In each Example, the storage stability, development residue, and edge shape of the cured product were evaluated in the same manner as in Example 1 using the prepared curable composition. The evaluation results are shown in Table 5.

TABLE 5

| | | | | | | | | | | | Organic | | Evaluation results | | | | |
|---|---|---|---|---|---|---|---|---|---|---|---|---|---|---|---|---|---|
| | Colorant | | Alkali- | | Poly- | | Photopoly- | | | | solvent | | Undercut | | | | |
| | dispersion | | soluble | | merizable | | merization | | | | (solid | | width | | | De- | |
| | liquid | | resin | | compound | | initiator | | Surfactant | | content 28%) | | Under- | | | velop- | Stor- |
| | | Parts | | Parts | | Parts | | Parts | | Parts | | Parts | cut | | Bor- | ment | age |
| | | by | | by | | by | | by | | by | | by | width | Eval- | der | res- | sta- |
| | Type | mass | Type | mass | Type | mass | Type | mass | Type | mass | Type | mass | (μm) | uation | width | idue | bility |
| Example | G-1 | 376 | Alkali- | 4 | M-1 | 15 | Oxime- | 6 | Sur- | 0.1 | PGMEA | 300 | 0.1 | AA | AA | 5 | 4 |
| 13 | | | soluble | | | | based | | factant | | | | | | | | |
| | | | resin 1 | | | | polymer- | | 1 | | | | | | | | |
| | | | | | | | ization | | | | | | | | | | |
| | | | | | | | initiator 1 | | | | | | | | | | |
| Example | G-2 | 376 | Alkali- | 4 | M-1 | 15 | Oxime- | 6 | Sur- | 0.1 | PGMEA | 300 | 0.2 | AA | A | 4 | 4 |
| 14 | | | soluble | | | | based | | factant | | | | | | | | |
| | | | resin 2 | | | | polymer- | | 1 | | | | | | | | |
| | | | | | | | ization | | | | | | | | | | |
| | | | | | | | initiator 2 | | | | | | | | | | |
| Example | G-3 | 376 | Alkali- | 4 | M-1 | 15 | Oxime- | 6 | Sur- | 0.1 | PGMEA | 300 | 0.2 | AA | A | 4 | 4 |
| 15 | | | soluble | | | | based | | factant | | | | | | | | |
| | | | resin 3 | | | | polymer- | | 1 | | | | | | | | |
| | | | | | | | ization | | | | | | | | | | |
| | | | | | | | initiator 3 | | | | | | | | | | |
| Example | G-4 | 376 | Alkali- | 4 | M-1 | 15 | Oxime- | 6 | Sur- | 0.1 | PGMEA | 300 | 0.2 | AA | A | 4 | 4 |
| 16 | | | soluble | | | | based | | factant | | | | | | | | |
| | | | resin 1 | | | | polymer- | | 1 | | | | | | | | |
| | | | | | | | ization | | | | | | | | | | |
| | | | | | | | initiator 4 | | | | | | | | | | |
| Example | G-5 | 376 | Alkali- | 4 | M-2 | 15 | Oxime- | 6 | Sur- | 0.1 | PGMEA | 300 | 0.2 | AA | A | 4 | 4 |
| 17 | | | soluble | | | | based | | factant | | | | | | | | |
| | | | resin 1 | | | | polymer- | | 1 | | | | | | | | |
| | | | | | | | ization | | | | | | | | | | |
| | | | | | | | initiator 1 | | | | | | | | | | |
| Example | G-6 | 376 | Alkali- | 4 | M-1/ | 10/5 | Oxime- | 6 | Sur- | 0.1 | PGMEA | 300 | 0.2 | AA | AA | 4 | 5 |
| 18 | | | soluble | | M-3 | | based | | factant | | | | | | | | |
| | | | resin 1 | | | | polymer- | | 1 | | | | | | | | |
| | | | | | | | ization | | | | | | | | | | |
| | | | | | | | initiator 1 | | | | | | | | | | |
| Example | G-7 | 376 | Alkali- | 4 | M-1 | 15 | Oxime- | 6 | Sur- | 0.1 | PGMEA | 300 | 0.2 | AA | AA | 4 | 5 |
| 19 | | | soluble | | | | based | | factant | | | | | | | | |
| | | | resin 1 | | | | polymer- | | 1 | | | | | | | | |
| | | | | | | | ization | | | | | | | | | | |
| | | | | | | | initiator 1 | | | | | | | | | | |
| Example | G-8 | 376 | Alkali- | 2/2 | M-1 | 15 | Oxime- | 6 | Sur- | 0.1 | PGMEA | 300 | 0.2 | AA | AA | 4 | 5 |
| 20 | | | soluble | | | | based | | factant | | | | | | | | |
| | | | resin1/ | | | | polymer- | | 1 | | | | | | | | |
| | | | Alkali- | | | | ization | | | | | | | | | | |
| | | | soluble | | | | initiator 1 | | | | | | | | | | |
| | | | resin 2 | | | | | | | | | | | | | | |
| Example | G-9 | 376 | Alkali- | 4 | M-1 | 15 | Oxime- | 6 | Sur- | 0.1 | PGMEA | 300 | 0.1 | AA | AA | 5 | 5 |
| 21 | | | soluble | | | | based | | factant | | | | | | | | |
| | | | resin 1 | | | | polymer- | | 1 | | | | | | | | |
| | | | | | | | ization | | | | | | | | | | |
| | | | | | | | initiator 1 | | | | | | | | | | |
| Example | G-10 | 376 | Alkali- | 4 | M-1 | 15 | Oxime- | 6 | Sur- | 0.1 | PGMEA | 300 | 0.1 | AA | AA | 4 | 4 |
| 22 | | | soluble | | | | based | | factant | | | | | | | | |
| | | | resin 1 | | | | polymer- | | 1 | | | | | | | | |
| | | | | | | | ization | | | | | | | | | | |
| | | | | | | | initiator 1 | | | | | | | | | | |
| Example | G-11 | 376 | Alkali- | 4 | M-1 | 15 | Oxime- | 6 | Sur- | 0.1 | PGMEA | 300 | 0.1 | AA | AA | 5 | 4 |
| 23 | | | soluble | | | | based | | factant | | | | | | | | |
| | | | resin 1 | | | | polymer- | | 1 | | | | | | | | |
| | | | | | | | ization | | | | | | | | | | |
| | | | | | | | initiator 1 | | | | | | | | | | |
| Example | G-12 | 376 | Alkali- | 4 | M-1 | 15 | Oxime- | 6 | Sur- | 0.1 | PGMEA | 300 | 0.1 | AA | AA | 5 | 4 |
| 24 | | | soluble | | | | based | | factant | | | | | | | | |
| | | | resin 1 | | | | polymer- | | 1 | | | | | | | | |
| | | | | | | | ization | | | | | | | | | | |
| | | | | | | | initiator 1 | | | | | | | | | | |
| Compar- | Compar- | 376 | Alkali- | 4 | M-1 | 15 | Oxime- | 6 | Sur- | 0.1 | PGMEA | 300 | 0.6 | B | B | 1 | 1 |
| ative | ative | | soluble | | | | based | | factant | | | | | | | | |
| Example | G-1 | | resin 1 | | | | polymer- | | 1 | | | | | | | | |
| 4 | | | | | | | ization | | | | | | | | | | |
| | | | | | | | initiator 1 | | | | | | | | | | |
| Compar- | Compar- | 376 | Alkali- | 4 | M-1 | 15 | Oxime- | 6 | Sur- | 0.1 | PGMEA | 300 | 1.3 | C | B | 4 | 4 |
| ative | ative | | soluble | | | | based | | factant | | | | | | | | |
| Example | G-2 | | resin 1 | | | | polymer- | | 1 | | | | | | | | |
| 5 | | | | | | | ization | | | | | | | | | | |
| | | | | | | | initiator 1 | | | | | | | | | | |
| Compar- | Compar- | 376 | Alkali- | 4 | M-1 | 15 | Oxime- | 6 | Sur- | 0.1 | PGMEA | 300 | 1.1 | C | C | 1 | 1 |
| ative | ative | | soluble | | | | based | | factant | | | | | | | | |
| Example | G-3 | | resin 1 | | | | polymer- | | 1 | | | | | | | | |
| 6 | | | | | | | ization | | | | | | | | | | |
| | | | | | | | initiator 1 | | | | | | | | | | |

The evaluation was carried out in the same manner as in Examples 13 to 24, except that the colorant dispersion liquids G-1 to G-12 in Examples 13 to 24 were changed into the following colorant dispersion liquids B-1 to B-12, respectively. As a result, the same evaluation results as those of the corresponding Examples were obtained.

TABLE 6

| | | | Pigment | | | | Organic | |
|---|---|---|---|---|---|---|---|---|
| | Colorant | | derivative | | Resin | | solvent | |
| Colorant | | Parts | | Parts | | Parts | | Parts |
| dispersion | | by | | by | | by | | by |
| liquid | Type | mass | Type | mass | Type | mass | Type | mass |
| B-1 | PB15:6 | 33.9 | Pigment | 5 | Polymer compound 1-1 | 20 | PGMEA | 360 |
| | PV23 | 8.5 | derivative | | PGMEA 30% solution | | | |
| | | | A | | | | | |
| B-2 | PB15:6 | 33.9 | Pigment | 5 | Polymer compound 1-2 | 20 | PGMEA | 360 |
| | PV23 | 8.5 | derivative | | PGMEA 30% solution | | | |
| | | | A | | | | | |
| B-3 | PB15:6 | 33.9 | Pigment | 5 | Polymer compound 1-3 | 20 | PGMEA | 360 |
| | PV23 | 8.5 | derivative | | PGMEA 30% solution | | | |
| | | | A | | | | | |
| B-4 | PB15:6 | 33.9 | Pigment | 5 | Polymer compound 1-4 | 20 | PGMEA | 360 |
| | PV23 | 8.5 | derivative | | PGMEA 30% solution | | | |
| | | | A | | | | | |
| B-5 | PB15:6 | 33.9 | Pigment | 5 | Polymer compound 1-5 | 20 | PGMEA | 360 |
| | PV23 | 8.5 | derivative | | PGMEA 30% solution | | | |
| | | | A | | | | | |
| B-6 | PB15:6 | 33.9 | Pigment | 5 | Polymer compound 1-6 | 20 | PGMEA | 360 |
| | PV23 | 8.5 | derivative | | PGMEA 30% solution | | | |
| | | | A | | | | | |
| B-7 | PB15:6 | 33.9 | Pigment | 5 | Polymer compound 1-7 | 20 | PGMEA | 360 |
| | PV23 | 8.5 | derivative | | PGMEA 30% solution | | | |
| | | | A | | | | | |
| B-8 | PB15:6 | 33.9 | Pigment | 5 | Polymer compound 1-8 | 20 | PGMEA | 360 |
| | PV23 | 8.5 | derivative | | PGMEA 30% solution | | | |
| | | | A | | | | | |
| B-9 | PB15:6 | 33.9 | Pigment | 5 | Polymer compound 1-9 | 20 | PGMEA | 360 |
| | PV23 | 8.5 | derivative | | PGMEA 30% solution | | | |
| | | | A | | | | | |
| B-10 | PB15:6 | 33.9 | Pigment | 5 | Polymer compound 1-10 | 20 | PGMEA | 360 |
| | PV23 | 8.5 | derivative | | PGMEA 30% solution | | | |
| | | | A | | | | | |
| B-11 | PB15:6 | 33.9 | Pigment | 5 | Polymer compound 2-1 | 20 | PGMEA | 360 |
| | PV23 | 8.5 | derivative | | PGMEA 31% solution | | | |
| | | | A | | | | | |
| B-12 | PB15:6 | 33.9 | Pigment | 5 | Polymer compound 2-2 | 20 | PGMEA | 360 |
| | PV23 | 8.5 | derivative | | PGMEA 32% solution | | | |
| | | | A | | | | | |

In Table 6, PB15:6 represents Pigment Blue 15:6, and PV23 represents Pigment Violet 23.

### Examples 25 to 36 and Comparative Examples 7 to 9

<Preparation of Colorant Dispersion Liquids R-1 to R-12 and Comparative R-1 to R-3>

Pigment Red 254, Pigment Yellow 139, a pigment dispersant BYK-161 (manufactured by BYK-Chemie GmbH), a polymer compound, and propylene glycol methyl ether acetate (PGMEA) were mixed by a bead mill (zirconia bead: 0.3 mm diameter) for 3 hours so as to have the composition shown in Table 6 to prepare a pigment dispersion liquid. Thereafter, using a high-pressure disperser NANO-3000-10 with a pressure reducing mechanism (manufactured by Nippon BEE Chemical Co., Ltd.), a dispersion treatment was carried out at a flow rate of 500 g/min under a pressure of 2000 kg/cm³.

This dispersion treatment was repeated 10 times to prepare red colorant dispersion liquid pigment dispersion liquids R-1 to R-12 and Comparative R-1 to R-3.

TABLE 7

| | | | Pigment | | | | Organic | |
|---|---|---|---|---|---|---|---|---|
| | Colorant | | derivative | | Resin | | solvent | |
| Colorant | | Parts | | Parts | | Parts | | Parts |
| dispersion | | by | | by | | by | | by |
| liquid | Type | mass | Type | mass | Type | mass | Type | mass |
| R-1 | PR254 | 9.6 | Pigment | 0.5 | Polymer compound 1-1 | 20 | PGMEA | 79.3 |
| | PY139 | 4.3 | derivative A | | PGMEA 30% solution | | | |
| R-2 | PR254 | 9.6 | Pigment | 0.5 | Polymer compound 1-2 | 20 | PGMEA | 79.3 |
| | PY139 | 4.3 | derivative A | | PGMEA 30% solution | | | |
| R-3 | PR254 | 9.6 | Pigment | 0.5 | Polymer compound 1-3 | 20 | PGMEA | 79.3 |
| | PY139 | 4.3 | derivative A | | PGMEA 30% solution | | | |
| R-4 | PR254 | 9.6 | Pigment | 0.5 | Polymer compound 1-4 | 20 | PGMEA | 79.3 |
| | PY139 | 4.3 | derivative A | | PGMEA 30% solution | | | |
| R-5 | PR254 | 9.6 | Pigment | 0.5 | Polymer compound 1-5 | 20 | PGMEA | 79.3 |
| | PY139 | 4.3 | derivative A | | PGMEA 30% solution | | | |
| R-6 | PR264 | 10.9 | Pigment | 0.5 | Polymer compound 1-6 | 20 | PGMEA | 79.3 |
| | PY139 | 3.0 | derivative A | | PGMEA 30% solution | | | |
| R-7 | PR264 | 10.9 | Pigment | 0.5 | Polymer compound 1-7 | 20 | PGMEA | 79.3 |
| | PY139 | 3.0 | derivative A | | PGMEA 30% solution | | | |
| R-8 | PR264 | 10.9 | Pigment | 0.5 | Polymer compound 1-8 | 20 | PGMEA | 79.3 |
| | PY139 | 3.0 | derivative A | | PGMEA 30% solution | | | |
| R-9 | PR264 | 10.9 | Pigment | 0.5 | Polymer compound 1-9 | 20 | PGMEA | 79.3 |
| | PY139 | 3.0 | derivative A | | PGMEA 30% solution | | | |
| R-10 | PR264 | 10.9 | Pigment | 0.5 | Polymer compound 1-10 | 20 | PGMEA | 79.3 |
| | PY139 | 3.0 | derivative A | | PGMEA 30% solution | | | |
| R-11 | PR264 | 10.9 | Pigment | 0.5 | Polymer compound 2-1 | 20 | PGMEA | 79.3 |
| | PY139 | 3.0 | derivative A | | PGMEA 31% solution | | | |
| R-12 | PR264 | 10.9 | Pigment | 0.5 | Polymer compound 2-2 | 20 | PGMEA | 79.3 |
| | PY139 | 3.0 | derivative A | | PGMEA 32% solution | | | |
| Comparative | PR264 | 10.9 | Pigment | 0.5 | Comparative Compound 1 | 20 | PGMEA | 79.3 |
| R-1 | PY139 | 3.0 | derivative A | | PGMEA 30% solution | | | |
| Comparative | PR264 | 10.9 | Pigment | 0.5 | Comparative Compound 2 | 20 | PGMEA | 79.3 |
| R-2 | PY139 | 3.0 | derivative A | | PGMEA 30% solution | | | |
| Comparative | PR264 | 10.9 | Pigment | 0.5 | Comparative Compound 3 | 20 | PGMEA | 79.3 |
| R-3 | PY139 | 3.0 | derivative A | | MFG 30% solution | | | |

Individual components were mixed to prepare a curable composition in the same manner as in Example 1, except that the composition in each Example was changed into the composition shown in Table 8.

In each Example, the storage stability, development residue, and edge shape of the cured product were evaluated in the same manner as in Example 1 using the prepared curable composition. The evaluation results are shown in Table 8.

TABLE 8

| | | | | | | | | | | | Organic | | Evaluation results | | | | |
|---|---|---|---|---|---|---|---|---|---|---|---|---|---|---|---|---|---|
| | Colorant | | Alkali- | | Poly- | | Photopoly- | | | | solvent | | Undercut | | | | |
| | dispersion | | soluble | | merizable | | merization | | | | (solid | | width | | | De- | |
| | liquid | | resin | | compound | | initiator | | Surfactant | | content 28%) | | Under- | | | velop- | Stor- |
| | | Parts | | Parts | | Parts | | Parts | | Parts | | Parts | cut | | Bor- | ment | age |
| | | by | | by | | by | | by | | by | | by | width | Eval- | der | res- | sta- |
| | Type | mass | Type | mass | Type | mass | Type | mass | Type | mass | Type | mass | (μm) | uation | width | idue | bility |
| Example | R-1 | 382 | Alkali- | 3 | M-1 | 13 | Oxime- | 5 | Sur- | 0.1 | PGMEA | 324 | 0.2 | AA | AA | 5 | 5 |
| 25 | | | soluble | | | | based | | factant | | | | | | | | |
| | | | resin 1 | | | | polymer- | | 1 | | | | | | | | |
| | | | | | | | ization | | | | | | | | | | |
| | | | | | | | initiator 1 | | | | | | | | | | |
| Example | R-2 | 382 | Alkali- | 3 | M-1 | 13 | Oxime- | 5 | Sur- | 0.1 | PGMEA | 324 | 0.4 | A | A | 4 | 4 |
| 26 | | | soluble | | | | based | | factant | | | | | | | | |
| | | | resin 2 | | | | polymer- | | 1 | | | | | | | | |
| | | | | | | | ization | | | | | | | | | | |
| | | | | | | | initiator 2 | | | | | | | | | | |
| Example | R-3 | 382 | Alkali- | 3 | M-1 | 13 | Oxime- | 5 | Sur- | 0.1 | PGMEA | 324 | 0.3 | A | A | 4 | 4 |
| 27 | | | soluble | | | | based | | factant | | | | | | | | |
| | | | resin 3 | | | | polymer- | | 1 | | | | | | | | |
| | | | | | | | ization | | | | | | | | | | |
| | | | | | | | initiator 3 | | | | | | | | | | |
| Example | R-4 | 382 | Alkali- | 3 | M-1 | 13 | Oxime- | 5 | Sur- | 0.1 | PGMEA | 324 | 0.4 | A | A | 4 | 4 |
| 28 | | | soluble | | | | based | | factant | | | | | | | | |
| | | | resin 1 | | | | polymer- | | 1 | | | | | | | | |
| | | | | | | | ization | | | | | | | | | | |
| | | | | | | | initiator 4 | | | | | | | | | | |
| Example | R-5 | 382 | Alkali- | 3 | M-2 | 13 | Oxime- | 5 | Sur- | 0.1 | PGMEA | 324 | 0.4 | A | A | 4 | 4 |
| 29 | | | soluble | | | | based | | factant | | | | | | | | |
| | | | resin 1 | | | | polymer- | | 1 | | | | | | | | |
| | | | | | | | ization | | | | | | | | | | |
| | | | | | | | initiator 1 | | | | | | | | | | |
| Example | R-6 | 382 | Alkali- | 3 | M-1 | 8/5 | Oxime- | 5 | Sur- | 0.1 | PGMEA | 324 | 0.2 | AA | AA | 5 | 5 |
| 30 | | | soluble | | | | based | | factant | | | | | | | | |
| | | | resin 1 | | | | polymer- | | 1 | | | | | | | | |
| | | | | | | | ization | | | | | | | | | | |
| | | | | | | | initiator 1 | | | | | | | | | | |
| Example | R-7 | 382 | Alkali- | 3 | M-1 | 15 | Oxime- | 5 | Sur- | 0.1 | PGMEA | 324 | 0.2 | AA | AA | 5 | 5 |
| 31 | | | soluble | | | | based | | factant | | | | | | | | |
| | | | resin 1 | | | | polymer- | | 1 | | | | | | | | |
| | | | | | | | ization | | | | | | | | | | |
| | | | | | | | initiator 1 | | | | | | | | | | |
| Example | R-8 | 382 | Alkali- | 2/1 | M-1 | 15 | Oxime- | 5 | Sur- | 0.1 | PGMEA | 324 | 0.2 | AA | AA | 5 | 5 |
| 32 | | | soluble | | | | based | | factant | | | | | | | | |
| | | | resin 1/ | | | | polymer- | | 1 | | | | | | | | |
| | | | Alkali- | | | | ization | | | | | | | | | | |
| | | | soluble | | | | initiator 1 | | | | | | | | | | |
| | | | resin 2 | | | | | | | | | | | | | | |
| Example | R-9 | 382 | Alkali- | 3 | M-1 | 13 | Oxime- | 5 | Sur- | 0.1 | PGMEA | 324 | 0.2 | AA | AA | 5 | 5 |
| 33 | | | soluble | | | | based | | factant | | | | | | | | |
| | | | resin 1 | | | | polymer- | | 1 | | | | | | | | |
| | | | | | | | ization | | | | | | | | | | |
| | | | | | | | initiator 1 | | | | | | | | | | |
| Example | R-10 | 382 | Alkali- | 3 | M-1 | 13 | Oxime- | 5 | Sur- | 0.1 | PGMEA | 324 | 0.2 | AA | AA | 4 | 4 |
| 34 | | | soluble | | | | based | | factant | | | | | | | | |
| | | | resin 1 | | | | polymer- | | 1 | | | | | | | | |
| | | | | | | | ization | | | | | | | | | | |
| | | | | | | | initiator 1 | | | | | | | | | | |
| Example | R-11 | 382 | Alkali- | 3 | M-1 | 13 | Oxime- | 5 | Sur- | 0.1 | PGMEA | 324 | 0.3 | A | AA | 5 | 4 |
| 35 | | | soluble | | | | based | | factant | | | | | | | | |
| | | | resin 1 | | | | polymer- | | 1 | | | | | | | | |
| | | | | | | | ization | | | | | | | | | | |
| | | | | | | | initiator 1 | | | | | | | | | | |
| Example | R-12 | 382 | Alkali- | 3 | M-1 | 13 | Oxime- | 5 | Sur- | 0.1 | PGMEA | 324 | 0.4 | A | AA | 5 | 4 |
| 36 | | | soluble | | | | based | | factant | | | | | | | | |
| | | | resin 1 | | | | polymer- | | 1 | | | | | | | | |
| | | | | | | | ization | | | | | | | | | | |
| | | | | | | | initiator 1 | | | | | | | | | | |
| Compar- | Compar- | 382 | Alkali- | 3 | M-1 | 13 | Oxime- | 5 | Sur- | 0.1 | PGMEA | 324 | 0.8 | B | C | 1 | 1 |
| ative | ative | | soluble | | | | based | | factant | | | | | | | | |
| Example | R-1 | | resin 1 | | | | polymer- | | 1 | | | | | | | | |
| 7 | | | | | | | ization | | | | | | | | | | |
| | | | | | | | initiator 1 | | | | | | | | | | |
| Compar- | Compar- | 382 | Alkali- | 3 | M-1 | 13 | Oxime- | 5 | Sur- | 0.1 | PGMEA | 324 | 1.5 | C | B | 4 | 4 |
| ative | ative | | soluble | | | | based | | factant | | | | | | | | |
| Example | R-2 | | resin 1 | | | | polymer- | | 1 | | | | | | | | |
| 8 | | | | | | | ization | | | | | | | | | | |
| | | | | | | | initiator 1 | | | | | | | | | | |
| Compar- | Compar- | 382 | Alkali- | 3 | M-1 | 13 | Oxime- | 5 | Sur- | 0.1 | PGMEA | 324 | 1.3 | C | C | 1 | 1 |
| ative | ative | | soluble | | | | based | | factant | | | | | | | | |
| Example | R-3 | | resin 1 | | | | polymer- | | 1 | | | | | | | | |
| 9 | | | | | | | ization | | | | | | | | | | |
| | | | | | | | initiator 1 | | | | | | | | | | |

### Examples 37 to 48 and Comparative Examples 10 to 12

The pyrrolopyrrole pigment 1, the polymer compound, and PGMEA were mixed and dispersed using zirconia beads having a diameter of 0.3 mm in a bead mill (high-pressure disperser NANO-3000-10 with a pressure reducing mechanism, manufactured by Nippon BEE Chemical Co., Ltd.) so as to have the composition shown in Table 9 to prepare IR pigment dispersion liquids IR-1 to IR-12 or Comparative IR-1 to IR-3. The dispersion resin 1 is the same as that used in chromatic pigment dispersion liquids 2-1 to 2-4 which will be described later.

In the present disclosure, “IR pigment” refers to an infrared absorbing pigment.

TABLE 9

| | IR pigment | | Resin | | Organic solvent | |
|---|---|---|---|---|---|---|
| IR pigment | | Parts | | Parts | | Parts |
| dispersion | | by | | by | | by |
| liquid | Type | mass | Type | mass | Type | mass |
| IR-1 | Pyrrolopyrrole | 13.5 | Polymer compound 1-1 | 13.3 | PGMEA | 82.5 |
| | pigment 1 | | PGMEA 30% solution | | | |
| IR-2 | Pyrrolopyrrole | 13.5 | Polymer compound 1-2 | 13.3 | PGMEA | 82.5 |
| | pigment 1 | | PGMEA 30% solution | | | |
| IR-3 | Pyrrolopyrrole | 13.5 | Polymer compound 1-3 | 13.3 | PGMEA | 82.5 |
| | pigment 1 | | PGMEA 30% solution | | | |
| IR-4 | Pyrrolopyrrole | 13.5 | Polymer compound 1-4 | 13.3 | PGMEA | 82.5 |
| | pigment 1 | | PGMEA 30% solution | | | |
| IR-5 | Pyrrolopyrrole | 13.5 | Polymer compound 1-5 | 13.3 | PGMEA | 82.5 |
| | pigment 1 | | PGMEA 30% solution | | | |
| IR-6 | Pyrrolopyrrole | 13.5 | Polymer compound 1-6 | 13.3 | PGMEA | 82.5 |
| | pigment 1 | | PGMEA 30% solution | | | |
| IR-7 | Pyrrolopyrrole | 13.5 | Polymer compound 1-7 | 13.3 | PGMEA | 82.5 |
| | pigment 1 | | PGMEA 30% solution | | | |
| IR-8 | Pyrrolopyrrole | 13.5 | Polymer compound 1-8 | 13.3 | PGMEA | 82.5 |
| | pigment 1 | | PGMEA 30% solution | | | |
| IR-9 | Pyrrolopyrrole | 13.5 | Polymer compound 1-9 | 13.3 | PGMEA | 82.5 |
| | pigment 1 | | PGMEA 30% solution | | | |
| IR-10 | Pyrrolopyrrole | 13.5 | Polymer compound 1-10 | 13.3 | PGMEA | 82.5 |
| | pigment 1 | | PGMEA 30% solution | | | |
| IR-11 | Pyrrolopyrrole | 13.5 | Polymer compound 2-1 | 13.3 | PGMEA | 82.5 |
| | pigment 1 | | PGMEA 31% solution | | | |
| IR-12 | Pyrrolopyrrole | 13.5 | Polymer compound 2-2 | 13.3 | PGMEA | 82.5 |
| | pigment 1 | | PGMEA 32% solution | | | |
| Comparative | Pyrrolopyrrole | 13.5 | Comparative Compound 1 | 13.3 | PGMEA | 82.5 |
| IR-1 | pigment 1 | | PGMEA 30% solution | | | |
| Comparative | Pyrrolopyrrole | 13.5 | Comparative Compound 2 | 13.3 | PGMEA | 82.5 |
| IR-2 | pigment 1 | | PGMEA 30% solution | | | |
| Comparative | Pyrrolopyrrole | 13.5 | Comparative Compound 3 | 13.3 | PGMEA | 82.5 |
| IR-3 | pigment 1 | | MFG 30% solution | | | |

Details of the compounds used for the preparation of the IR pigment dispersion liquids IR-1 to IR-12 and Comparative IR-1 to IR-3 are as follows.

[Ir Pigment]
Pyrrolopyrrole pigment 1: a compound having a structure shown below (synthesized by the method described in JP2009-263614A) (which is an infrared absorbing pigment having maximum absorption in a wavelength range of 800 to 900 nm)

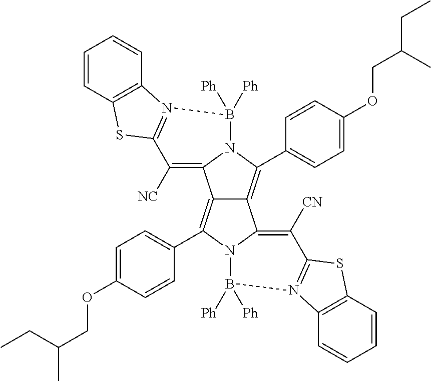

<Preparation of Chromatic Pigment Dispersion Liquids 2-1 to 2-4>

The mixed liquid having the composition shown in Table 10 below was mixed and dispersed for 3 hours using zirconia beads having a diameter of 0.3 mm in a bead mill (high-pressure disperser NANO-3000-10 with a pressure reducing mechanism, manufactured by Nippon BEE Chemical Co., Ltd.) to prepare chromatic pigment dispersion liquids 2-1 to 2-4. Table 10 below shows the used amount (unit: parts by mass) of the corresponding component.

TABLE 10

| | Pigment | | Resin | | Organic solvent | |
|---|---|---|---|---|---|---|
| | | Parts | | Parts | | Parts |
| | | by | | by | | by |
| | Type | mass | Type | mass | Type | mass |
| Pigment | PR254 | 13.5 | Dispersion resin 2/ | 2/2 | PGMEA | 82.5 |
| dispersion | | | Alkali-soluble | | | |
| liquid 2-1 | | | resin 2 | | | |
| Pigment | PB15:6 | 13.5 | Dispersion resin 3 | 4 | PGMEA | 82.5 |
| dispersion | | | | | | |
| liquid 2-2 | | | | | | |
| Pigment | PY139 | 14.8 | Dispersion resin 1/ | 3/2.2 | PGMEA | 80 |
| dispersion | | | Alkali-soluble | | | |
| liquid 2-3 | | | resin 2 | | | |
| Pigment | PV23 | 14.8 | Dispersion resin 1, | 3/2.2 | PGMEA | 80 |
| dispersion | | | Alkali-soluble | | | |
| liquid 2-4 | | | resin 2 | | | |

Details of the components shown in Table 10 other than those described above will be described below.

[Pigment]
PR254: Pigment Red 254
PB15: 6: Pigment Blue 15:6
PY139: Pigment Yellow 139
PV23: Pigment Violet 23

[Dispersion Resin]
Dispersing resin 2: a structure shown below (Mw: 7950)

In the following structural formula, the subscript for parentheses representing the constitutional unit of the polymer main chain represents the content (mol %) of the constitutional unit, and the subscript for parentheses representing the polyester unit represents the number of repetitions.

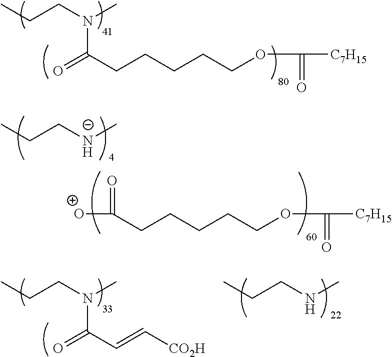

Dispersing resin 3: a structure shown below (Mw: 30000)

In the following structural formula, the subscript for parentheses representing the constitutional unit of the polymer main chain represents the content (mol %) of the constitutional unit, and the subscript for parentheses representing the polyester unit represents the number of repetitions.

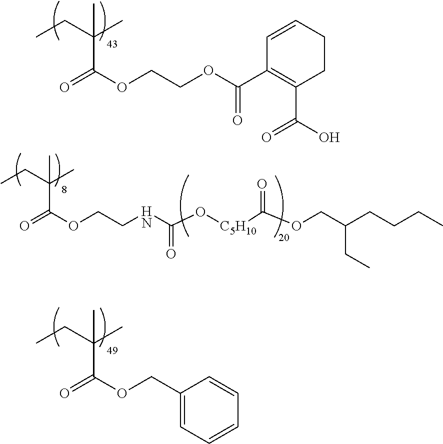

[Alkali-Soluble Resin]
Alkali-soluble resin 2: a structure shown below (Mw: 12000)

In the following structural formula, the subscript for parentheses representing the constitutional unit of the polymer main chain represents the content (mol %) of the constitutional unit.

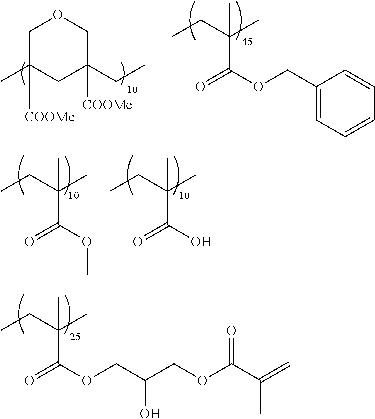

Individual components were mixed to prepare a curable composition in the same manner as in Example 1, except that the composition in each Example was changed into the composition shown in Table 11 or 12.

In each Example, the storage stability, development residue, and edge shape of the cured product were evaluated in the same manner as in Example 1 using the prepared curable composition. The evaluation results are shown in Table 11 or 12.

TABLE 11

| Evaluation results | | | | | | | | | | | | | | | | | | | |
|---|---|---|---|---|---|---|---|---|---|---|---|---|---|---|---|---|---|---|---|
| | | | | | | | | | | | | | Organic | | | | | | |
| | Colorant | | | | | | Poly- | | Photopoly- | | | | solvent | | Evaluation results | | | | |
| | dispersion | | | | Alkali- | | merizable | | merization | | | | (solid | | Undercut width | | | | |
| | liquid | | | | soluble resin | | compound | | initiator | | Surfactant | | content 28%) | | Under- | | | De- | |
| | | Parts | | Parts | | Parts | | Parts | | Parts | | Parts | | Parts | cut | | | velop- | |
| | | by | | by | | by | | by | | by | | by | | by | width | Eval- | Border | ment | Storage |
| | Type | mass | Type | mass | Type | mass | Type | mass | Type | mass | Type | mass | Type | mass | (μm) | uation | width | residue | stability |
| Example 37 | IR-1 | 157 | Pigment dispersion liquid 2-1 | 63.2 | Alkali- | 2.4 | M-1 | 12 | Oxime- | 5 | Surfactant 1 | 0.1 | PGMEA | 420 | 0.2 | AA | AA | 5 | 4 |
| | | | Pigment dispersion liquid 2-2 | 126.4 | soluble | | | | based | | | | | | | | | | |
| | | | Pigment dispersion liquid 2-3 | 57.6 | resin 1 | | | | polymer- | | | | | | | | | | |
| | | | Pigment dispersion liquid 2-4 | 38.4 | | | | | ization | | | | | | | | | | |
| | | | | | | | | | initiator 1 | | | | | | | | | | |
| Example 38 | IR-2 | 157 | Pigment dispersion liquid 2-1 | 63.2 | Alkali- | 2.4 | M-1 | 12 | Oxime- | 5 | Surfactant 1 | 0.1 | PGMEA | 420 | 0.4 | A | A | 4 | 4 |
| | | | Pigment dispersion liquid 2-2 | 126.4 | soluble | | | | based | | | | | | | | | | |
| | | | Pigment dispersion liquid 2-3 | 57.6 | resin 2 | | | | polymer- | | | | | | | | | | |
| | | | Pigment dispersion liquid 2-4 | 38.4 | | | | | ization | | | | | | | | | | |
| | | | | | | | | | initiator 2 | | | | | | | | | | |
| Example 39 | IR-3 | 157 | Pigment dispersion liquid 2-1 | 63.2 | Alkali- | 2.4 | M-1 | 12 | Oxime- | 5 | Surfactant 1 | 0.1 | PGMEA | 420 | 0.4 | A | A | 4 | 4 |
| | | | Pigment dispersion liquid 2-2 | 126.4 | soluble | | | | based | | | | | | | | | | |
| | | | Pigment dispersion liquid 2-3 | 57.6 | resin 3 | | | | polymer- | | | | | | | | | | |
| | | | Pigment dispersion liquid 2-4 | 38.4 | | | | | ization | | | | | | | | | | |
| | | | | | | | | | initiator 3 | | | | | | | | | | |
| Example 40 | IR-4 | 157 | Pigment dispersion liquid 2-1 | 63.2 | Alkali- | 2.4 | M-1 | 12 | Oxime- | 5 | Surfactant 1 | 0.1 | PGMEA | 420 | 0.3 | A | A | 4 | 4 |
| | | | Pigment dispersion liquid 2-2 | 126.4 | soluble | | | | based | | | | | | | | | | |
| | | | Pigment dispersion liquid 2-3 | 57.6 | resin 1 | | | | polymer- | | | | | | | | | | |
| | | | Pigment dispersion liquid 2-4 | 38.4 | | | | | ization | | | | | | | | | | |
| | | | | | | | | | initiator 4 | | | | | | | | | | |
| Example 41 | IR-5 | 157 | Pigment dispersion liquid 2-1 | 63.2 | Alkali- | 2.4 | M-1 | 12 | Oxime- | 5 | Surfactant 1 | 0.1 | PGMEA | 420 | 0.3 | A | A | 4 | 4 |
| | | | Pigment dispersion liquid 2-2 | 126.4 | soluble | | | | based | | | | | | | | | | |
| | | | Pigment dispersion liquid 2-3 | 57.6 | resin 1 | | | | polymer- | | | | | | | | | | |
| | | | Pigment dispersion liquid 2-4 | 38.4 | | | | | ization | | | | | | | | | | |
| | | | | | | | | | initiator 1 | | | | | | | | | | |
| Example 42 | IR-6 | 157 | Pigment dispersion liquid 2-1 | 63.2 | Alkali- | 2.4 | M-1/ | 6/6 | Oxime- | 5 | Surfactant 1 | 0.1 | PGMEA | 420 | 0.2 | AA | AA | 4 | 5 |
| | | | Pigment dispersion liquid 2-2 | 126.4 | soluble | | M-3 | | based | | | | | | | | | | |
| | | | Pigment dispersion liquid 2-3 | 57.6 | resin 1 | | | | polymer- | | | | | | | | | | |
| | | | Pigment dispersion liquid 2-4 | 38.4 | | | | | ization | | | | | | | | | | |
| | | | | | | | | | initiator 1 | | | | | | | | | | |
| Example 43 | IR-7 | 157 | Pigment dispersion liquid 2-1 | 63.2 | Alkali- | 2.4 | M-1 | 12 | Oxime- | 5 | Surfactant 1 | 0.1 | PGMEA | 420 | 0.2 | AA | AA | 4 | 5 |
| | | | Pigment dispersion liquid 2-2 | 126.4 | soluble | | | | based | | | | | | | | | | |
| | | | Pigment dispersion liquid 2-3 | 57.6 | resin 1 | | | | polymer- | | | | | | | | | | |
| | | | Pigment dispersion liquid 2-4 | 38.4 | | | | | ization | | | | | | | | | | |
| | | | | | | | | | initiator 1 | | | | | | | | | | |
| Example 44 | IR-8 | 157 | Pigment dispersion liquid 2-1 | 63.2 | Alkali- | 12/12 | M-1 | 12 | Oxime- | 5 | Surfactant 1 | 0.1 | PGMEA | 420 | 0.2 | AA | AA | 4 | 5 |
| | | | Pigment dispersion liquid 2-2 | 126.4 | soluble | | | | based | | | | | | | | | | |
| | | | Pigment dispersion liquid 2-3 | 57.6 | resin 1/ | | | | polymer- | | | | | | | | | | |
| | | | Pigment dispersion liquid 2-4 | 38.4 | Alkali- | | | | ization | | | | | | | | | | |
| | | | | | soluble | | | | initiator 1 | | | | | | | | | | |
| | | | | | resin 2 | | | | | | | | | | | | | | |

TABLE 12

| | Evaluation results | | | | | | | | | | | | | | | | | | |
|---|---|---|---|---|---|---|---|---|---|---|---|---|---|---|---|---|---|---|---|
| | | | | | | | | | | | | | Organic | | | | | | |
| | | | | | | | | | | | | | solvent | | | | | | |
| | Colorant | | | | Alkali- | | Poly- | | Photopoly- | | | | (solid | | Evaluation results | | | | |
| | dispersion | | | | soluble | | merizable | | merization | | | | content | | Undercut width | | | | |
| | liquid | | | | resin | | compound | | initiator | | Surfactant | | 28%) | | Under- | | | De- | |
| | | Parts | | Parts | | Parts | | Parts | | Parts | | Parts | | Parts | cut | | | velop- | |
| | | by | | by | | by | | by | | by | | by | | by | width | Eval- | Border | ment | Storage |
| | Type | mass | Type | mass | Type | mass | Type | mass | Type | mass | Type | mass | Type | mass | (μm) | uation | width | residue | stability |
| Example 46 | IR-10 | 157 | Pigment dispersion liquid 2-1 | 63.2 | Alkali- | 2.4 | M-1 | 12 | Oxime- | 5 | Surfactant 1 | 0.1 | PGMEA | 420 | 0.2 | AA | AA | 4 | 4 |
| | | | Pigment dispersion liquid 2-2 | 126.4 | soluble | | | | based | | | | | | | | | | |
| | | | Pigment dispersion liquid 2-3 | 57.6 | resin 1 | | | | polymer- | | | | | | | | | | |
| | | | Pigment dispersion liquid 2-4 | 38.4 | | | | | ization | | | | | | | | | | |
| | | | | | | | | | initiator 1 | | | | | | | | | | |
| Example 47 | IR-11 | 157 | Pigment dispersion liquid 2-1 | 63.2 | Alkali- | 2.4 | M-1 | 12 | Oxime- | 5 | Surfactant 1 | 0.1 | PGMEA | 420 | 0.2 | AA | AA | 5 | 4 |
| | | | Pigment dispersion liquid 2-2 | 126.4 | soluble | | | | based | | | | | | | | | | |
| | | | Pigment dispersion liquid 2-3 | 57.6 | resin 1 | | | | polymer- | | | | | | | | | | |
| | | | Pigment dispersion liquid 2-4 | 38.4 | | | | | ization | | | | | | | | | | |
| | | | | | | | | | initiator 1 | | | | | | | | | | |
| Example 48 | IR-12 | 157 | Pigment dispersion liquid 2-1 | 63.2 | Alkali- | 2.4 | M-1 | 12 | Oxime- | 5 | Surfactant 1 | 0.1 | PGMEA | 420 | 0.2 | AA | AA | 5 | 4 |
| | | | Pigment dispersion liquid 2-2 | 126.4 | soluble | | | | based | | | | | | | | | | |
| | | | Pigment dispersion liquid 2-3 | 57.6 | resin 1 | | | | polymer- | | | | | | | | | | |
| | | | Pigment dispersion liquid 2-4 | 38.4 | | | | | ization | | | | | | | | | | |
| | | | | | | | | | initiator 1 | | | | | | | | | | |
| Comparative | Comparative | 157 | Pigment dispersion liquid 2-1 | 63.2 | Alkali- | 2.4 | M-1 | 12 | Oxime- | 5 | Surfactant 1 | 0.1 | PGMEA | 420 | 0.9 | B | B | 1 | 1 |
| Example 10 | IR-1 | | Pigment dispersion liquid 2-2 | 126.4 | soluble | | | | based | | | | | | | | | | |
| | | | Pigment dispersion liquid 2-3 | 57.6 | resin 1 | | | | polymer- | | | | | | | | | | |
| | | | Pigment dispersion liquid 2-4 | 38.4 | | | | | ization | | | | | | | | | | |
| | | | | | | | | | initiator 1 | | | | | | | | | | |
| Comparative | Comparative | 157 | Pigment dispersion liquid 2-1 | 63.2 | Alkali- | 2.4 | M-1 | 12 | Oxime- | 5 | Surfactant 1 | 0.1 | PGMEA | 420 | 1.5 | C | C | 3 | 3 |
| Example 11 | IR-2 | | Pigment dispersion liquid 2-2 | 126.4 | soluble | | | | based | | | | | | | | | | |
| | | | Pigment dispersion liquid 2-3 | 57.6 | resin 1 | | | | polymer- | | | | | | | | | | |
| | | | Pigment dispersion liquid 2-4 | 38.4 | | | | | ization | | | | | | | | | | |
| | | | | | | | | | initiator 1 | | | | | | | | | | |
| Comparative | Comparative | 157 | Pigment dispersion liquid 2-1 | 63.2 | Alkali- | 2.4 | M-1 | 12 | Oxime- | 5 | Surfactant 1 | 0.1 | PGMEA | 420 | 1.5 | C | C | 2 | 1 |
| Example 12 | IR-3 | | Pigment dispersion liquid 2-2 | 126.4 | soluble | | | | based | | | | | | | | | | |
| | | | Pigment dispersion liquid 2-3 | 57.6 | resin 1 | | | | polymer- | | | | | | | | | | |
| | | | Pigment dispersion liquid 2-4 | 38.4 | | | | | ization | | | | | | | | | | |
| | | | | | | | | | initiator 1 | | | | | | | | | | |

### EXPLANATION OF REFERENCES

2: pattern edge portion of cured product
4: wafer
T: length of notch of bottom portion in pattern edge portion of cured product
L₁: exposed region
L₂: unexposed region

What is claimed is:

1. A curable composition comprising:
a particle; and
at least one polymer compound selected from the group consisting of a polymer compound represented by Formula I and having a specific absorbance E represented by Expression Aλ of less than 5 at a maximum absorption wavelength within a range of 400 nm to 800 nm, and a polymer compound represented by Formula II and having a specific absorbance E represented by Expression Aλ of less than 5 at a maximum absorption wavelength within a range of 400 nm to 800 nm,
Specific absorbance E=A/(c×L) Expression Aλ
in Expression Aλ, A represents an absorbance at the maximum absorption wavelength within the range of 400 nm to 800 nm, L represents an optical path length at a time of measuring the absorbance, which is expressed in cm, and c represents a concentration of the polymer compound in a solution, which is expressed in mg/mL, 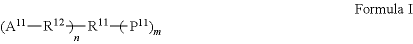
in Formula I, R¹ represents an (m+n)-valent organic linking group, A¹¹'s each independently represent a monovalent organic group containing at least one structure or group selected from the group consisting of an organic coloring agent structure, a heterocyclic structure, an acid group, a group having a basic nitrogen atom, a urea group, a urethane group, a group having a coordinating oxygen atom, a hydrocarbon group having 4 or more carbon atoms, an alkoxysilyl group, an epoxy group, an isocyanate group, and a hydroxy group, R¹²'s each independently represent a single bond or a divalent organic linking group, n represents 1.5 to 9, P¹¹ represents a polymer chain containing a constitutional unit having a polymerizable group, m represents 1 to 8.5, and m+n is 3 to 10, 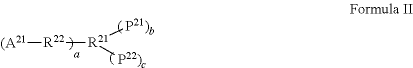
in Formula II, R²¹ represents an (a+b+c)-valent organic linking group, and A²¹ represents a monovalent organic group containing at least one moiety selected from an organic coloring agent structure, a heterocyclic structure, an acid group, a group having a basic nitrogen atom, a urea group, a urethane group, a group having a coordinating oxygen atom, a hydrocarbon group having 4 or more carbon atoms, an alkoxysilyl group, an epoxy group, an isocyanate group, or a hydroxyl group, R²² represents a single bond or a divalent organic linking group, a represents 0 to 8.5, b represents 1 to 10, c represents 1 to 8.5, a+b+c is 3 to 10, P²¹ represents a polymer chain having an acid value of 10 mgKOH/g or less and containing a constitutional unit having a polymerizable group, and P²² represents a polymer chain having an acid value of 20 mgKOH/g or more and containing a constitutional unit having an acid group.

2. The curable composition according to claim 1,
wherein the polymerizable group contained in P^{H} and the polymerizable group contained in P²¹ include at least one selected from the group consisting of a (meth)acryloxy group, a (meth)acrylamide group, and a vinyl phenyl group.

3. The curable composition according to claim 1,
wherein P^{H} further contains a constitutional unit having an acid group.

4. The curable composition according to claim 3,
wherein the constitutional unit having an acid group is represented by Formula A: 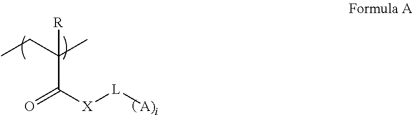
in Formula A, R represents a hydrogen atom or an alkyl group having 1 to 4 carbon atoms, X represents —O— or —NR^{N}— where R^{N} represents a hydrogen atom or an alkyl group having 1 to 4 carbon atoms, L represents an (i+1)-valent linking group, A represents an acid group, and i represents an integer of 1 to 3.

5. The curable composition according to claim 1,
wherein a polymerizable group value in P²¹ is 0.01 mol/g to 6 mol/g.

6. The curable composition according to claim 1,
wherein the particle includes at least one selected from the group consisting of a colorant and an infrared absorber.

7. The curable composition according to claim 1, further comprising:
a photopolymerization initiator.

8. The curable composition according to claim 1, further comprising:
a polymerizable compound.

9. A cured product obtained by curing the curable composition according to claim 1.

10. A color filter comprising:
the cured product according to claim 9.

11. A method for producing a color filter, comprising:
applying the curable composition according to claim 1 onto a support to form a composition film;
exposing the formed composition film in a pattern-wise manner; and
developing the composition film after exposure to form a pattern.

12. A method for producing a color filter, comprising:
applying the curable composition according to claim 1 onto a support and curing the applied curable composition to form a cured product;
forming a photoresist layer on the cured product;
exposing the photoresist layer in a pattern-wise manner and developing the exposed photoresist layer to form a resist pattern; and
etching the cured product through the resist pattern.

13. A solid-state imaging element comprising:
the color filter according to claim 10.

14. An image display device comprising:
the color filter according to claim 10.
